(19) United States
(12) Patent Application Publication
(10) Pub. No.: US 2008/0302418 A1
(43) Pub. Date: Dec. 11, 2008

(54) Elongated Photovoltaic Devices in Casings

(76) Inventors: Benyamin Buller, Sylvania, OH (US); Christian M. Gronet, Portola Valley, CA (US); Ratson Morad, Palo Alto, CA (US); Markus E. Beck, Scotts Valley, CA (US); Brian Cumpston, Pleasanton, CA (US)

Correspondence Address: JONES DAY, 222 EAST 41ST ST, NEW YORK, NY, 10017, US

(21) Appl. No.: 12/115,485

(22) Filed: May 5, 2008

Related U.S. Application Data
(63) Continuation-in-part of application No. 11/800,089, filed on May 3, 2007.
Application No. 11/800,089 is a continuation-in-part of application No. 11/378,847, filed on Mar. 18, 2006.
Application No. 11/378,847 is a continuation-in-part of application No. 11/437,928, filed on May 19, 2006.

(51) Int. Cl. H01L 31/0272; H01L 31/04; H01L 31/06; H01L 31/18

(52) U.S. Cl. 136/259; 136/262; 136/265; 438/64; 257/E31.009

(57) ABSTRACT

A solar cell unit comprising a solar cell and an at least partially transparent casing that encases the solar cell. The solar cell includes a nonplanar substrate defining a length of the solar cell, wherein a length of the nonplanar substrate is at least three times longer than a width of the nonplanar substrate. A back-electrode is disposed around all or a portion of the nonplanar substrate, and extends along all or a portion of the length of the nonplanar substrate. A semiconductor junction is disposed on the back-electrode, and has first and second layers, each of which has an inorganic semiconductor. An at least partially transparent conductive layer is disposed on the semiconductor junction. Optionally, filler material is disposed on the transparent conductive layer, which can for example be a liquid or gel.

### CROSS-REFERENCE TO RELATED APPLICATIONS

This application is a continuation-in-part, and claims the benefit under 35 U.S.C. § 120, of U.S. patent application Ser. No. 11/800,089, filed May 3, 2007 and entitled “Elongated Photovoltaic Cells in Casings,” the entire contents of which are hereby incorporated by reference herein, which is a continuation-in-part of U.S. patent application Ser. No. 11/378,847, filed Mar. 18, 2006 and entitled “Elongated Photovoltaic Cells in Casings,” the entire contents of which are hereby incorporated by reference herein. This application is also a continuation-in-part, and claims the benefit under 35 U.S.C. § 120, of U.S. patent application Ser. No. 11/437,928, filed May 19, 2006 and entitled “Hermetically Sealed Nonplanar Solar Cells,” the entire contents of which are hereby incorporated by reference herein.

### 1. FIELD

This application relates to solar cell assemblies for converting solar energy into electrical energy and more particularly to improved solar cell assemblies.

### 2. BACKGROUND

Solar cells are typically fabricated as separate physical entities with light gathering surface areas on the order of 4-6 cm² or larger. For this reason, it is standard practice for power generating applications to mount the cells in a flat array on a supporting substrate or panel so that their light gathering surfaces provide an approximation of a single large light gathering surface. Also, since each cell itself generates only a small amount of power, the required voltage and/or current is realized by interconnecting the cells of the array in a series and/or parallel matrix.

A conventional prior art solar cell structure is shown in FIG. 1. Because of the large range in the thickness of the different layers, they are depicted schematically. Moreover, FIG. 1 is highly schematic so that it represents the features of both “thick-film” solar cells and “thin-film” solar cells. In general, solar cells that use an indirect band gap material to absorb light are typically configured as “thick-film” solar cells because a thick film of the absorber layer is required to absorb a sufficient amount of light. Solar cells that use a direct band gap material to absorb light are typically configured as “thin-film” solar cells because only a thin layer of the direct band-gap material is needed to absorb a sufficient amount of light.

The arrows at the top of FIG. 1 show the source of direct solar illumination on the cell. Layer 102 is the substrate. Glass or metal is a common substrate. In thin-film solar cells, substrate 102 can be—a polymer-based backing, metal, or glass. In some instances, there is an encapsulation layer (not shown) coating substrate 102. Layer 104 is the back electrical contact for the solar cell.

Layer 106 is the semiconductor absorber layer. Back electrical contact 104 makes ohmic contact with absorber layer 106. In many but not all cases, absorber layer 106 is a p-type semiconductor. Absorber layer 106 is thick enough to absorb light. Layer 108 is the semiconductor junction partner—that, together with semiconductor absorber layer 106, completes the formation of a p-n junction. A p-n junction is a common type of junction found in solar cells. In p-n junction based solar cells, when semiconductor absorber layer 106 is a p-type doped material, junction partner 108 is an n-type doped material. Conversely, when semiconductor absorber layer 106 is an n-type doped material, junction partner 108 is a p-type doped material. Generally, junction partner 108 is much thinner than absorber layer 106. For example, in some instances junction partner 108 has a thickness of about 0.05 microns. Junction partner 108 is highly transparent to solar radiation. Junction partner 108 is also known as the window layer, since it lets the light pass down to absorber layer 106.

In a typical thick-film solar cell, absorber layer 106 and window layer 108 can be made from the same semiconductor material but have different carrier types (dopants) and/or carrier concentrations in order to give the two layers their distinct p-type and n-type properties. In thin-film solar cells in which copper-indium-gallium-diselenide (CIGS) is the absorber layer 106, the use of CdS to form junction partner 108 has resulted in high efficiency cells. Other materials that can be used for junction partner 108 include, but are not limited to, In₂Se₃, In₂S₃, ZnS, ZnSe, CdInS, CdZnS, ZnIn₂Se₄, Zn₁₋ₓMgₓO, CdS, SnO₂, ZnO, ZrO₂ and doped ZnO.

Layer 110 is the counter electrode, which completes the functioning cell. Counter electrode 110 is used to draw current away from the junction since junction partner 108 is generally too resistive to serve this function. As such, counter electrode 110 should be highly conductive and transparent to light. Counter electrode 110 can in fact be a comb-like structure of metal printed onto layer 108 rather than forming a discrete layer. Counter electrode 110 is typically a transparent conductive oxide (TCO) such as doped zinc oxide (e.g., aluminum doped zinc oxide, gallium doped zinc oxide, boron doped zinc oxide), indium-tin-oxide (ITO), tin oxide (SnO₂), or indium-zinc oxide. However, even when a TCO layer is present, a bus bar network 114 is typically needed in conventional solar cells to draw off current since the TCO has too much resistance to efficiently perform this function in larger solar cells. Network 114 shortens the distance charge carriers must move in the TCO layer in order to reach the metal contact, thereby reducing resistive losses. The metal bus bars, also termed grid lines, can be made of any reasonably conductive metal such as, for example, silver, steel or aluminum. In the design of network 114, there is design a trade off between thicker grid lines that are more electrically conductive but block more light, and thin grid lines that are less electrically conductive but block less light. The metal bars are preferably configured in a comb-like arrangement to permit light rays through TCO layer 110. Bus bar network layer 114 and TCO layer 110, combined, act as a single metallurgical unit, functionally interfacing with a first ohmic contact to form a current collection circuit. In U.S. Pat. No. 6,548,751 to Sverdrup et al., hereby incorporated by reference herein in its entirety, a combined silver bus bar network and indium-tin-oxide layer function as a single, transparent ITO/Ag layer.

Layer 112 is an optional antireflective coating that allows a significant amount of extra light into the cell. Depending on the intended use of the cell, it might be deposited directly on the top conductor as illustrated in FIG. 1. Alternatively or additionally, antireflective coating 112 made be deposited on a separate cover glass that overlays top electrode 110. Ideally, the antireflective coating reduces the reflection of the cell to very near zero over the spectral region in which photoelectric absorption occurs, and at the same time increases the reflection in the other spectral regions to reduce heating. U.S. Pat. No. 6,107,564 to Aguilera et al., hereby incorporated by reference herein in its entirety, describes representative antireflective coatings that are known in the art.

Solar cells typically produce only a small voltage. For example, silicon based solar cells produce a voltage of about 0.6 volts (V). Thus, solar cells are interconnected in series or parallel in order to achieve greater voltages. When connected in series, voltages of individual cells add together while current remains the same. Thus, solar cells arranged in series reduce the amount of current flow through such cells, compared to analogous solar cells arranged in parallel, thereby improving efficiency. As illustrated in FIG. 1, the arrangement of solar cells in series is accomplished using interconnects 116. In general, an interconnect 116 places the first electrode of one solar cell in electrical communication with the counter-electrode of an adjoining solar cell.

As noted above and as illustrated in FIG. 1, conventional solar cells are typically in the form of a plate structure. Although such cells are highly efficient when they are smaller, larger planar solar cells have reduced efficiency because it is harder to make the semiconductor films that form the junction in such solar cells uniform. Furthermore, the occurrence of pinholes and similar flaws increase in larger planar solar cells. These features can cause shunts across the junction.

A number of problems are associated with solar cell designs present in the known art. A number of prior art solar cell designs and some of the disadvantages of each design will now be discussed.

As illustrated in FIG. 2A, U.S. Pat. No. 6,762,359 B2 to Asia et al. discloses a solar cell 210 including a p-type layer 12 and an n-type layer 14. A first electrode 32 is provided on one side of the solar cell. Electrode 32 is in electrical contact with n-type layer 14 of solar cell 210. Second electrode 60 is on the opposing side of the solar cell. Electrode 60 is in electrical contact with the p-type layer of the solar cell. Light-transmitting layers 200 and 202 form one side of device 210 while layer 62 forms the other side. Electrodes 32 and 60 are separated by insulators 40 and 50. In some instances, the solar cell has a tubular shape rather than the spherical shape illustrated in FIG. 2A. While device 210 is functional, it is unsatisfactory. Electrode 60 has to pierce absorber 12 in order to make an electrical contact. This results in a net loss in absorber area, making the solar cell less efficient. Furthermore, such a junction is difficult to make relative to other solar cell designs.

As illustrated in FIG. 2B, U.S. Pat. No. 3,976,508 to Mlavsky discloses a tubular solar cell including a cylindrical silicon tube 2 of n-type conductivity that has been subjected to diffusion of boron into its outer surface to form an outer p-conductivity type region 4 and thus a p-n junction 6. The inner surface of the cylindrical tube is provided with a first electrode in the form of an adherent metal conductive film 8 that forms an ohmic contact with the tube. Film 8 covers the entire inner surface of the tube and consists of a selected metal or metal alloy having relatively high conductivity, e.g., gold, nickel, aluminum, copper or the like, as disclosed in U.S. Pat. Nos. 2,984,775, 3,046,324 and 3005862. The outer surface is provided with a second electrode in the form of a grid consisting of a plurality of circumferentially extending conductors 10 that are connected together by one or more longitudinally-extending conductors 12. The opposite ends of the outer surface of the hollow tube are provided with two circumferentially-extending terminal conductors 14 and 16 that intercept the longitudinally-extending conductors 12. The spacing of the circumferentially-extending conductors 10 and the longitudinally-extending conductors 12 is such as to leave areas 18 of the outer surface of the tube exposed to solar radiation. Conductors 12, 14 and 16 are made wider than the circumferentially-extending conductors 10 since they carry a greater current than any of the latter. These conductors are made of an adherent metal film like the inner electrode 8 and form ohmic contacts with the outer surface of the tube. While the solar cell disclosed in FIG. 2B is functional, it is also unsatisfactory. Conductors 12, 14, and 16 are not transparent to light and therefore the amount of light that the solar cell receives is reduced.

Referring to FIGS. 2C and 2D, Japanese Patent Application Kokai Publication Number S59-125670, Toppan Printing Company, published Jul. 20, 1984 (hereinafter “S59-125670”) discloses a rod-shaped solar cell. The rod shaped solar cell is depicted in cross-section in FIG. 2C. A conducting metal is used as core 1 of the cell. A light-activated amorphous silicon semiconductor layer 3 is provided on core 1. An electrically conductive transparent conductive layer 4 is built up on top of semiconductor layer 3. The transparent conductive layer 4 can be made of materials such as indium oxide, tin oxide or indium tin oxide (ITO) and the like. As illustrated in FIG. 2C, a layer 5, made of a good electrical conductor, is provided on the lower portion of the solar cell. The publication states that this good conductive layer 5 is not particularly necessary but helps to lower the contact resistance between the rod and a conductive substrate 7 that serves as a counter-electrode. As such, conductive layer 5 serves as a current collector that supplements the conductivity of counter-electrode 7 illustrated in FIG. 2D.

As illustrated in FIG. 2D, rod-shaped solar cells 6 are multiply arranged in a row parallel with each other, and counter-electrode layer 7 is provided on the surface of the rods that is not irradiated by light so as to electrically make contact with each transparent conductive layer 4. The rod-shaped solar cells 6 are arranged in parallel and both ends of the solar cells are hardened with resin or a similar material in order to fix the rods in place.

S59-125670 addresses many of the drawbacks associated with planar solar cells. However, S59-125670 has a number of significant drawbacks that limit the efficiency of the disclosed devices. First, the manner in which current is drawn off the exterior surface is inefficient because layer 5 does not wrap all the way around the rod (e.g., see FIG. 2C). Second, substrate 7 is a metal plate that does not permit the passage of light. Thus, a full side of each rod is not exposed to light and can thus serve as a leakage path. Such a leakage path reduces the efficiency of the solar cell. For example, any such dark junction areas will result in a leakage that will detract from the photocurrent of the cell. Another disadvantage with the design disclosed in FIGS. 2C and 2D is that the rods are arranged in parallel rather than in series. Thus, the current levels in such devices will be large, relative to a corresponding serially arranged model, and therefore subject to resistive losses.

Referring to FIG. 2E, German Unexamined Patent Application DE 43 39 547 A1 to Twin Solar-Technik Entwicklungs-GmbH, published May 24, 1995, (hereinafter “Twin Solar”) also discloses a plurality of rod-shaped solar cells 2 arranged in a parallel manner inside a transparent sheet 28, which forms the body of the solar cell. Thus, Twin Solar does not have some of the drawbacks found in S59-125670. Transparent sheet 28 allows light in from both faces 47A and 47B. Transparent sheet 28 is installed at a distance from a wall 27 in such a manner as to provide an air gap 26 through which liquid coolant can flow. Thus, Twin Solar devices have the drawback that they are not truly bifacial. In other words, only face 47A of the Twin Solar device is capable of receiving direct light. As defined here, “direct light” is light that has not passed through any media other than air. For example, light that has passed through a transparent substrate, into a solar cell assembly and exited the assembly, is no longer direct light once it exits the solar cell assembly. Light that has merely reflected off of a surface, however, is direct light provided that it has not passed through a solar cell assembly. Under this definition of direct light, face 47B is not configured to receive direct light. This is because all light received by face 47B must first traverse the body of the solar cell apparatus after entering the solar cell apparatus through face 47A. Such light must then traverse cooling chamber 26, reflect off back wall 42, and finally re-enter the solar cell through face 47B. The solar cell assembly is therefore inefficient because direct light cannot enter both sides of the assembly.

Although tubular designs of solar cells have addressed many of the drawbacks associated with planar solar cells, some problems remain unresolved. The capacity of solar cells to withstand physical shock is one unresolved problem. Conventional solar cell panels often crack over time. Solar cell assemblies are often built from small individual solar cell units. This approach provides efficiency and flexibility. Smaller solar cells are easier to manufacture on a large scale, and they can also be assembled into different sizes and shapes to suit the ultimate application. Inevitably, the smaller solar cell unit design also comes with the price of fragility. The smaller solar cell units easily break under pressure during transportation or routine handling processes. What are needed in the art are methods and systems that provide support and strength to solar cell units while maintaining the advantages of the small design.

Discussion or citation of a reference herein will not be construed as an admission that such reference is prior art to the present application.

### 3. SUMMARY

A solar cell unit including a solar cell and an at least partially transparent casing that encases the solar cell. The solar cell includes a nonplanar substrate defining a length of the solar cell, wherein a length of the nonplanar substrate is at least three times longer than a width of the nonplanar substrate. A back-electrode is disposed around all or a portion of the nonplanar substrate, and extends along all or a portion of the length of the nonplanar substrate. A semiconductor junction is disposed on the back-electrode, and has first and second layers, each of which has an inorganic semiconductor. An at least partially transparent conductive layer is disposed on the semiconductor junction. Optionally, filler material is disposed on the transparent conductive layer, which can for example be a liquid or gel.

### 4. BRIEF DESCRIPTION OF THE DRAWINGS

FIG. 1 illustrates interconnected solar cells in accordance with the prior art.

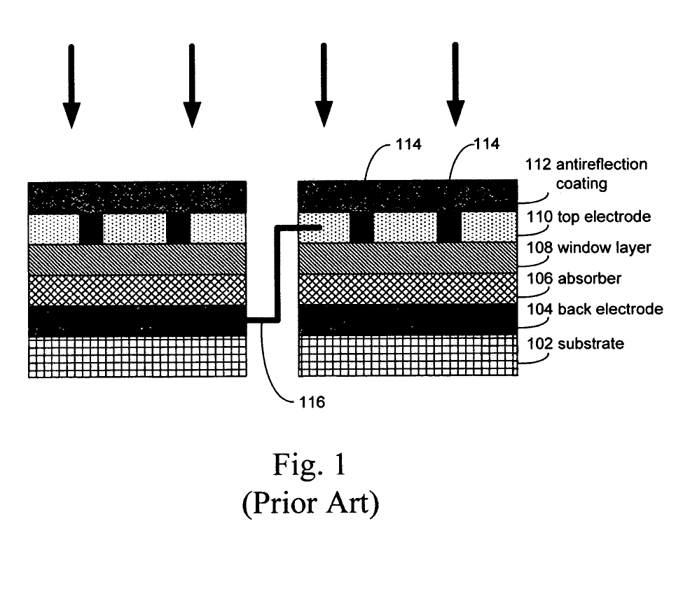

FIG. 2A illustrates a spherical solar cell including a p-type inner layer and an n-type outer layer in accordance with the prior art.

FIG. 2B illustrates a tubular photovoltaic element including a cylindrical silicon tube of n-type conductivity that has been subjected to diffusion of boron into its outer surface to form an outer p-conductivity type region and thus a tubular solar cell in accordance with the prior art.

FIG. 2C is a cross-sectional view of an elongated solar cell in accordance with the prior art.

FIG. 2D is a cross-sectional view of a solar cell assembly in which a plurality of elongated solar cells are affixed to an electrically conductive substrate in accordance with the prior art.

FIG. 2E is a cross-sectional view of a solar cell assembly disposed a distance away from a reflecting wall in accordance with the prior art.

FIG. 3A illustrates a photovoltaic element with a casing, in accordance with an embodiment of the present application.

FIG. 3B illustrates a cross-sectional view of an elongated solar cell in a transparent casing, in accordance with an embodiment of the present application.

FIG. 3C illustrates the multi-layer components of an elongated solar cell in accordance with an embodiment of the present application.

FIG. 3D illustrates a transparent casing, in accordance with an embodiment of the present application.

FIGS. 3F-3O illustrate hermetically sealed elongated solar cells, in accordance with some embodiments of the present application.

FIG. 4A is a cross-sectional view of elongated solar cells in a casing that are electrically arranged in series and geometrically arranged in a parallel or near parallel manner, in accordance with an embodiment of the present application.

FIG. 4B is a cross-sectional view taken about line 4B-4B of FIG. 4A depicting the serial electrical arrangement of solar cells in an assembly, in accordance with an embodiment of the present application.

FIG. 4C is a blow-up perspective view of region 4C of FIG. 4B, illustrating various layers in elongated solar cells, in accordance with one embodiment of the present application.

FIG. 4D is a cross-sectional view of an elongated solar cell taken about line 4D-4D of FIG. 4B, in accordance with an embodiment of the present application.

FIGS. 5A-5D illustrate semiconductor junctions that are used in various elongated solar cells in various embodiments of the present application.

FIG. 6A illustrates an extrusion blow molding method, in accordance with the prior art.

FIG. 6B illustrates an injection blow molding method, in accordance with the prior art.

FIG. 6C illustrates a stretch blow molding method, in accordance with the prior art.

FIG. 7A is a cross-sectional view of elongated solar cells electrically arranged in series in an assembly where counter-electrodes abut individual solar cells, in accordance with another embodiment of the present application.

FIG. 7B is a cross-sectional view taken about line 7B-7B of FIG. 7A that depicts the serial arrangement of the cylindrical solar cells in an assembly, in accordance with an embodiment of the present application.

FIG. 7C is a perspective view an array of alternating casings, in accordance with an embodiment of the present application.

FIG. 8 is a cross-sectional view of elongated solar cells electrically arranged in series in an assembly where counter-electrodes abut individual solar cells and the outer TCO is cut, in accordance with another embodiment of the present application.

FIG. 9 is a cross-sectional view of elongated solar cells electrically arranged in series in an assembly in which the inner metal electrode is hollowed, in accordance with an embodiment of the present application.

FIG. 10 is a cross-sectional view of elongated solar cells electrically arranged in series in an assembly in which a groove pierces the counter-electrodes, transparent conducting oxide layer, and junction layers of the solar cells, in accordance with an embodiment of the present application.

FIG. 11 illustrates a static concentrator for use in some embodiments of the present application.

FIG. 12 illustrates a static concentrator used in some embodiments of the present application.

FIG. 13 illustrates a cross-sectional view of a solar cell in accordance with an embodiment of the present application.

FIG. 14 illustrates a molded casing in accordance with some embodiments of the present application.

FIG. 15 illustrates a perspective view of an elongated solar cell architecture with protruding electrode attachments, in accordance with an embodiment of the present application.

FIG. 16 illustrates a perspective view of a solar cell architecture in accordance with an embodiment of the present application.

FIG. 17A illustrates light reflection on a specular surface, in accordance with the prior art.

FIG. 17B illustrates light reflection on a diffuse surface, in accordance with the prior art.

FIG. 17C illustrates light reflection on a Lambertian surface, in accordance with the prior art.

FIG. 18A illustrates a circle and an involute of the circle, in accordance with the prior art

FIG. 18B illustrates a cross-sectional view of a solar cell architecture in accordance with an embodiment of the present application.

FIG. 19 illustrates a cross-sectional view of an array of alternating casings and internal reflectors, in accordance with an embodiment of the present application.

FIG. 20A illustrates a suction loading assembly method in accordance with the present application.

FIG. 20B illustrates a pressure loading assembly method in accordance with the present application.

FIG. 20C illustrates a pour-and-slide loading assembly method in accordance with the present application.

FIG. 21 illustrates a partial cross-sectional view of an elongated solar cell in a transparent casing, in accordance with an embodiment of the present application.

FIG. 22 illustrates Q-type silicone, silsequioxane, D-type silicone, and M-type silicone, in accordance with the prior art.

FIG. 23 illustrates a method of making a solar cell assembly in accordance with various embodiments of the present application.

FIG. 24 illustrates a method of forming a semiconductor junction in accordance with various embodiments of the present application.

FIG. 25 illustrates various solar energy spectra in accordance with the prior art that are commonly used to determine electrical characteristics of solar cells, typically in conjunction with the use of a reference solar cell such as one based upon doped silicon.

Like reference numerals refer to corresponding parts throughout the several views of the drawings. Dimensions are not drawn to scale.

### 5. DETAILED DESCRIPTION

Disclosed herein are nonplanar solar cell assemblies for converting solar energy into electrical energy and more particularly to improved solar cells and solar cell arrays.

### 5.1 Basic Structure

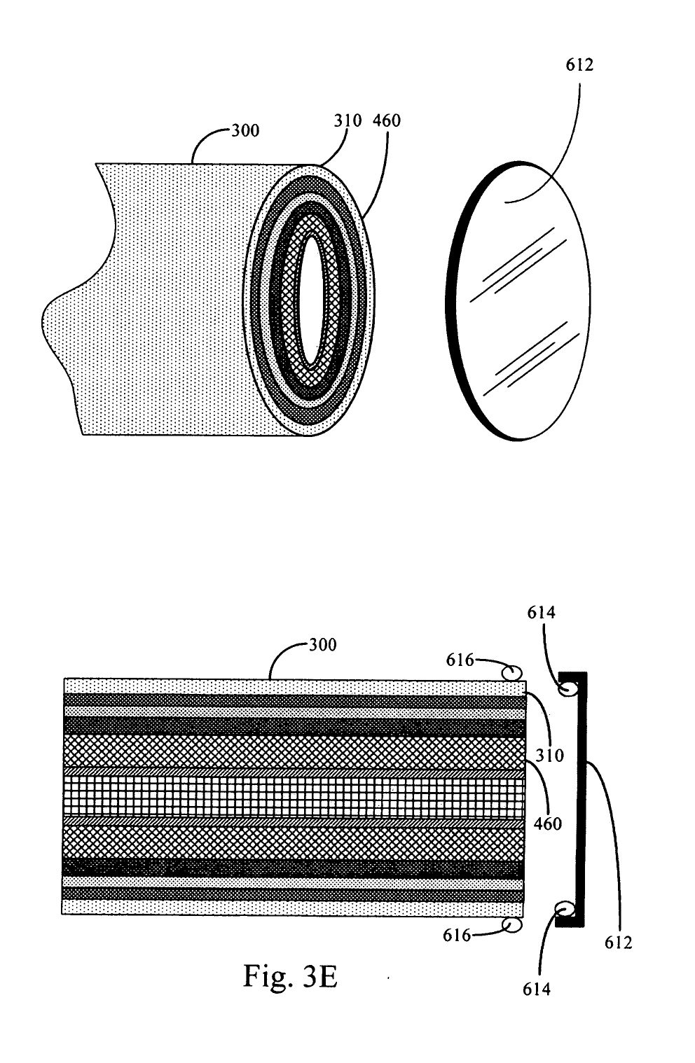

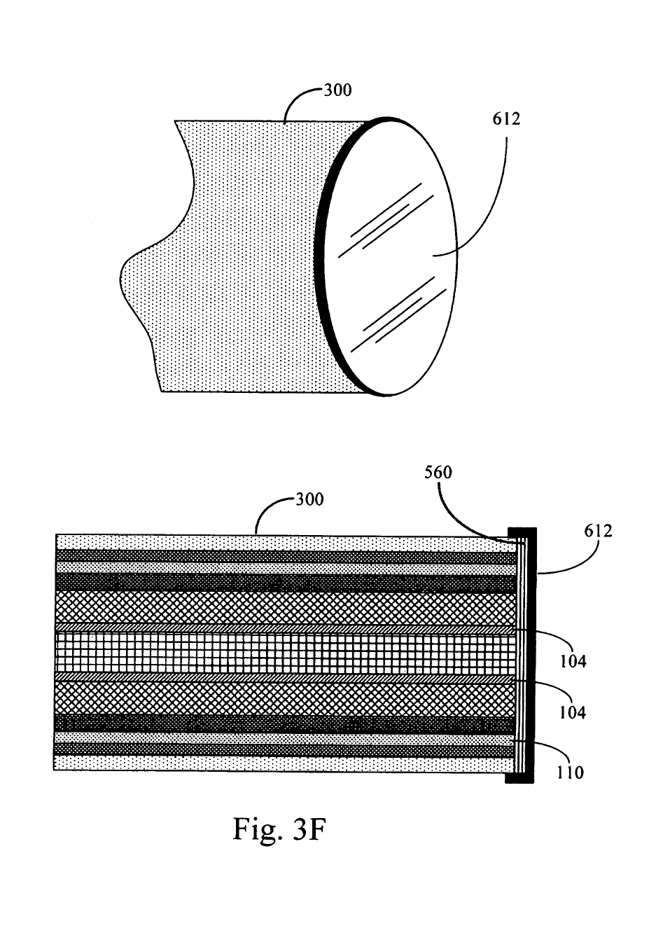

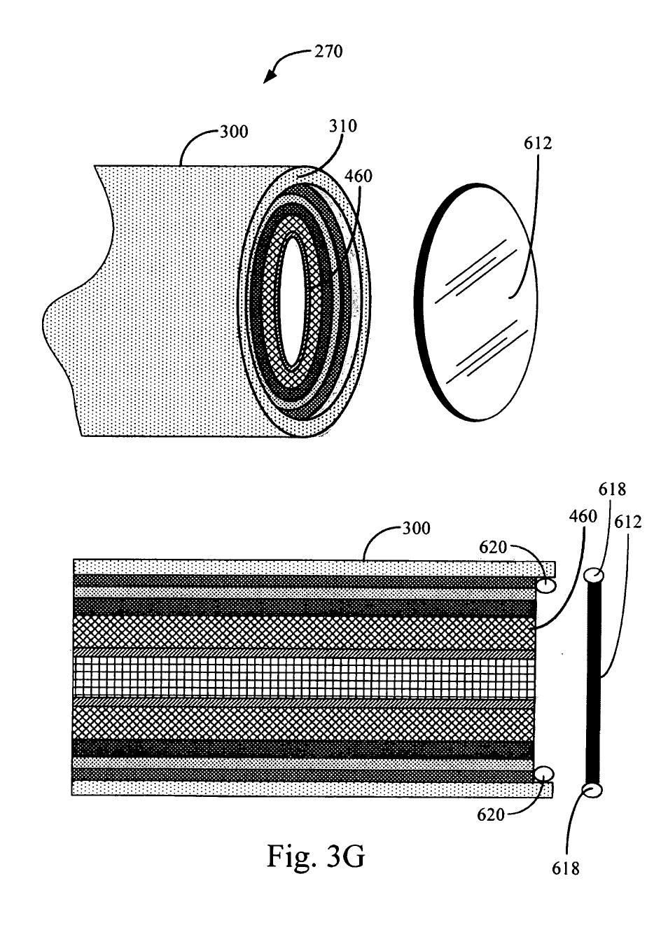

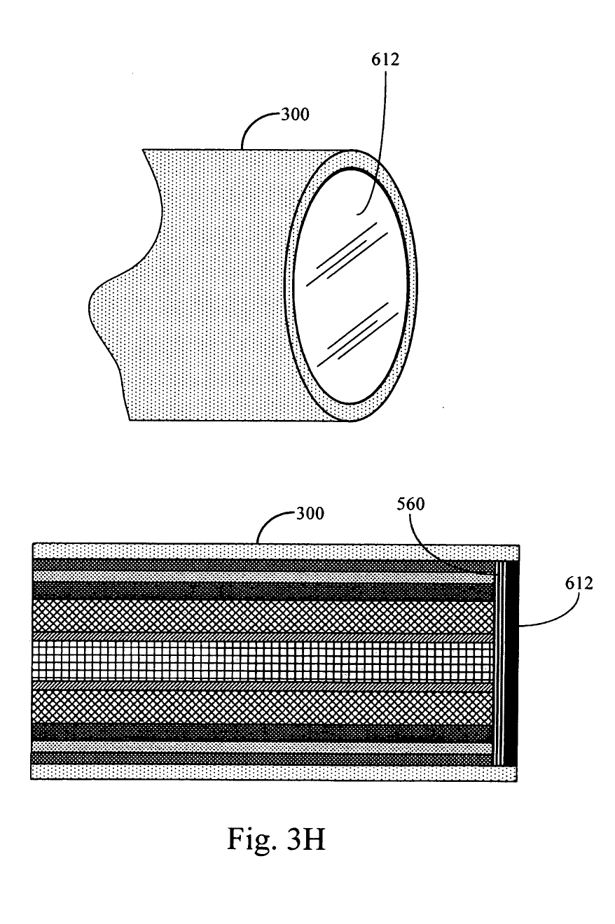

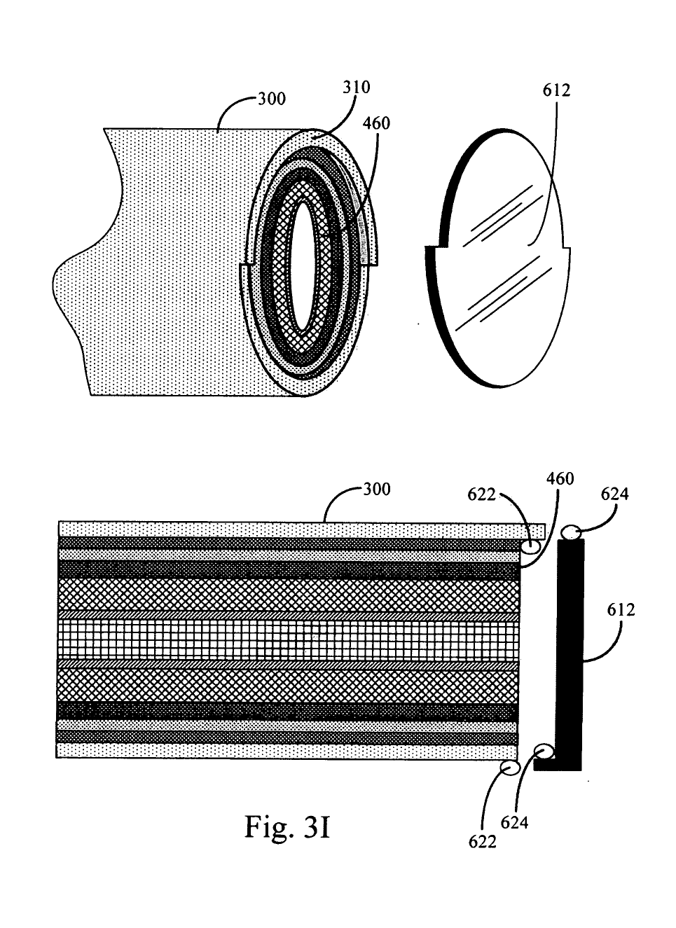

The present application provides nonplanar (e.g., cylindrical) solar cell units, such as the solar cell units 300 that are illustrated in perspective view in FIG. 3A and cross-sectional view in FIG. 3B. In a solar cell unit 300, an elongated nonplanar solar cell 402 (FIG. 3C) is encased by a transparent casing 310 (FIG. 3D). In some embodiments, the solar cell unit 300 includes a solar cell 402 coated with a transparent casing 310. In some embodiments, only one end of the elongated solar cell 402 is exposed by the transparent casing 310 in order to form an electrical connection with the adjacent solar cells 402 or other circuitry. In some embodiments, both ends of the elongated solar cell 402 are exposed by the transparent casing 310 in order to form an electrical connection with the adjacent solar cells 402 or other circuitry. As discussed in greater detail below, in some embodiments one or both ends of the elongated solar cell 402 are hermetically sealed with a cap. In some embodiments, such as those illustrated in FIGS. 3A, 3B, and 3D, the transparent casing has a cylindrical shape. As used herein, the term “cylindrical” means objects having a cylindrical or approximately cylindrical shape. In fact, cylindrical objects can have irregular shapes so long as the object, taken as a whole, is roughly cylindrical. Such cylindrical shapes can be solid (e.g., a rod) or hollowed (e.g., a tube). As used herein, the term tubular means objects having a tubular or approximately tubular shape. In fact, tubular objects can have irregular shapes so long as the object, taken as a whole, is roughly tubular.

Although most discussion in the present application pertaining to the solar cell units 300 is in the context of encapsulated embodiments, it is to be appreciated that such discussions serve as no limitation to the scope of the present application. Any transparent casing that provides support and protection to nonplanar solar cells and permits electrical connections between the nonplanar solar cells is within the scope of the systems and methods of the present application. Not all embodiments include casings.

A description of exemplary solar cells 402 is provided in this section as well as Sections 5.2 through 5.8. For instance, examples of semiconductor junctions that can be used in the solar cells 402 is in Section 5.2. Exemplary systems and methods for manufacturing the transparent casing 310 is in Section 5.1.2. Systems and methods for encasing the solar cells 402 with transparent casing 310 in order to form the solar cell units 300 is found in Section 5.1.3. Solar cell units 300 can be assembled into solar cell assemblies of various sizes and shapes to generate electricity and potentially heat water or other fluids.

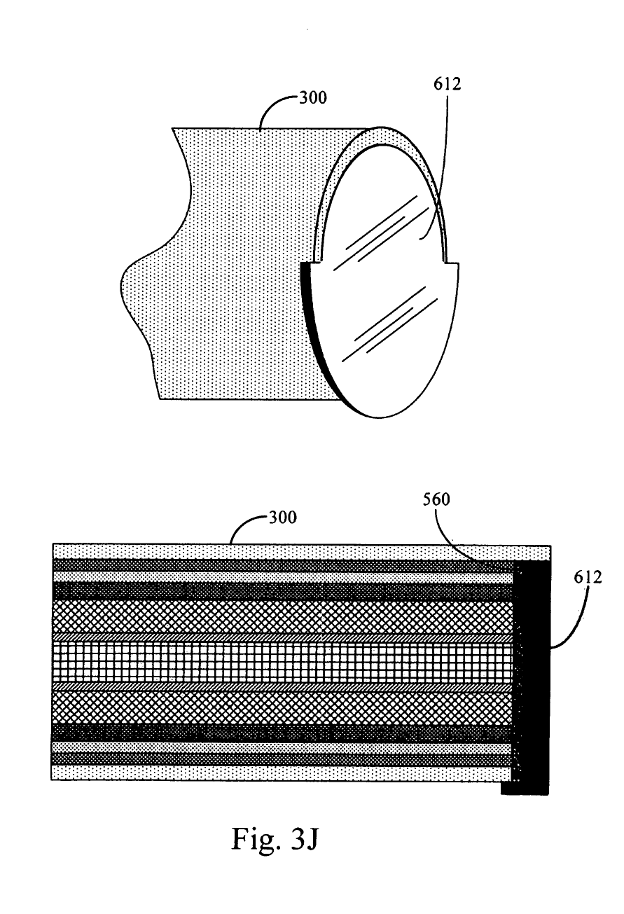

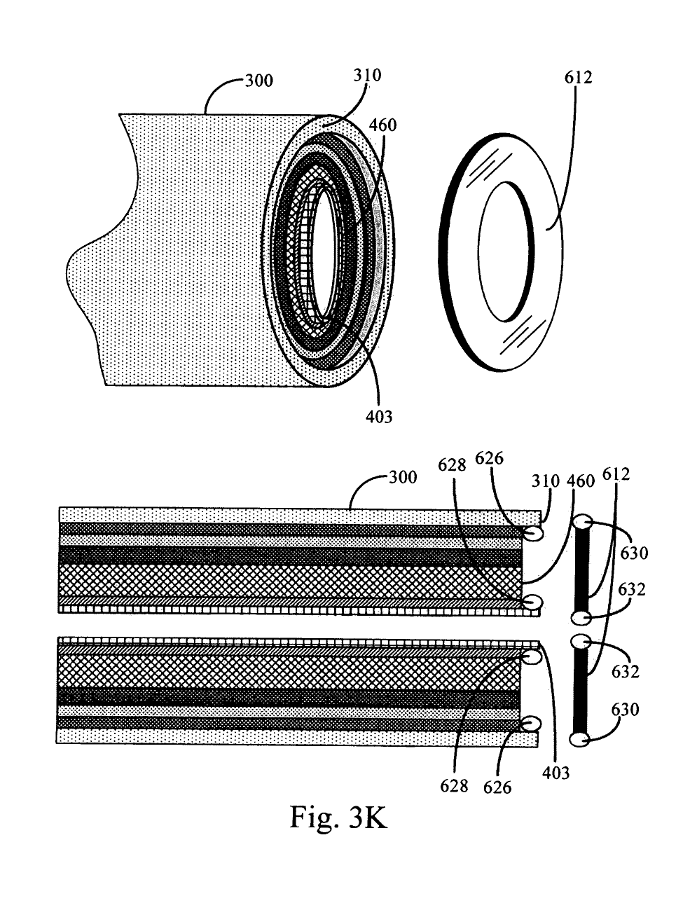

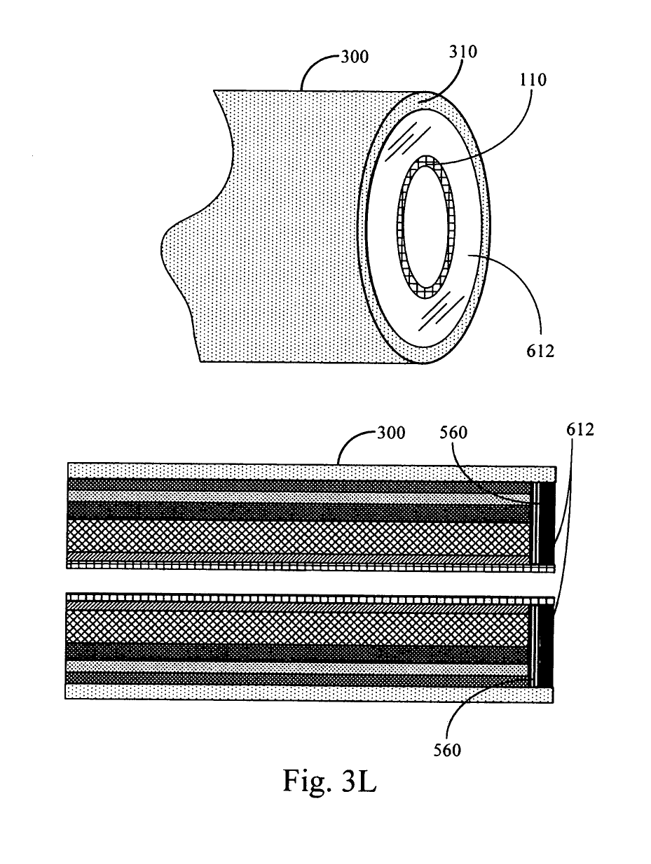

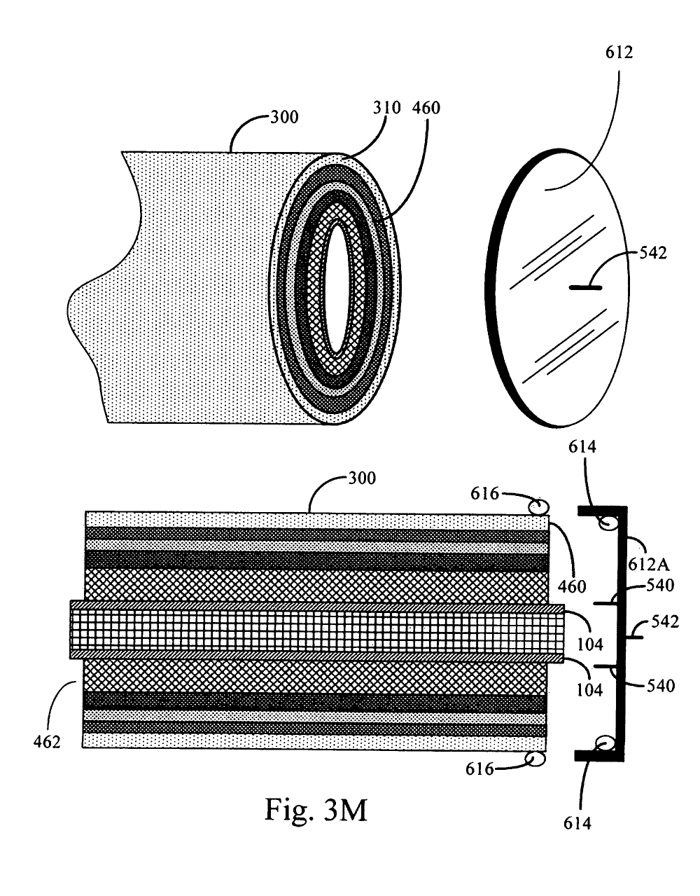

FIG. 3B illustrates the cross-sectional view of an exemplary embodiment of the solar cell unit 300. Other exemplary embodiments of solar cells (e.g., 402 in FIG. 4A) are also suitable for coating by the transparent casing 310.

In some embodiments, the solar cell units 300 are arranged in parallel rows to form a planar assembly. The solar cell units 300 may be electrically connected in series or parallel. In some embodiments, some solar cell units 300 in the assembly are electrically arranged in series and some are electrically arranged in parallel. In some embodiments, some of the solar cell units 300 are directly contacting other solar cell units 300 in the assembly. In some embodiments, each solar cell unit 300 is spaced at least 1 micron, at least 2 microns, at least 3 microns, at least 4 microns, at least 5 microns, at least 100 microns, or at least 500 microns away from neighboring solar cell units 300. In some such embodiments, solar cell units 300 in the assembly are electrically isolated from neighboring solar cell units in the assembly. In some embodiments, each solar cell unit 300 is spaced at least 1 centimeter, at least 2 centimeters, at least 3 centimeters, at least 4 centimeters, at least 5 centimeters, at least 100 centimeters, or at least 500 centimeters away from neighboring solar cell units 300. In some such embodiments, the solar cell units 300 in the assembly are electrically isolated from neighboring solar cell units in the assembly.

Substrate 403. Nonplanar substrate 403 serves as a substrate for the solar cell 402, and defines a length of the solar cell 402. In some embodiments, a length of the substrate 403 is at least three times longer than a width of the substrate. In some embodiments, the substrate 403 is made of a plastic, metal, metal alloy, or glass. In some embodiments, the substrate 403 is cylindrically shaped. In some embodiments, the substrate 403 is nonplanar. In some embodiments, the substrate 403 has a hollow core, as illustrated in FIG. 3B. In some embodiments, the substrate 403 has a solid core. In some embodiments, the shape of the substrate 403 is approximately that of a cylindrical object, meaning that a cross-section taken at a right angle to the long axis of the substrate 403 defines an ellipse rather than a circle. As the term is used herein, such approximately shaped objects are still considered cylindrically shaped in the present application.

The present application is not limited to elongated solar cell units and substrates that have rigid cylindrical shapes or are hollow or solid rods. In some embodiments, all or a portion of the substrate 403 can be characterized by a cross-section bounded by any one of a number of shapes other than circular or elliptical. The bounding shape can be ovoid, or any shape characterized by one or more smooth curved surfaces, or any splice of smooth curved surfaces. The bounding shape can also be an n-gon, where n is 3, 5, or greater than 5. The bounding shape can also be linear in nature, including triangular, rectangular, pentangular, hexagonal, or having any number of linear segmented surfaces. Or, the cross-section can be bounded by any combination of linear surfaces, arcuate surfaces, or curved surfaces.

In some embodiments, a first portion of the substrate 403 is characterized by a first cross-sectional shape and a second portion of the substrate 403 is characterized by a second cross-sectional shape, where the first and second cross-sectional shapes are the same or different. In some embodiments, at least zero percent, at least ten percent, at least twenty percent, at least thirty percent, at least forty percent, at least fifty percent, at least sixty percent, at least seventy percent, at least eighty percent, at least ninety percent, or all of the length of the substrate 403 is characterized by the first cross-sectional shape, and some or all of the remainder of the length of the substrate is characterized by the second cross-sectional shape. In some embodiments, the first cross-section shape is planar (e.g., has no arcuate side), and the second cross-sectional shape has at least one arcuate side.

In some embodiments, substrate 403 is made of a urethane polymer, an acrylic polymer, a fluoropolymer, polybenzamidazole, polyimide, polytetrafluoroethylene, polyetheretherketone, polyamide-imide, glass-based phenolic, polystyrene, cross-linked polystyrene, polyester, polycarbonate, polyethylene, polyethylene, acrylonitrile-butadiene-styrene, polytetrafluoro-ethylene, polymethacrylate, nylon 6,6, cellulose acetate butyrate, cellulose acetate, rigid vinyl, plasticized vinyl, or polypropylene. In some embodiments, substrate 403 is made of aluminosilicate glass, borosilicate glass (e.g., PYREX, DURAN, SIMAX, etc.), dichroic glass, germanium/semiconductor glass, glass ceramic, silicate/fused silica glass, soda lime glass, quartz glass, chalcogenide/sulphide glass, fluoride glass, PYREX glass, a glass-based phenolic, cereated glass, or flint glass. In some embodiments, substrate 403 is a solid cylindrical shape. Such solid cylindrical substrates 403 can be made out of a plastic, glass, metal, or metal alloy.

In some embodiments, the substrate 403 and/or the transparent casing 310 is rigid. Rigidity of a material can be measured using several different metrics including, but not limited to, Young's modulus. In solid mechanics, Young's Modulus (E) (also known as the Young Modulus, modulus of elasticity, elastic modulus, or tensile modulus) is a measure of the stiffness of a given material. It is defined as the ratio, for small strains, of the rate of change of stress with strain. This can be experimentally determined from the slope of a stress-strain curve created during tensile tests on a sample of the material. Young's Modulus for various materials is given in the following table.

| | Young's | |
|---|---|---|
| | modulus | Young's modulus |
| Material | (E) in GPa | (E) in lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced plastic | 150 | 21,800,000 |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments, a material (e.g., the substrate 403, the transparent casing 310, etc.) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments, a material (e.g., the substrate 403, the transparent casing 310, etc.) is deemed to be rigid when the Young's Modulus for the material is constant over a range of strains. Such materials are called linear, and are deemed to obey Hooke's Law. Examples of linear material include, but are not limited to, steel, carbon fiber, and glass. Rubber and soil (except at negligible strains) are non-linear materials. In some embodiments, a material is considered rigid when it adheres to the small deformation theory of elasticity, when subjected to any amount of force in a large range of forces (e.g., between 1 dyne and 10⁵ dynes, between 100 dynes and 10⁶ dynes, between 10,000 dynes and 10⁷ dynes), such that the material only undergoes small elongations or shortenings or other deformations when subject to such force. The requirement that the deformations (or gradients of deformations) of such exemplary materials are small means, mathematically, that the square of either of these quantities is negligibly small when compared to the first power of the quantities when exposed so such a force. Another way of stating the requirement for a rigid material is that such a material does not visibly deform over a large range of forces (e.g., between 1 dyne and 10⁵ dynes, between 1000 dynes and 10⁶ dynes, between 10,000 and 10⁷ dynes). Still another way of stating the requirement for a rigid material is that such a material, over a large range of forces (e.g., between 1 dyne and 10⁵ dynes, between 1000 dynes and 10⁶ dynes, between 10,000 and 10⁷ dynes), by a strain tensor that only has linear terms. The strain tensor for materials is described in Borg, 1962, Fundamentals of Engineering Elasticity, Princeton, N.J., pp. 36-41, which is hereby incorporated by reference herein in its entirety. In some embodiments, a material is considered rigid when a sample of sufficient size and dimensions does not visibly bend under the force of gravity.

In general, the extent to which a body (e.g., the substrate 401, the casing 310, etc.) deflects under a force, e.g., the stiffness of the body, is related to the Young's Modulus of the material from which it is made, the body's length and cross-sectional dimensions, and the force applied to the body, as is known to those of ordinary skill in the art. In some embodiments, the Young's Modulus of the body material, and the body's length and cross-sectional area, are selected such that the body (e.g., the substrate 401, casing 310, etc.) substantially does not visibly deflect (bend) when a first end of the body is subjected to a force of, e.g., between 1 dyne and 10⁵ dynes, between 100 dynes and 10⁶ dynes, or between 10,000 dynes and 10⁷ dynes, while a second end of the body is held fixed. In some embodiments, the Young's Modulus of the body material, and the body's length and cross-sectional area, are selected such that the body (e.g., the substrate 401, casing 310, etc.) substantially does not visibly deflect when a first end of the body is subjected to the force of gravity, while a second end of the body is held fixed.

In some embodiments, a cross-section of the substrate 403 is circumferential and has an outer diameter of between 3 mm and 100 mm, between 4 mm and 75 mm, between 5 mm and 50 mm, between 10 mm and 40 mm, or between 14 mm and 17 mm. In some embodiments, a cross-section of the substrate 403 is circumferential and has an outer diameter of between 1 mm and 1000 mm.

In some embodiments, the substrate 403 is a tube with a hollowed inner portion. In such embodiments, a cross-section of substrate 403 is characterized by an inner radius defining the hollowed interior and an outer radius. The difference between the inner radius and the outer radius is the thickness of the substrate 403. In some embodiments, the thickness of the substrate 403 is between 0.1 mm and 20 mm, between 0.3 mm and 10 mm, between 0.5 mm and 5 mm, or between 1 mm and 2 mm. In some embodiments, the inner radius is between 1 mm and 100 mm, between 3 mm and 50 mm, or between 5 mm and 10 mm.

In some embodiments, the substrate 403 has a length (perpendicular to the plane defined by FIG. 3B) that is between 5 mm and 10,000 mm, between 50 mm and 5,000 mm, between 100 mm and 3000 mm, or between 500 mm and 1500 mm. In one embodiment, the substrate 403 is a hollowed tube having an outer diameter of 15 mm and a thickness of 1.2 mm, and a length of 1040 mm. Although the substrate 403 is shown as solid in FIG. 3B, it will be appreciated that in many embodiments, the substrate 403 will have a hollow core and will adopt a rigid tubular structure such as that formed by a glass tube.

In some embodiments, the substrate 403 has a width dimension and a longitudinal dimension. In some embodiments, the longitudinal dimension of the substrate 403 is much larger than the width dimension (e.g., at least four times greater than the width dimension., at least five times greater than the width dimension, at least six times greater than the width dimension, etc.). In some embodiments, the longitudinal dimension of the substrate 403 is 10 cm or greater. In other embodiments, the longitudinal dimension of the substrate 403 is 50 cm or greater. In some embodiments, the width dimension of the substrate 403 is 1 cm or greater. In other embodiments, the width dimension of the substrate 403 is 5 cm or greater. In yet other embodiments, the width dimension of the elongated substrate 403 is 10 cm or greater.

Back-electrode 404. A back-electrode 404 is disposed on all or a portion of the substrate 403. By “a portion of” it is meant at least 20%, or at least 30%, or at least 40%, or at least 50%, or at least 60%, or at least 70%, or at least 80%, or at least 90%, or at least 95% of the surface area of the substrate 403. Back-electrode 404 serves as the first electrode in the assembly. In general, back-electrode 404 is made out of any material such that it can support the photovoltaic current generated by solar cell unit 300 with negligible resistive losses. In some embodiments, back-electrode 404 includes any suitable conductive material, such as aluminum, molybdenum, tungsten, vanadium, rhodium, niobium, chromium, tantalum, titanium, steel, nickel, platinum, silver, gold, an alloy thereof, or any combination thereof. In some embodiments, back-electrode 404 includes any suitable conductive material, such as indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic. As defined herein, a conductive plastic is one that, through compounding techniques, contains conductive fillers which, in turn, impart their conductive properties to the plastic. In some embodiments, conductive plastics used in back-electrode 404 contain fillers that form sufficient conductive current-carrying paths through the plastic matrix to support the photovoltaic current generated by solar cell unit 300 with negligible resistive losses. The plastic matrix of the conductive plastic is typically insulating, but the composite produced exhibits the conductive properties of the filler.

Semiconductor junction 410. A semiconductor junction 410 is disposed on all or a portion of the back-electrode 404. By “a portion of” it is meant at least 20%, or at least 30%, or at least 40%, or at least 50%, or at least 60%, or at least 70%, or at least 80%, or at least 90%, or at least 95% of the surface area of the back-electrode 404. Semiconductor junction 410 is any photovoltaic homojunction, heterojunction, heteroface junction, buried homojunction, a p-i-n junction or a tandem junction having an absorber layer that is a direct band-gap absorber (e.g., crystalline silicon) or an indirect band-gap absorber (e.g., amorphous silicon). Such junctions are described in Chapter 1 of Bube, Photovoltaic Materials, 1998, Imperial College Press, London, as well as Lugue and Hegedus, 2003, Handbook of Photovoltaic Science and Engineering, John Wiley & Sons, Ltd., West Sussex, England, each of which is hereby incorporated by reference herein in its entirety. Details of exemplary types of semiconductors junctions 410 in accordance with the present application are disclosed in Section 5.2, below. In addition to the exemplary junctions disclosed in Section 5.2, below, junctions 410 can be multijunctions in which light traverses into the core of junction 410 through multiple junctions that, in some embodiments, have successfully smaller band gaps. In some embodiments, semiconductor junction 410 includes a copper-indium-gallium-diselenide (CIGS) absorber layer. In some embodiments, the semiconductor junction 410 is a so-called thin film semiconductor junction; in other embodiments the semiconductor junction is a so-called thick film (e.g., silicon) semiconductor junction.

Optional intrinsic layer 415. Optionally, there is a thin intrinsic layer (i-layer) 415 disposed on all or a portion of the semiconductor junction 410. By “a portion of” it is meant at least 20%, or at least 30%, or at least 40%, or at least 50%, or at least 60%, or at least 70%, or at least 80%, or at least 90%, or at least 95% of the surface area of the semiconductor junction 410. The i-layer 415 can be formed using any undoped transparent oxide including, but not limited to, zinc oxide, metal oxide, or any transparent material that is highly insulating. In some embodiments, i-layer 415 is highly pure zinc oxide.

Transparent conductive layer 412. Transparent conductive layer 412 is disposed on all or a portion of the semiconductor junction layer 410 thereby completing the circuit. By “portion of” it is meant at least 20%, or at least 30%, or at least 40%, or at least 50%, or at least 60%, or at least 70%, or at least 80%, or at least 90%, or at least 95% of the surface area of the semiconductor junction layer 410. As noted above, in some embodiments, a thin i-layer 415 is disposed on all or a portion of the semiconductor junction 410. In such embodiments, transparent conductive layer 412 is disposed on all or a portion of i-layer 415.

In some embodiments, transparent conductive layer 412 includes tin oxide SnOₓ (with or without fluorine doping), indium-tin oxide (ITO), doped zinc oxide (e.g., aluminum doped zinc oxide, gallium doped zinc oxide, boron dope zinc oxide), indium-zinc oxide or any combination thereof. In some embodiments, transparent conductive layer 412 is either p-doped or n-doped. In some embodiments, transparent conductive layer includes carbon nanotubes. Carbon nanotubes are commercially available, for example from Eikos (Franklin, Mass.) and are described in U.S. Pat. No. 6,988,925, which is hereby incorporated by reference herein in its entirety. For example, in embodiments where the outer semiconductor layer of junction 410 is p-doped, transparent conductive layer 412 can be p-doped. Likewise, in embodiments where the outer semiconductor layer of junction 410 is n-doped, transparent conductive layer 412 can be n-doped. In general, transparent conductive layer 412 is usefully made of a material that has relatively or very low resistance, suitable optical transmission properties (e.g., greater than 90%), and a deposition temperature that will not damage underlying layers of semiconductor junction 410 and/or optional i-layer 415. In some embodiments, transparent conductive layer 412 includes an electrically conductive polymer material such as a conductive polythiophene, a conductive polyaniline, a conductive polypyrrole, a PSS-doped PEDOT (e.g., Bayrton), or a derivative of any of the foregoing. In some embodiments, transparent conductive layer 412 includes more than one layer, including a first layer including tin oxide SnOₓ (with or without fluorine doping), indium-tin oxide (ITO), indium-zinc oxide, doped zinc oxide (e.g., aluminum doped zinc oxide, gallium doped zinc oxide, boron dope zinc oxide) or a combination thereof and a second layer including a conductive polythiophene, a conductive polyaniline, a conductive polypyrrole, a PSS-doped PEDOT (e.g., Bayrton), or a derivative of any of the foregoing. Additional suitable materials that can be used to form transparent conductive layer are disclosed in United States Patent publication 2004/0187917A1 to Pichler, which is hereby incorporated by reference herein in its entirety.

Optional electrode strips 420. In some embodiments in accordance with the present application, optional counter-electrode strips or leads 420 are disposed on the transparent conductive layer 412 in order to facilitate electrical current flow. In some embodiments, the electrode strips 420 are thin strips of electrically conducting material that run lengthwise along the long axis the elongated, nonplanar solar cell, as depicted in FIG. 4A. In some embodiments, optional electrode strips are positioned at spaced intervals on the surface of the transparent conductive layer 412. For instance, FIG. 3B, electrode strips 420 run parallel to each other and are spaced out at ninety degree intervals along the long axis of the solar cell. In some embodiments, electrode strips 420 are spaced out at five degree, ten degree, fifteen degree, twenty degree, thirty degree, forty degree, fifty degree, sixty degree, ninety degree or 180 degree intervals on the surface of transparent conductive layer 412. In some embodiments, there is a single electrode strip 420 on the surface of transparent conductive layer 412. In some embodiments, there is no electrode strip 420 on the surface of transparent conductive layer 412. In some embodiments, there is two, three, four, five, six, seven, eight, nine, ten, eleven, twelve, fifteen or more, or thirty or more electrode strips on the transparent conductive layer 412, all running parallel, or near parallel, to each other down the long axis of the solar cell. In some embodiments electrode strips 420 are evenly spaced about the outer surface of transparent conductive layer 412, for example, as depicted in FIG. 3B. In alternative embodiments, the electrode strips 420 are not evenly spaced about the outer surface of the transparent conductive layer 412. In some embodiments, electrode strips 420 are only on one face of the solar cell. Elements 403, 404, 410, 415 (optional), and 412 of FIG. 3B collectively include solar cell 402 of FIG. 3A. In some embodiments, the electrode strips 420 are made of conductive epoxy, conductive ink, copper or an alloy thereof, aluminum or an alloy thereof, nickel or an alloy thereof, silver or an alloy thereof, gold or an alloy thereof, a conductive glue, or a conductive plastic.

In some embodiments, there are electrode strips that run along the long axis of the solar cell and these electrode strips are interconnected to each other by grid lines. These grid lines can be thicker than, thinner than, or the same width as the electrode strips. These grid lines can be made of the same or different electrically material as the electrode strips.

In some embodiments, the electrode strips 420 are deposited on the transparent conductive layer 412 using ink jet printing. Examples of conductive ink that can be used for such strips include, but are not limited to silver loaded or nickel loaded conductive ink. In some embodiments epoxies as well as anisotropic conductive adhesives can be used to construct the electrode strips 420. In typical embodiments, such inks or epoxies are thermally cured in order to form the electrode strips 420.

Optional filler material 330. In some embodiments of the present application, as depicted in FIG. 3B, a filler material 330 includes, for example, a sealant such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane is overlayed on transparent conductive layer 412. In some embodiments, filler material 330 is a Q-type silicone, a silsequioxane, a D-type silicone, or an M-type silicone. Additional suitable materials for optional filler material 330 are disclosed in Section 5.1.4, below. Filler material 330 can be, for example, a gel or a liquid.

In some embodiments, the optional filler material 330 is a laminate such as any of those disclosed in U.S. Provisional patent application No. 60/906,901, filed Mar. 13, 2007, which is hereby incorporated by reference herein in its entirety. In some embodiments the filler material 330 has a viscosity of less than 1×10⁶ cP. In some embodiments, the filler material 330 has a thermal coefficient of expansion of greater than 500×10⁻⁶/° C. or greater than 1000×10⁻⁶/° C. In some embodiments, the filler material 330 includes polydimethylsiloxane polymer. In some embodiments, the filler material 330 includes by weight: less than 50% of a dielectric gel or components to form a dielectric gel; and at least 30% of a transparent silicon oil, the transparent silicon oil having a beginning viscosity of no more than half of the beginning viscosity of the dielectric gel or components to form the dielectric gel. In some embodiments, the filler material 330 has a thermal coefficient of expansion of greater than 500×10⁻⁶/° C. and includes by weight: less than 50% of a dielectric gel or components to form a dielectric gel; and at least 30% of a transparent silicon oil. In some embodiments, the filler material 330 is formed from silicon oil mixed with a dielectric gel. In some embodiments, the silicon oil is a polydimethylsiloxane polymer liquid and the dielectric gel is a mixture of a first silicone elastomer and a second silicone elastomer. In some embodiments, the filler material 330 is formed from X %, by weight, polydimethylsiloxane polymer liquid, Y %, by weight, a first silicone elastomer, and Z %, by weight, a second silicone elastomer, where X, Y, and Z sum to 100. In some embodiments, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. In some embodiments, first silicone elastomer includes at least sixty percent, by weight, dimethylvinyl-terminated dimethyl siloxane and between 3 and 7 percent by weight silicate. In some embodiments, the second silicone elastomer includes: (i) at least sixty percent, by weight, dimethylvinyl-terminated dimethyl siloxane; (ii) between ten and thirty percent by weight hydrogen-terminated dimethyl siloxane; and (iii) between 3 and 7 percent by weight trimethylated silica. In some embodiments, X is between 30 and 90; Y is between 2 and 20; and Z is between 2 and 20.

In some embodiments, the filler material includes a silicone gel composition, including: (A) 100 parts by weight of a first polydiorganosiloxane containing an average of at least two silicon-bonded alkenyl groups per molecule and having a viscosity of from 0.2 to 10 Pa·s at 25° C.; (B) at least about 0.5 part by weight to about 10 parts by weight of a second polydiorganosiloxane containing an average of at least two silicon-bonded alkenyl groups per molecule, wherein the second polydiorganosiloxane has a viscosity at 25° C. of at least four times the viscosity of the first polydiorganosiloxane at 25° C.; (C) an organohydrogensiloxane having the average formula R⁷Si(SiOR⁸₂H)₃ wherein R⁷ is an alkyl group having 1 to 18 carbon atoms or aryl, R⁸ is an alkyl group having 1 to 4 carbon atoms, in an amount sufficient to provide from 0.1 to 1.5 silicon-bonded hydrogen atoms per alkenyl group in components (A) and (B) combined; and (D) a hydrosilylation catalyst in an amount sufficient to cure the composition as disclosed in U.S. Pat. No. 6,169,155, which is hereby incorporated by reference herein.

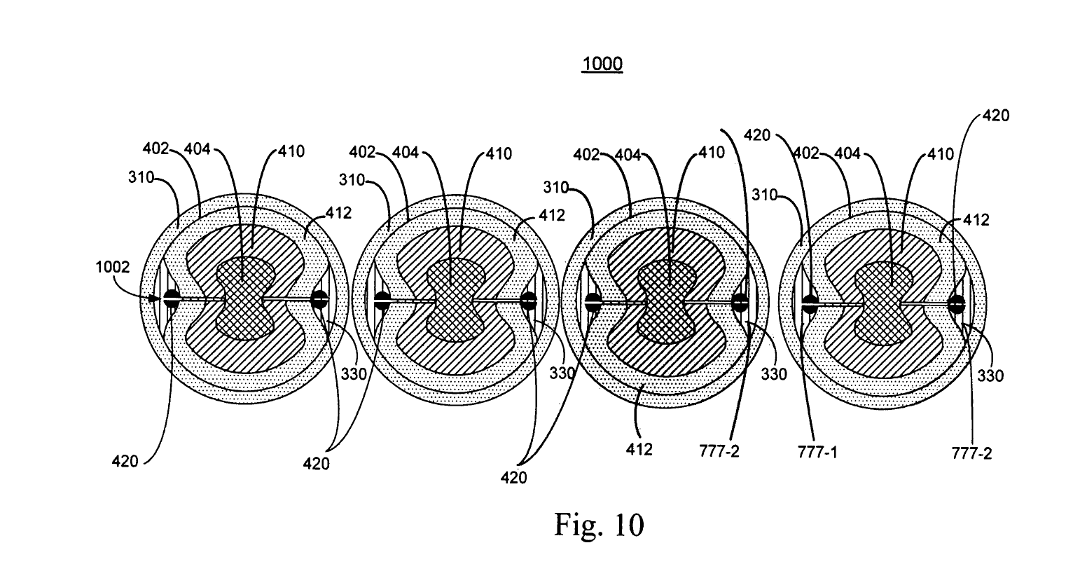

Transparent casing 310. Transparent casing 310 is disposed on all or a portion of transparent conductive layer 412 and/or optional filler material 330. In some embodiments the casing 310 is made of plastic or glass. In some embodiments, the elongated solar cells 402, after being properly modified for packaging as described below, are sealed in the transparent casing 310. As shown in FIG. 4A, the transparent casing 310 fits over the outermost layer of the elongated solar cell 402. In some embodiments, the elongated solar cell 402 is inside the transparent casing 310 such that adjacent elongated solar cells 402 do not electrically contact each other except at the ends of the solar cells. Methods, such as heat shrinking, injection molding, or vacuum loading, can be used to construct the transparent casing 310 such that they exclude oxygen and water from the apparatus. In some embodiments, the transparent casing 310, for example as depicted in FIG. 14, can be used to encase the elongated solar cells 402.

Potential transparent casing 310 geometries include, but are not limited to, cylindrical, various elongate structures where the radial dimension and/or cross-sectional area are far less than the length, having arcuate features, box-like, or any potential geometry compatible for use with photovoltaic cells. In some of the embodiments described herein, the transparent casing 310 is tubular, with a hollow core. However, it should be understood that other geometries and shapes can be used.

In some embodiments, the transparent casing 310 includes a urethane polymer, an acrylic polymer, polymethylmethacrylate (PMMA), a fluoropolymer, silicone, poly-dimethyl siloxane (PDMS), silicone gel, epoxy, ethylene vinyl acetate (EVA), perfluoroalkoxy fluorocarbon (PFA), nylon/polyamide, cross-linked polyethylene (PEX), polyolefin, polypropylene (PP), polyethylene terephthalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), TYGON®, vinyl, VITON®, or any combination or variation thereof.

In some embodiments, the transparent casing 310 includes a plurality of transparent casing layers. In some embodiments, each transparent casing includes a different material. For example, in some embodiments, the transparent casing 310 includes a first transparent casing layer and a second transparent casing layer. Depending on the exact configuration of the solar cell, the first transparent casing layer is disposed on all or a portion of the transparent conductive layer 412, the optional filler material 330, and/or the water resistant layer. The second transparent casing layer is disposed on all or a portion of the first transparent casing layer.

In some embodiments, each transparent casing layer has different properties. In one example, the outer transparent casing layer has excellent UV shielding properties whereas the inner transparent casing layer has good water proofing characteristics. Moreover, the use of multiple transparent casing layers can be used to reduce costs and/or improve the overall properties of transparent casing 310. For example, one transparent casing layer may be made of an expensive material that has a desired physical property. By using one or more additional transparent casing layers, the thickness of the expensive transparent casing layer may be reduced, thereby achieving a savings in material costs. In another example, one transparent casing layer may have excellent optical properties (e.g., index of refraction, etc.) but be very heavy. By using one or more additional transparent casing layers, the thickness of the heavy transparent casing layer may be reduced, thereby reducing the overall weight of transparent casing 310.

Optional water resistant layer. In some embodiments, one or more water resistant layers are disposed on all or a portion of solar cell 402 to reduce or inhibit the damaging effects of water molecules. In some embodiments, the one or more water resistant layers are disposed on all or a portion of transparent conductive layer 412 prior to depositing optional filler material 330 and encasing the solar cell 402 in transparent casing 310. In some embodiments, such water resistant layers are disposed on all or a portion of optional filler material 330 prior to encasing the solar cell 402 in transparent casing 310. In some embodiments, such water resistant layers are disposed on all or a portion of transparent casing 310 itself. In embodiments where a water resistant layer is provided to seal molecular water from solar cell 402, it should be noted that the optical properties of the water resistant layer(s) usefully do not significantly interfere with the absorption of incident solar radiation by solar cell 402. In some embodiments, this water resistant layer is made of clear silicon, SiN, SiOₓN_{y}, SiOₓ, or Al₂O₃, where x and y are integers. In some embodiments, water resistant layer is made of a Q-type silicone, a silsequioxane, a D-type silicone, or an M-type silicone.

Optional antireflective coating. In some embodiments, an optional antireflective coating is disposed on all or a portion of transparent casing 310 to enhance solar cell efficiency. In some embodiments, there is a both a water resistant layer and an antireflective coating deposited on transparent casing 310. In some embodiments, a single layer serves the dual purpose of a water resistant layer and an anti-reflective coating. In some embodiments, the antireflective coating includes MgF₂, silicon nitrate, titanium nitrate, silicon monoxide (SiO), or silicon oxide nitrite. In some embodiments, there is more than one layer of antireflective coating. In some embodiments, there is more than one layer of antireflective coating and each layer includes the same material. In some embodiments, there is more than one layer of antireflective coating and each layer is made of a different material.

In some embodiments, some of the layers of multi-layered solar cells 402 are constructed using cylindrical magnetron sputtering techniques. In some embodiments, some of the layers of multi-layered solar cells 402 are constructed using conventional sputtering methods or reactive sputtering methods on long tubes or strips. Sputtering coating methods for long tubes and strips are disclosed in for example, Hoshi et al., 1983, “Thin Film Coating Techniques on Wires and Inner Walls of Small Tubes via Cylindrical Magnetron Sputtering,” Electrical Engineering in Japan 103:73-80; Lincoln and Blickensderfer, 1980, “Adapting Conventional Sputtering Equipment for Coating Long Tubes and Strips,” J. Vac. Sci. Technol. 17:1252-1253; Harding, 1977, “Improvements in a dc Reactive Sputtering System for Coating Tubes,” J. Vac. Sci. Technol. 14:1313-1315; Pearce, 1970, “A Thick Film Vacuum Deposition System for Microwave Tube Component Coating,” Conference Records of 1970 Conference on Electron Device Techniques 208-211; and Harding et al., 1979, “Production of Properties of Selective Surfaces Coated onto Glass Tubes by a Magnetron Sputtering System,” Proceedings of the International Solar Energy Society 1912-1916, each of which is hereby incorporated by reference herein in its entirety.

Optional fluorescent material. In some embodiments, a fluorescent material (e.g., luminescent material, phosphorescent material) is coated on all or a portion of a layer of solar cell 300. In some embodiments, the fluorescent material is coated on all or a portion of the luminal surface and/or the exterior surface of transparent casing 310. In some embodiments, the fluorescent material is coated on all or a portion of the outside surface of transparent conductive oxide 412. In some embodiments, solar cell 300 includes an optional filler material 330 and the fluorescent material is coated on all or a portion the optional filler material 330. In some embodiments, solar cell 300 includes a water resistant layer and the fluorescent material is coated on all or a portion of the water resistant layer. In some embodiments, more than one surface of a solar cell 300 is coated with optional fluorescent material. In some embodiments, the fluorescent material absorbs blue and/or ultraviolet light, which some semiconductor junctions 410 of the present application do not use to convert light to electricity, and the fluorescent material emits light in visible and/or infrared light which is useful for electrical generation in some solar cells 300 of the present application.

Fluorescent, luminescent, or phosphorescent materials can absorb light in the blue or UV range and emit visible light. Phosphorescent materials, or phosphors, usually include a suitable host material and an activator material. The host materials are typically oxides, sulfides, selenides, halides or silicates of zinc, cadmium, manganese, aluminum, silicon, or various rare earth metals. The activators are added to prolong the emission time.

In some embodiments, phosphorescent materials are incorporated in the systems and methods of the present application to enhance light absorption by solar cell 300. In some embodiments, the phosphorescent material is directly added to the material used to make optional transparent casing 310. In some embodiments, the phosphorescent materials are mixed with a binder for use as transparent paints to coat various outer or inner layers of solar cell 300, as described above.

Exemplary phosphors include, but are not limited to, copper-activated zinc sulfide (ZnS:Cu) and silver-activated zinc sulfide (ZnS:Ag). Other exemplary phosphorescent materials include, but are not limited to, zinc sulfide and cadmium sulfide (ZnS:CdS), strontium aluminate activated by europium (SrAlO₃:Eu), strontium titanium activated by praseodymium and aluminum (SrTiO₃:Pr, Al), calcium sulfide with strontium sulfide with bismuth ((Ca,Sr)S:Bi), copper and magnesium activated zinc sulfide (ZnS:Cu,Mg), or any combination thereof.

Methods for creating phosphor materials are known in the art. For example, methods of making ZnS:Cu or other related phosphorescent materials are described in U.S. Pat. Nos. 2,807,587 to Butler et al.; 3,031,415 to Morrison et al.; 3,031,416 to Morrison et al.; 3,152,995 to Strock; 3,154,712 to Payne; 3,222,214 to Lagos et al.; 3,657,142 to Poss; 4,859,361 to Reilly et al., and 5,269,966 to Karam et al., each of which is hereby incorporated by reference herein in its entirety. Methods for making ZnS:Ag or related phosphorescent materials are described in U.S. Pat. Nos. 6,200,497 to Park et al., 6,025,675 to Ihara et al.; 4,804,882 to Takahara et al., and 4,512,912 to Matsuda et al., each of which is hereby incorporated herein by reference in its entirety. Generally, the persistence of the phosphor increases as the wavelength decreases. In some embodiments, quantum dots of CdSe or similar phosphorescent material can be used to get the same effects. See Dabbousi et al., 1995, “Electroluminescence from CdSe quantum-dot/polymer composites,” Applied Physics Letters 66 (11): 1316-1318; Dabbousi et al., 1997 “(CdSe)ZnS Core-Shell Quantum Dots: Synthesis and Characterization of a Size Series of Highly Luminescent Nanocrystallites,” J. Phys. Chem. B, 101: 9463-9475; Ebenstein et al., 2002, “Fluorescence quantum yield of CdSe:ZnS nanocrystals investigated by correlated atomic-force and single-particle fluorescence microscopy,” Applied Physics Letters 80: 4033-4035; and Peng et al., 2000, “Shape control of CdSe nanocrystals,” Nature 404: 59-61; each of which is hereby incorporated by reference herein in its entirety.

In some embodiments, optical brighteners are used in the optional fluorescent layers of the present application. Optical brighteners (also known as optical brightening agents, fluorescent brightening agents or fluorescent whitening agents) are dyes that absorb light in the ultraviolet and violet region of the electromagnetic spectrum, and re-emit light in the blue region. Such compounds include stilbenes (e.g., trans-1,2-diphenylethylene or (E)-1,2-diphenylethene). Another exemplary optical brightener that can be used in the optional fluorescent layers of the present application is umbelliferone (7-hydroxycoumarin), which also absorbs energy in the UV portion of the spectrum. This energy is then re-emitted in the blue portion of the visible spectrum. More information on optical brighteners is in Dean, 1963, Naturally Occurring Oxygen Ring Compounds, Butterworths, London; Joule and Mills, 2000, Heterocyclic Chemistry, 4^{th} edition, Blackwell Science, Oxford, United Kingdom; and Barton, 1999, Comprehensive Natural Products Chemistry 2: 677, Nakanishi and Meth-Cohn eds., Elsevier, Oxford, United Kingdom, 1999, each of which is hereby incorporated by reference herein in its entirety.

Circumferentially disposed. In some embodiments of the present application, layers of material are successively circumferentially disposed on a non-planar (e.g., cylindrical) substrate 403 in order to form a solar cell. As used herein, the term circumferentially disposed is not intended to imply that each such layer of material is necessarily deposited on an underlying layer, or that the underlying layers are necessarily completely, or even partially, cylindrical. In fact, the present application teaches methods by which such layers are molded or otherwise formed on an underlying layer. Nevertheless, the term circumferentially disposed means that an overlying layer is disposed on an underlying layer such that there is no space (e.g., no annular space) between the overlying layer and the underlying layer. Furthermore, as used herein, the term circumferentially disposed means that an overlying layer is disposed on at least fifty percent of the perimeter of the underlying layer. Furthermore, as used herein, the term circumferentially disposed means that an overlying layer is disposed along at least half of the length of the underlying layer.

Circumferentially sealed. In the present application, the term circumferentially sealed is not intended to imply that an overlying layer or structure is necessarily deposited on an underlying layer or structure. In fact, the present application teaches methods by which such layers or structures (e.g., transparent casing 310) are molded or otherwise formed on an underlying layer or structure. Nevertheless, the term circumferentially sealed means that an overlying layer or structure is disposed on an underlying layer or structure such that there is no annular space between the overlying layer or structure and the underlying layer or structure. Furthermore, as used herein, the term circumferentially sealed means that an overlying layer is disposed on the full perimeter of the underlying layer. In typical embodiments, a layer or structure circumferentially seals an underlying layer or structure when it is circumferentially disposed around the full perimeter of the underlying layer or structure and along the full length of the underlying layer or structure. However, the present application contemplates embodiments in which a circumferentially sealing layer or structure does not extend along the full length of an underlying layer or structure.

Sealant cap 612. In some embodiments, one or both ends of the solar cell 300 are sealed with a sealant cap (not shown in FIGS. 3A-3D). Examples of sealant caps are illustrated, for example, in FIGS. 3E through 3O. Each illustration in FIGS. 3E-3O provides a perspective view of the solar cell 300. Below each perspective view is a corresponding cross-sectional view of the solar cell 300. The solar cell 300 illustrated in FIGS. 3E through 3O does not have an electrically conducting substrate 403. Any non-planar solar cell can be sealed with sealant caps such as those described herein.

In some embodiments, there is a first sealant cap at a first end of the solar cell 300 and a second sealant cap at a second end of the solar cell 300, thereby sealing the solar cell 300 from water. For example, referring to FIGS. 3E and 3F, sealant cap 612 seals end 460 of solar cell 300. In the embodiment illustrated in FIGS. 3E and 3F, the sealant cap 612 is sealed onto the outer surface of transparent nonplanar casing 310. However, other configurations of the sealant cap 612 are possible. For example, referring to FIGS. 3G and 3H, sealant cap 612 is sealed onto the inner surface of the transparent nonplanar casing 310. Mixed embodiments of the sealant cap 612 are possible as well. For example, referring to FIGS. 3I and 3J, a first portion of the cap 612 seals onto the inner surface of the transparent nonplanar casing 310 while a second portion of the cap 612 seals onto the outer surface of the transparent nonplanar casing 310. In FIGS. 3I and 3J, this first portion is approximately half the circumference of the cap 612. However, in other embodiments, this first portion is some value other than half the circumference of the cap 612. In some embodiments, the first portion is a quarter of the circumference of the cap 612 and the second portion is three quarters of the circumference of the cap 612. In some embodiments, the first portion is one percent or more, ten percent or more, twenty percent or more, thirty percent or more of the circumference of the cap 612 and the second portion makes up the balance of cap 612. In some embodiments, the cap 612 comprises a plurality of first portions, where each first portion seals onto the inner surface of the transparent nonplanar casing 310, and a plurality of second portions, where each said second portion of the cap 612 seals onto the outer surface of the transparent nonplanar casing 310. In the embodiments illustrated in FIGS. 3K and 3L, the sealant cap 612 is sealed onto the inner surface of the transparent nonplanar casing 310 and the outer surface of the substrate 403. In FIGS. 3K and 3L, the substrate 403 is hollowed. In other embodiments, however, the substrate 403 is solid, with no hollow core. In some embodiments, any of the configurations shown in FIG. 3 has a substrate with a hollow core.

Still other configurations of the sealant cap 612 are possible. For example, in some embodiments, the sealant cap 612 is bonded onto the outer surface of the transparent nonplanar casing 310 and the outer surface of the substrate 403. In some embodiments, the sealant cap 612 is bonded onto the outer surface of the transparent nonplanar casing 310 and the inner surface of substrate 403. In some embodiments, the sealant cap 612 is bonded onto the inner surface of the transparent nonplanar casing 310 and the inner surface of substrate 403.

Usefully, in some embodiments, the metal(s) that are typically used to make the sealant cap 612 are chosen to match the thermal expansion coefficient of the glass. For example, in some embodiments, the transparent nonplanar casing 310 is made of soda lime glass (CTE of about 9 ppm/C) and the sealant cap 612 is made of a low expansion stainless steel alloy like 410 (CTE of about 10 ppm/C). In some embodiments, the transparent nonplanar casing 310 is made of borosilicate glass (CTE of about 3.5 ppm/C) and sealant cap 612 is made of Kovar (CTE of about 5 ppm/C). Kovar is an iron-nickel-cobalt alloy. In some embodiments, the sealant cap 612 is composed of any conductive material, such as aluminum, molybdenum, tungsten, vanadium, rhodium, niobium, chromium, tantalum, titanium, steel, nickel, platinum, silver, gold, an alloy thereof (e.g. Kovar), or any combination thereof. In some embodiments, the sealant cap 612 is composed of any waterproof conductive material, such as indium tin oxide, titanium nitride, tin oxide, fluorine doped tin oxide, doped zinc oxide, aluminum doped zinc oxide, gallium doped zinc oxide, boron dope zinc oxide, or indium-zinc oxide. In some embodiments, the sealant cap 612 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

In embodiments where the sealant cap 612 is made of metal, care is taken to make sure that the sealant cap does not form an electrical connection with both the transparent conductive layer 110 and the back-electrode 104. This can be accomplished in any number of ways. In the embodiment illustrated in FIG. 3F, a filler layer 560 is positioned between the end 460 and the sealant cap 612. The filler layer 560 electrically isolates the sealant cap 612 from the transparent conductive layer 110 and back-electrode 104. In some embodiments filler layer 560 includes ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane. In some embodiments, the filler layer 560 is a Q-type silicone, a silsequioxane, a D-type silicone, or an M-type silicone. In some embodiments, the filler layer 560 comprises EVA, silicone rubber, or solid rubber. In some embodiments the filler layer 560 is a part of optional filler material 330. In some embodiments the filler layer is laced with a desiccant such as calcium oxide or barium oxide. In some embodiments, in addition to using the filler layer 560, the sealant cap 612 is shaped so that it will not contact the transparent conductive layer 110 and the back-electrode 104. One such shape for the sealant cap 612 is illustrated in FIG. 3O. As can be seen in FIG. 3O, the sealant cap 612 is bowed out relative to the solar cell 300 so that it does not make electrical contact with the transparent conductive layer 110 and the back-electrode 104. FIG. 3O merely serves to illustrate the point that the sealant cap 612 can adopt any type of shape so long at it makes a seal with the solar cell 300.

Advantageously, the sealant cap 612 can serve as an electrical lead for either the transparent conductive layer 110 or the back-electrode 104. Thus, in some embodiments, a first end of the solar cell 300 is sealed with a first sealant cap 612 that makes an electrical connection with the transparent conductive layer 110 and the second end of the solar cell 300 is sealed with a second sealant cap 612 that makes an electrical connection with the back-electrode 104. More typically, a first end of the solar cell 300 is sealed with a first sealant cap 612 that makes an electrical connection with the back-electrode 104 that is electrical communication with the transparent conductive layer 110 while a second end of the solar cell 300 is sealed with a second sealant cap 612 that makes an electrical connection with the back-electrode 104 that is electrically isolated from the transparent conductive layer 110. For example, referring to FIG. 3N, in some embodiments, a first sealant cap 612A makes an electrical connection with the back-electrode 104 that is in electrical communication with the transparent conductive layer 110 and a second sealant cap 612B makes an electrical connection with the back-electrode 104 that is electrically isolated from the transparent conductive layer 110. In these embodiments, the first sealant cap 612 serves as the electrode for transparent conductive layer 110 while the second sealant cap 612 serves as the electrode for the back-electrode 104. Referring to FIGS. 3E and 3F, for example, in embodiments where the sealant cap 612 is made of metal, electrical contact between the sealant cap 612 and both the transparent conductive layer 110 and the back-electrode 104 is not made. Thus, in embodiments where the sealant cap 612 is made of metal, the sealant cap 612 is electrically isolated from at least one of the transparent conductive layer 110 and the back-electrode 104.

Referring to FIG. 3M, in one example, the sealant cap 612A includes the electrical contacts 540 that are positioned within the sealant cap 612A so that they form electrical contact with the back-electrode 104 (as illustrated in FIG. 3M). Then the lead 542 serves as the electrical lead for the transparent conductive layer 110 (as illustrated in FIG. 3M) since the transparent conductive layer 110 is in electrical communication with the back-electrode 104 at the point of contact of electrode 540. Referring to FIG. 3M, sealant cap 612A is sealed onto the solar cell 300 using the sealant 614 and/or 616. As a result, the electrical contacts 540 make electrical contact with the back-electrode 104. In preferred embodiments, the space 560 is filled with a non-conducting filler such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane, before sealing the sealant cap 612 onto the solar cell unit to prevent encapsulation of air within the solar cell. In some embodiments, the electrical contacts 540 are fitted onto the back-electrode 104 rather than onto the sealant cap 612. In some embodiments, the electrical contacts 540 are simply an extension of the back-electrode 104.

In some embodiments the sealant cap 612 is made of glass. In such embodiments, there is a lead for the transparent conductive layer 110 or the back-electrode 104 through the sealant cap 612 (not shown). In such embodiments, the sealant cap 612 can abut directly against the side ends 460. Thus, in such embodiments, the filler layer 560 is optional.

In some embodiments, the sealant cap 612 is sealed onto solar cell unit using butyl rubber (e.g., polyisobutylene). In such embodiments, the filler layer 560 is butyl rubber and glass frits or ceramics are not required to seal the sealant cap 612 onto the solar cell 300 because the butyl rubber performs this function. In some embodiments, this butyl rubber is loaded with active desiccant such as CaO or BaO. In such embodiments that are sealed with butyl rubber, the solar cell unit has a water vapor transmission rate of less than 10⁻⁴ g/m²·day. In some embodiments that use butyl rubber for the filler layer 560, the sealant cap 612 is not required. In such embodiments, the ends of solar cell 300 are sealed with butyl rubber. In embodiments where butyl rubber is used without the sealant cap 612 leads such as leads 540 and 542 of FIG. 3M can be used to electrically connect the solar cell 300 with other solar cell units 300 or other circuitry.

In some embodiments the sealant cap 612 is sealed onto the solar cell 300 using glass-to-glass, metal-to-metal, ceramic-to-metal, or glass-to-metal seals. There are two exemplary types of glass-to-metal hermetic seals used in various exemplary embodiments: matched seals and mismatched (compression) seals. Matched glass-to-metal hermetic seals are made of metal alloys and the substrate 403/transparent nonplanar casing 310 that share similar thermal expansion characteristics. Mismatched or compression glass to metal hermetic seals feature a steel or stainless steel sealant cap 612 that has a higher thermal expansion rate than the glass solar cell. Upon cooling, the sealant cap 612 contracts around the glass, creating a hermetic seal that is reinforced both chemically and mechanically. In some embodiments, a hermetic seal is any seal that has a water vapor transmission rate of 10⁻⁴ g/m²·day or better. In some embodiments, a hermetic seal is any seal that has a water vapor transmission rate of 10⁻⁵ g/m²·day or better. In some embodiments, a hermetic seal is any seal that has a water vapor transmission rate of 10⁻⁶ g/m²·day or better. In some embodiments, a hermetic seal is any seal that has a water vapor transmission rate of 10⁻⁷ g/m²·day or better. In some embodiments, a hermetic seal is any seal that has a water vapor transmission rate of 10⁻⁸ g/m²·day or better.

In some embodiments, the seal formed between the sealant cap 612 and the solar cell 300 has a water vapor transmission rate (WVTR) of 10⁻⁴ g/m²·day or less. In some embodiments, the seal formed between the sealant cap 612 and the solar cell 300 has a water vapor transmission rate (WVTR) of 10⁻⁵ g/m²·day or less. In some embodiments, the seal formed between the cap 612 and the solar cell 300 has a WVTR of 10⁻⁶ g/m²·day or less. In some embodiments, the seal formed between the cap 612 and the solar cell 300 has a WVTR of 10⁻⁷ g/m²·day or less. In some embodiments, the seal formed between the cap 612 and the solar cell 300 has a WVTR of 10⁻⁸ g/m²·day or less. The seal between the sealant cap 612 and the solar cell 300 can be accomplished using a glass or, more generally, a ceramic material. In preferred embodiments, this glass or ceramic material has a melting temperature between 200° C. and 450° C. In some embodiments, this glass or ceramic material has a melting temperature between 300° C. and 450° C. In some embodiments, this glass or ceramic material has a melting temperature between 350° C. and 400° C. There are a wide range of glasses and ceramic materials that can be used to form the hermetic seal. Examples include, but are not limited to, oxide ceramics including alumina, zirconia, silica, aluminum silicate, magnesia and other metal oxide based materials, ceramics based upon aluminum dioxide, aluminum nitrate, aluminum oxide, aluminum zirconia, as well as glasses based upon silicon dioxide.

Referring to FIG. 3E, in some embodiments, the sealant cap 612 is sealed onto the solar cell 300 by placing a continuous strip of sealant 614 around the inner edge of the sealant cap 612. Still referring to FIG. 3E, in some embodiments, a continuous strip of sealant 616 is placed on the outer edge of the transparent nonplanar casing 310. Typically, the sealant 614 (around inner edge of sealant cap 612) or the sealant 616 (around outer edge of transparent nonplanar casing 310), but not both, are used (although both can be used).

In some embodiments, the sealant 614 and/or sealant 616 is glass frit. There are different types of frit which can be used for different types of glass and at different temperatures. The present invention is independent of the frit or glass type. In preferred embodiments, the glass frit has a melting temperature between 200° C. and 450° C. Such materials, also called solder glass, are available from many sources, including Ferro Corporation (Cleveland, Ohio), Schott Glass (Elmsford, N.Y.), and Asahi Glass (Tokyo, Japan). Advantageously, the use of low temperature melting solder glass limits the exposure of the active components of the solar cell to extreme temperature during formation of the seal. In preferred embodiments, the glass frit is a pressed or sintered preform made to the correct shape of the application (either to fit over outer edge of transparent nonplanar casing 310 in the case of sealant 616 or to fit within the inner edge of sealant cap 612 in the case of sealant 614. In some embodiment, the solder glass is suspended in an organic binder material or is applied as a dry powder. In embodiments where the sealant 614 and/or 616 is glass frit, the temperature is increased to a value that will enable the continuous glass frit to soften. Heat can be applied by methods such as direct contact with a hot surface, by inductively heating up a metal part, by contact with flame or hot air, or through absorption of light from a laser. Once the glass frit is softened, the sealant cap 612 is pressed onto the solar cell 300. The softened glass frit forms a bond with the parts being joined, thus forming a hermetic seal.

In some embodiments, the sealant 614 and/or sealant 616 is a sol-gel material. As is known, a sol-gel material alternates between two states, one being a colloidal suspension of solid particles in a liquid, the other state being a dual phase material in which there is a solid outer shell filled with a solvent. When the solvent is removed, e.g., though exposure to ambient atmospheric pressure, a xerogel material results with a consistency similar to that of a low density glass. As is also known, a sol-gel material may be formulated by combining a quantity of potassium silicate (kasil) (e.g., 120 grams) with a comparatively smaller quantity of formamide (e.g., 7-8 grams). Alternatively, a lesser quantity of kasil (e.g., 12 grams) may be combined with still a lesser quantity of propylene carbonate (e.g., 2-3 grams). Another method of forming a sol-gel material involves the mixture of TEOS—H₂O and methanol, and allowing the mixture to hydrolyse. In embodiments where the sealant 614 and/or 616 is sol-gel, the sealant cap 612 is pressed onto the solar cell 300 and the sol-gel is allowed to cure. In some embodiments, the sol-gel is cured at ambient temperature and ambient atmospheric pressure. Alternatively, the curing process may be accelerated by other methods such as, e.g., applying heat or using an infrared heat source. In the case where the sol-gel is a polycarbonate-kasil mixture, the sol-gel material cures in approximately 5 to 10 minutes at room temperature. Sol-gels are discussed in Madou, 2002, Fundamentals of Microfabrication, The Science of Miniaturization, Second Edition, CRC Press, New York, pp. 156-157, which is hereby incorporated by reference herein in its entirety.

In some embodiments, the sealant 614 and/or sealant 616 is a ceramic cement material. Such materials are readily available from suppliers such as Aremco (Valley Cottage, N.Y.) and Sauereisen (Pittsburgh, Pa.). Such materials are relatively inexpensive and provide strong bonds to glass or metal. By their nature, however, these cements form porous ceramics which do not provide a hermetic waterproof seal. However, such materials can be waterproofed. A suspension of solder glass particles which are smaller than the pore size of the ceramic can be made in a volatile liquid. This liquid can then be allowed to wick into the pores of the ceramic by capillary action. Subsequent heating causes the solder glass to melt, thus wetting the ceramic material, and thereby sealing the ceramic and forming a hermetic seal. Aremco sells a product for this application (AremcoSeal 617). AremcoSeal 617 glass, however, has the drawback that it must be treated at high temperature. Thus, in preferred embodiments, a low melting point solder glass suspended in a binder such as provided by DieMat (DM2700P sealing glass paste) is used instead. Both the porous ceramics and the sol-gel can be waterproofed using these techniques.

In one embodiment in accordance with FIGS. 3E and 3F, DM2700P (DieMat, Byfield, Mass.) is coated onto the outer circumference of the transparent nonplanar casing 310 to form the sealant 616 and the paste is allowed to dry. Then, the sealant cap 612, made of stainless steel, is heated on a hotplate to about 420° C. Next, the coated end of the solar cell is manually inserted into the hot cap, while still on the hotplate. The sealing glass paste is allowed to melt and wet the surface of the sealant cap 612. The solar cell is removed from the hotplate and allowed to cool.

In another embodiment in accordance with FIGS. 3E and 3F, DM2700P coating is applied to the inner circumference of the sealant cap 612 in order to form the sealant 614. The paste is allowed to dry. Next, the stainless steel cap is heated on a hotplate to about 420° C. until the sealing glass melts. One end of the solar cell is manually inserted into the stainless steal cap while the cap is still on the hotplate. The sealing glass paste melts and wets the outer surface of surface of the transparent nonplanar casing 310. The assembly is then removed from the hotplate and allowed to cool.

Referring to FIG. 3G, the sealant 618 and/or 620 is used to seal the sealant cap 612 to the solar cell 300. The sealant 618 and/or 620 is made of any of the compositions that can be used to make the sealant 614 and/or 616 described above. Referring to FIG. 31, the sealant 622 and/or 624 is used to seal the sealant cap 612 to the solar cell 300. The sealant 622 and/or 624 is made of any of the compositions that can be used to make the sealant 614 and/or 616 described above. Referring to FIG. 3K, the sealant 626 and/or 630 together with the sealant 628 and/or sealant 632 is used to seal the sealant cap 612 to the solar cell 300. The sealant 626 and/or 628 and/or 630 and/or 632 is made of any of the compositions that can be used to make the sealant 614 and/or 616 described above.

Multifacial Embodiments. In other embodiments (not shown), the solar cell 300 is bifacial, having two flat photovoltaic cells conjoined in opposite directions, such that light entering from either the top or the bottom would be received and converted to electric energy.

Further, the solar cell 300 and the transparent casing 310 may have the same or substantially the same geometric shape as each other. Alternatively, the solar cell and the transparent casing 310 may have differing geometries (e.g., a bifacial solar cell can be disposed within a tubular or cylindrical casing). Accordingly, the cell 300 and the casing 310 can thus have any suitable cross-sectional shapes, such as square, rectangular, elliptical, polygonal, or have a varying cross-sectional shape, and any desired overall shape and configuration.

In various embodiments, the solar cell 300 can have a multi-facial, or omnifacial configuration, or otherwise be designed to capture light from directions both facing and not facing the initial light source. An example omnifacial topology of a solar cell 300 is the cylindrical embodiment illustrated in FIG. 3A, where the surface of the cell has one continuous surface. In a multifacial configuration, the shape of the cross section of the solar cell 300 can be described by any combination of straight lines and curved features. In some cases, the omnifacial and multifacial configurations are operable to receive light from differing orientations, including anti-parallel directions.

### 5.1.1 Solar Cell Unit Assemblies

FIG. 4A illustrates a cross-sectional view of the arrangement of three solar cell units 300 arranged in a coplanar fashion in order to form a solar cell assembly 400. FIG. 4B provides a cross-sectional view with respect to line 4B-4B of FIG. 4A. In FIGS. 4A-4B, back-electrode 404 is depicted as a solid cylindrical substrate. However, in some embodiments in accordance with FIGS. 4A-4B, rather than being a solid cylindrical substrate, back-electrode is a thin layer of electrically conducting material disposed on all or a portion substrate 403 as depicted in FIG. 3B. All other layers in FIGS. 4A-4B are as illustrated in FIG. 3B. Like in FIG. 3B, filler material 330 in the embodiments depicted in FIGS. 4A-4B is optional.

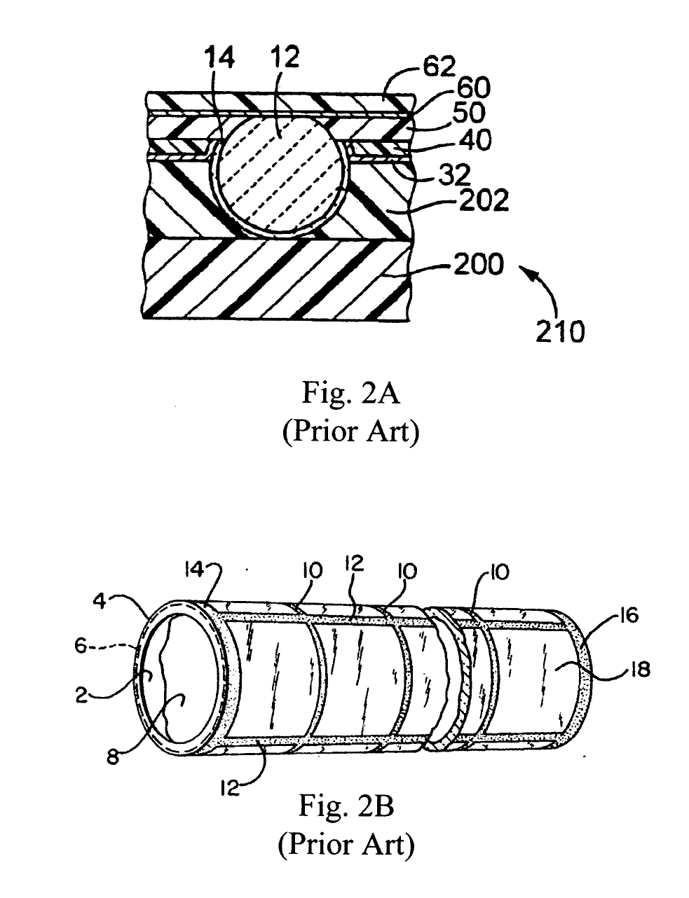

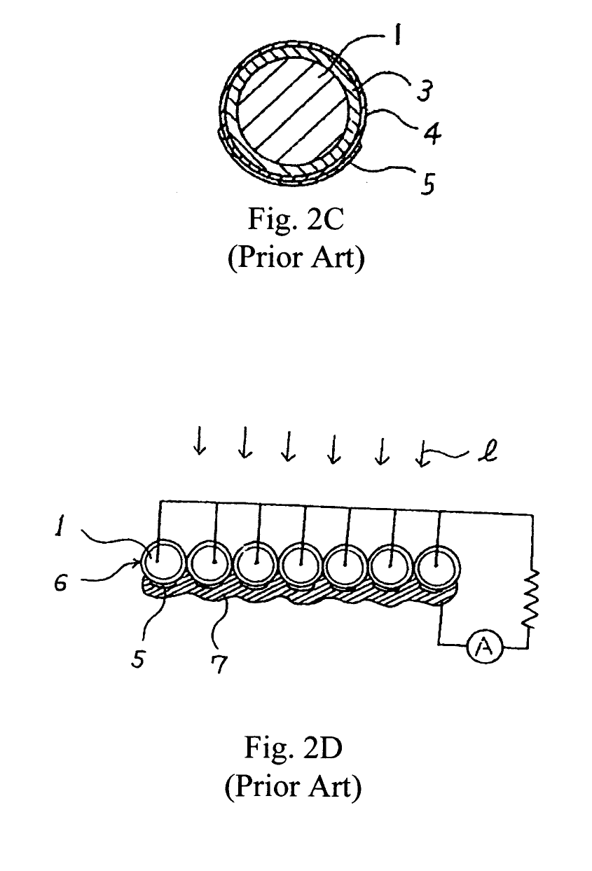

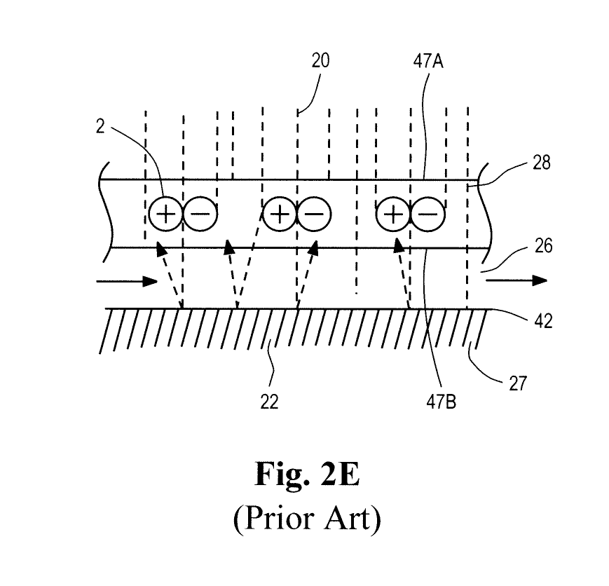

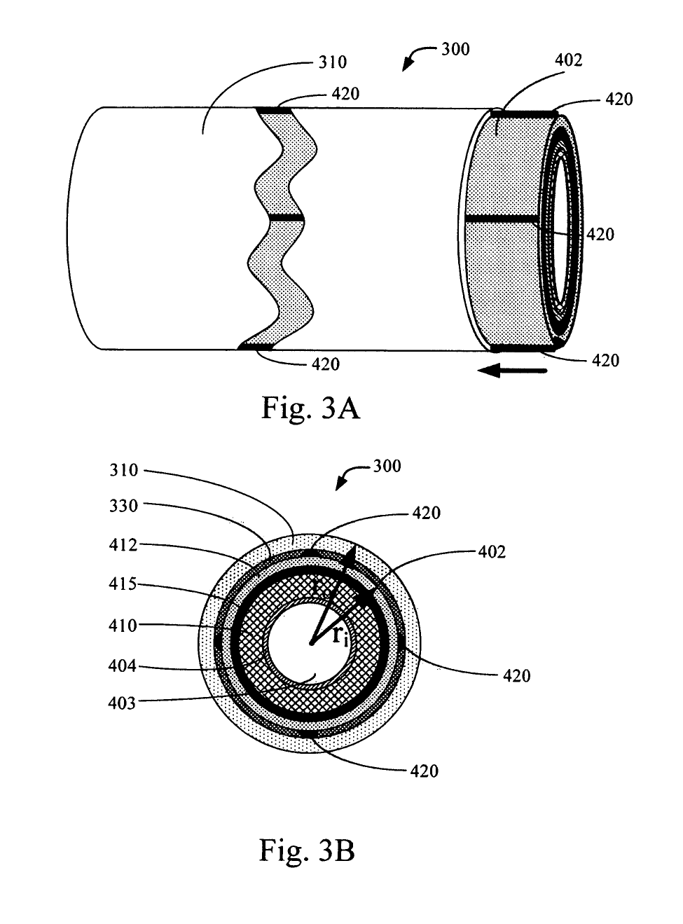

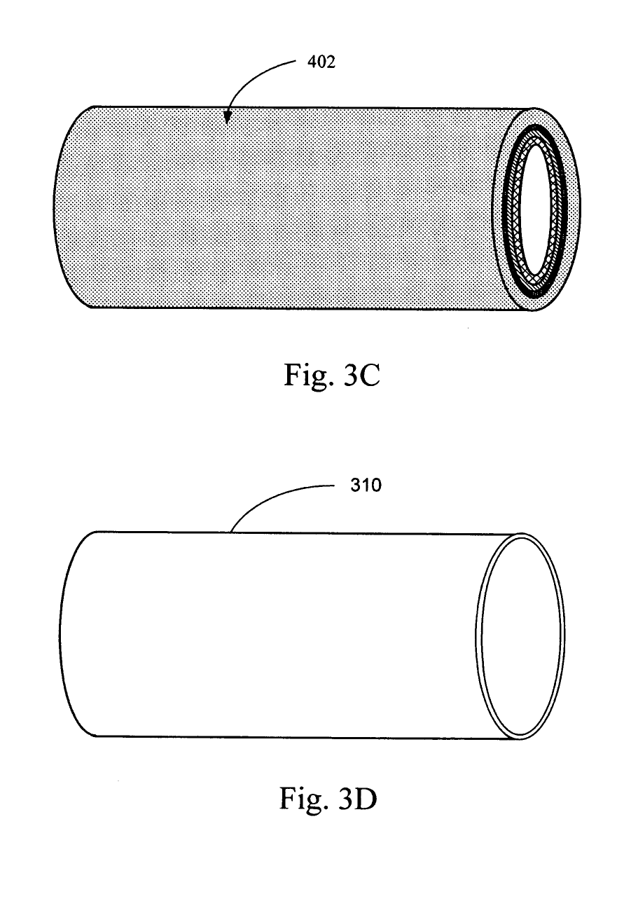

As can be seen with FIGS. 4A and 4B, each elongated cell 402 has a length that is great compared to the diameter d of its cross-section. A useful feature of the architecture shown in FIG. 4A is that there is no front side contact that shades solar cells 402. Such a front side contact is found in known devices (e.g., elements 10 of FIG. 2B). Another useful feature of the architecture shown in FIG. 4A is that elongated cells 402 are electrically connected in series rather than in parallel. In such a series configuration, the voltage of each elongated cell 402 is summed. This serves to increase the voltage across the system, thereby keeping the current down, relative to comparable parallel architectures, and reduces resistive losses. A serial electrical arrangement is maintained by arranging all or a portion of the elongated solar cells 402 as illustrated in FIGS. 4A and 4B. Another useful feature of the architecture shown in FIG. 4A is that the resistance loss across the system is low. This is because each electrode component of the circuit is made of highly conductive material. For example, as noted above, conductive core 404 of each solar cell 402 is made of a conductive material such as metal. In the alternative, where conductive core 404 is not a solid, but rather includes a back-electrode layer circumferentially deposited on substrate 403, the back-electrode layer 404 is highly conductive. Regardless of whether back-electrode 404 is in a solid configuration as depicted in FIGS. 4A-4B or a thin layer as depicted in FIG. 3B, such back-electrodes 404 carry current without an appreciable current loss due to resistance. While larger conductive cores 404 (FIGS. 4A-4B) and/or thicker back-electrodes 404 (FIG. 3B) ensure low resistance, transparent conductive layers encompassing such larger conductive cores 404 must carry current further to contacts (counter-electrode strips or leads) 420. Thus, there is an upper bound on the size of conductive cores 404 and/or substrate 403. In view of these and other considerations, diameter d is between 0.5 millimeters (mm) and 20 mm in some embodiments of the present application. Thus, conductive core 404 (FIGS. 4A-4B) and/or substrate 403 (FIG. 3B) are sized so that they are large enough to carry a current without appreciable resistive losses, yet small enough to allow transparent conductive 412 to efficiently deliver current to counter-electrode strip 420.

The relatively low resistance nature of the architecture illustrated in FIG. 4A is also facilitated by the highly conductive properties of counter-electrode strip 420. However, in some embodiments, counter-electrode strips are not used. In some embodiments, monolithic integration architectures, such as those described in U.S. Pat. No. 7,235,736 the entire contents of which are hereby incorporated by reference herein, are used in addition to or instead of the counter-electrode strips 420. Therefore, it will be appreciated that any of the solar cells 402 described herein may in fact include a plurality of solar cells arranged on a common substrate 403 (where each of these solar cells in the plurality of solar cells are termed “units” herein) and that each of solar cell in the plurality of solar cells arranged on a common substrate may be either be serially or electrically connected to one or more other solar cells in the plurality of solar cells arranged on a common substrate. In some embodiments, there are two or more, five or more, ten or more, fifty or more, one hundred or more, or one thousand or more solar cells (units) arranged on a common substrate 403. In some embodiments, two or more solar cells (units) arranged on a common substrate are electrically arranged in series as disclosed in U.S. Pat. No. 7,235,736 the entire contents of which are hereby incorporated by reference herein.

In some embodiments, for example, counter-electrode strips 420 are composed of a conductive epoxy (e.g., silver epoxy) or conductive ink and the like. For example, in some embodiments, counter-electrode strips 420 are formed by depositing a thin metallic layer on a suitable substrate and then patterning the layer into a series of parallel strips. Each counter-electrode strip 420 is affixed to a solar cell 402 with a conductive epoxy along the length of a solar cell 402, as shown in FIG. 4D. In some embodiments, counter-electrode strips 420 are formed directly on solar cells 402. In other embodiments, counter-electrode strips 420 are formed on the outer transparent conductive layer 412, as illustrated in FIG. 3B. In some embodiments, connections between counter-electrode strip 420 to electrodes 433 are established in series as depicted in FIG. 4B.

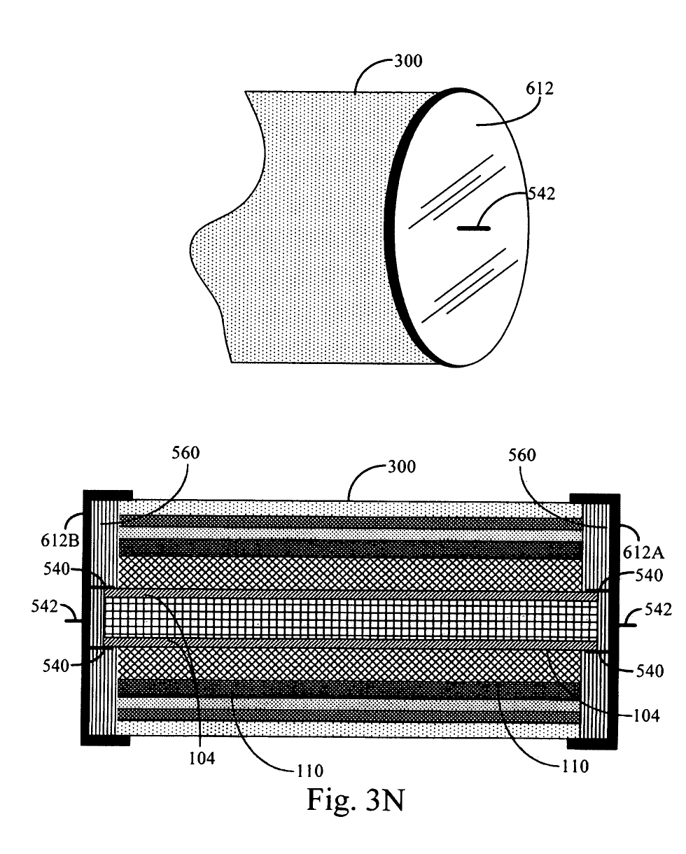

Still another useful feature of the architecture illustrated in FIG. 4A is that the path length through the absorber layer (e.g., layer 502, 510, 520, or 540 of FIGS. 5A-5D) of semiconductor junction 410 is, on average, longer than the path length through of the same type of absorber layer having the same width but in a planar configuration. Thus, the elongated architecture illustrated in FIG. 4A allows for the design of thinner absorption layers relative to analogous planar solar cell counterparts. In the elongated architecture, the thinner absorption layer absorbs the light because of the increased path length through the layer. Because the absorption layer is thinner relative to comparable planar solar cells, there is less resistance and, hence, an overall increase in efficiency in the cell relative to analogous planar solar cells. Additional useful aspects of having a thinner absorption layer that still absorbs sufficient amounts of light is that such absorption layers require less material and are thus cheaper. Furthermore, thinner absorption layers are faster to make, thereby further lowering production costs.

Another useful feature of elongated solar cells 402 illustrated in FIG. 4A is that they have a relatively small surface area, relative to comparable planar solar cells. In some embodiments, the cells possess radial symmetry. However, not all embodiments possess radial symmetry. The relatively small surface area and/or radial symmetry of the cells allow for the controlled deposition of doped semiconductor layers necessary to form semiconductor junction 410. The smaller surface area, relative to conventional flat panel solar cells, means that it is easier to present a uniform vapor across the surface during deposition of the layers that form semiconductor junction 410. The optional radial symmetry can be exploited during the manufacture of the cells in order to ensure uniform composition (e.g., uniform material composition, uniform dopant concentration, etc.) and/or uniform thickness of individual layers of semiconductor junction 410. For example, the conductive core 404 upon which layers are deposited to make solar cells 402 can be rotated along its longitudinal axis during such deposition in order to ensure uniform material composition and/or uniform thickness. Such rotation can also be performed for cells that do not possess radial symmetry.

The cross-sectional shape of solar cells 402 is illustrated as being generally circular in FIG. 4B. In other embodiments, solar cell 402 bodies with a quadrilateral cross-section or an elliptical shaped cross-section and the like are used. In fact, there is no limit on the cross-sectional shape of solar cells 402 in the present application. In some embodiments, the solar cells 402 maintain a general overall rod-like shape in which their length is much larger than their diameter and/or cross-sectional area, and they possess some form of cross-sectional radial symmetry or approximate cross-sectional radial symmetry. In some embodiments, the solar cells 402 maintain a general overall rod-like shape in which their length is much larger than their diameter and/or cross-sectional area, but do not possess radial symmetry. For example, the solar cells may be characterized by any of the cross-sectional areas discussed above in conjunction with the description of the substrate 403.

In some embodiments, as illustrated in FIG. 4A, a first and second elongated solar cell (rod-shaped solar cell) 402 are electrically connected in series by an electrical contact 433 that connects the back-electrode 404 (first electrode) of the first elongated solar cell 402 to the corresponding counter-electrode strip 420 of the second elongated solar cell 402. Thus, as illustrated in FIG. 4A, elongated solar cells 402 are the basic unit that respectively forms the semiconductor layer 410, the transparent conductive layer 412, and the metal conductive core 404 of the elongated solar cell 402. In some embodiments, the elongated solar cells 402 are multiply arranged in a row parallel or nearly parallel with respect to each other and rest upon independent leads (counter-electrodes) 420 that are electrically isolated from each other. Usefully, in the configuration illustrated in FIG. 4A, elongated solar cells 402 can receive direct light through transparent casing 310.

In some embodiments, not all elongated solar cells 402 in assembly 400 are electrically arranged in series. For example, in some embodiments, there are pairs of elongated solar cells 402 that are electrically arranged in parallel. A first and second elongated solar cell can be electrically connected in parallel, and are thereby paired, by using a first electrical contact (e.g., an electrically conducting wire, etc., not shown) that joins the conductive core 404 of a first elongated solar cell to the second elongated solar cell. To complete the parallel circuit, transparent conductive layer 412 of the first elongated solar cell 402 is electrically connected to transparent conductive layer 412 of the second elongated solar cell 402 either by contacting the transparent conductive layers of the two elongated solar cells either directly or through a second electrical contact (not shown). The pairs of elongated solar cells are then electrically arranged in series. In some embodiments, three, four, five, six, seven, eight, nine, ten, eleven or more elongated solar cells 402 are electrically arranged in parallel. These parallel groups of elongated solar cells 402 are then electrically arranged in series.

FIG. 4C is an enlargement of region 4C of FIG. 4B in which a portion of back-electrode 404 and transparent conductive layer 412 have been cut away to illustrate the positional relationship between counter-electrode strip 420, electrode 433, back-electrode 404, semiconductor layer 410, and transparent conductive layer 412. Furthermore, FIG. 4C illustrates how electrical contact 433 joins back-electrode 404 of one elongated solar cell 402 to counter-electrode 420 of another solar cell 402.

One useful feature of the configuration illustrated in FIGS. 4A-4B is that electrical contacts 433 that serially connect solar cells 402 together only need to be placed on one end of assembly 400, as illustrated in FIG. 4B. However, encapsulation shields each solar cell 402 from unwanted electrical contacts from adjacent solar cells 402, making encapsulation relatively simple. Thus, referring to FIG. 4D, which is a cross-sectional view of an elongated solar 402 cell taken about line 4D-4D of FIG. 4B, it is possible to completely seal far-end 455 of solar cell 402 with transparent casing 310 in the manner illustrated. In some embodiments, the layers in this seal are identical to the layers disposed lengthwise on conductive core 404, namely, in order of deposition on conductive core 404 and/or substrate 403, semiconductor junction 410, optional thin intrinsic layer (i-layer) 415, and transparent conductive layer 412. In such embodiments, end 455 can receive sunlight and therefore contribute to the electrical generating properties of the solar cell 402. In some embodiments, transparent casing 310 opens at both ends of solar cell 402 such that electrical contacts can be extended from either end of the solar cell.

FIG. 4D also illustrates how, in some embodiments, the various layers deposited on all or a portion of conductive core 404 are tapered at end 466 where electrical contacts 433 are found. For instance, a terminal portion of back-electrode 404 is exposed, as illustrated in FIG. 4D. In other words, semiconductor junction 410, optional i-layer 415, and transparent conductive layer 412 are stripped away from a terminal portion of conductive core 404. Furthermore, a terminal portion of semiconductor junction 410 is exposed as illustrated in FIG. 4D. That is, optional i-layer 415 and transparent conductive layer 412 are stripped away from a terminal portion of semiconductor junction 410. The remaining portions of the conductive core 404, semiconductor junction 410, optional i-layer 415, and transparent conductive layer 412 are coated by transparent casing 310. Such a configuration is useful because it prevents a short from developing between transparent conductive layer 412 and conductive core 404. In FIG. 4D, elongated solar cell 402 is positioned on counter-electrode strip 420 which, in turn, is positioned against electrically resistant transparent casing 310. However, there is no requirement that counter-electrode strip 420 make contact with electrically resistant transparent casing 310. In fact, in some embodiments, elongated solar cells 402 and their corresponding counter-electrode strips 420 are sealed within transparent conductive layer 412 such that there is no unfavorable electrical contact. In such embodiments, elongated solar cells 402 and corresponding electrode strips 420 are fixedly held in place by a sealant such as ethylene vinyl acetate or silicone. In some embodiments in accordance with the present application, counter-electrode strips 420 are replaced with metal wires that are attached to the sides of solar cell 402. In some embodiments in accordance with the present application, solar cells 402 implement a segmented design to eliminate the requirement of additional wire- or strip-like counter-electrodes. Details on segmented solar cell design are found in U.S. Pat. No. 7,235,736, entitled “Monolithic Integration of Cylindrical Solar Cells,” which is hereby incorporated by reference herein in its entirety. Briefly, in such a segmented design, one or more layers in the solar cell (e.g., the semiconductor junction) may be scribed thereby forming a plurality of individual units. A first unit in the plurality of units is electrically connected in series, or in parallel, to a second unit in the plurality of units.

FIG. 4D further provides a perspective view of electrical contacts 433 that serially connect elongated solar cells 402. For instance, a first electrical contact 433-1 electrically interfaces with counter-electrode 420 whereas a second electrical contact 433-2 electrically interfaces with back-electrode 404 (the first electrode of elongated solar cell 402). First electrical contact 433-1 serially connects the counter-electrode of elongated solar cell 402 to the back-electrode 404 of another elongated solar cell. Second electrical contact 433-2 serially connects the back-electrode 404 of elongated solar cell 402 to the counter-electrode 420 of another elongated solar cell 402, as shown in FIG. 4B. Such an electrical configuration is possible regardless of whether back-electrode 404 is itself a solid nonplanar substrate or is a layer of electrically conducting material disposed on all or a portion a substrate 403 as depicted in FIG. 3B. Each solar cell 402 is coated by a transparent casing 310.

In addition, FIG. 4D provides an encapsulated solar cell 402 where an optional filler material 330 and a transparent casing 310 cover the solar cell, leaving only one end 466 to establish electrical contracts. It is to be appreciated that, in some embodiments, the optional filler material 330 and transparent casing 310 are configured such that both ends (e.g., 455 and 466 in FIG. 4D) of the elongated solar cell 402 are available to establish electrical contacts.

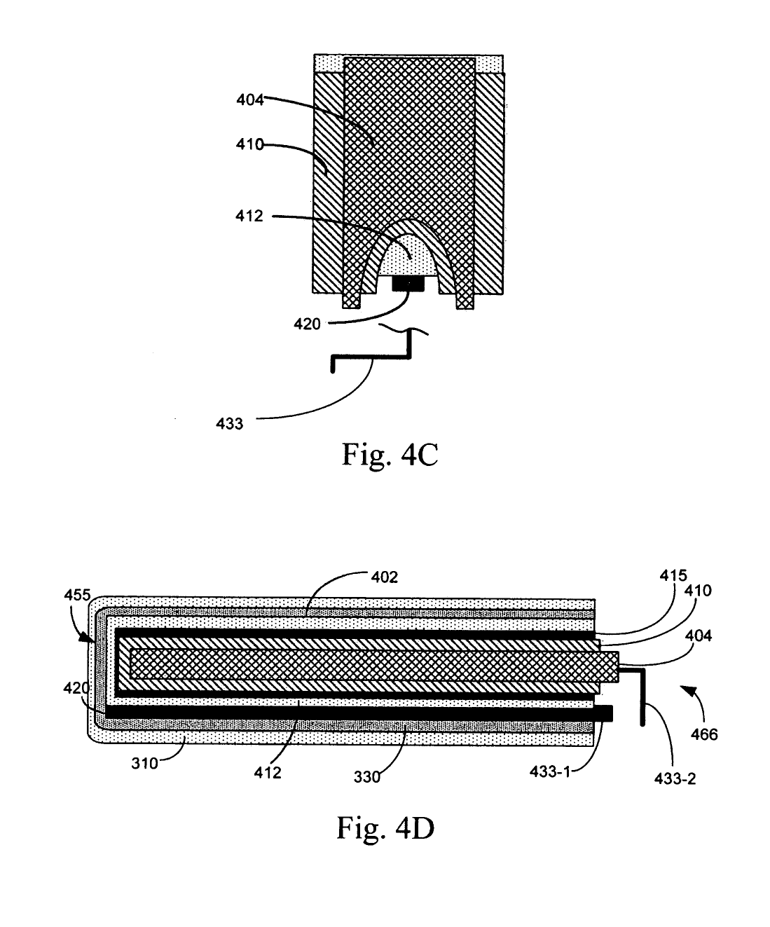

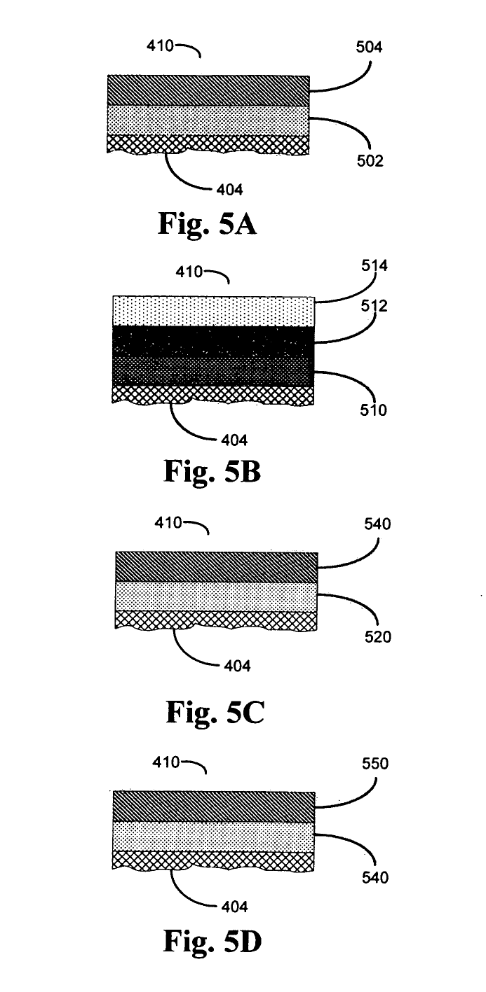

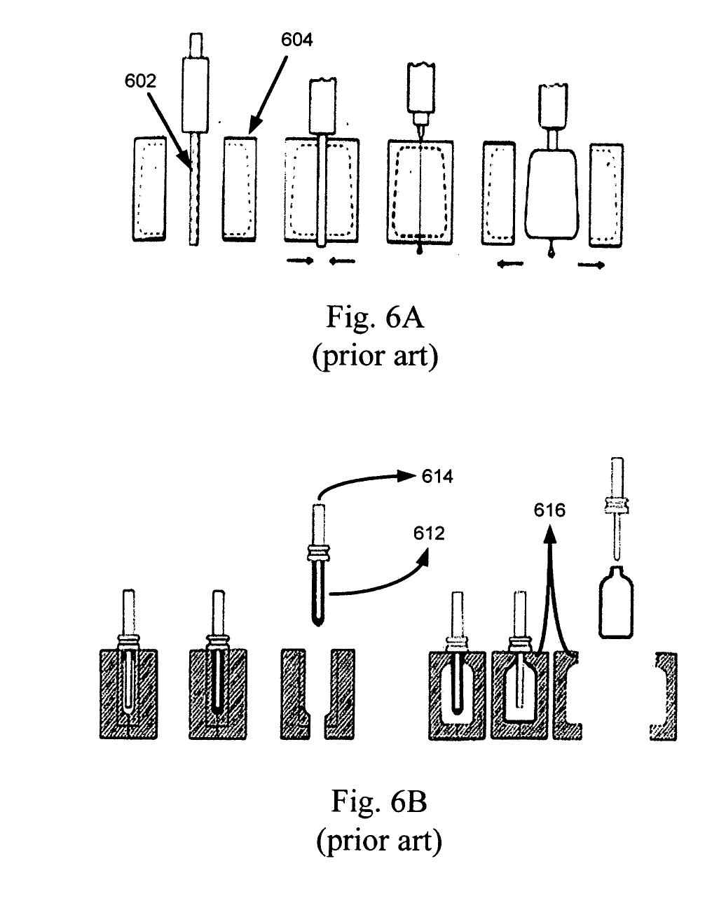

FIG. 7A illustrates a solar cell assembly 700 in accordance with another embodiment of the present application. Solar cell assembly 700 includes a plurality of elongated solar cells 402, each encapsulated in transparent casing 310. Each elongated solar cell 402 in the plurality of elongated solar cells has a back-electrode 404 configured as a first electrode. In the embodiment depicted in FIG. 7A, back electrode 404 is a solid cylindrical electrically conducting substrate. However, in alternative embodiments in accordance with FIG. 7A, back-electrode 404 is a thin film of electrically conducting material deposited on a hollowed tubular shaped substrate as in the case of FIG. 3B. The principles disclosed in FIG. 7A apply to each such form of back-electrode 404. In FIG. 7A, a semiconductor junction 410 is circumferentially disposed on the conductive core 402 and a transparent conductive layer 412 is circumferentially disposed on semiconductor junction 410. In some embodiments, the plurality of elongated solar cells 402 are geometrically arranged in a parallel or a near parallel manner thereby forming a planar array having a first face (facing side 733 of assembly 700) and a second face (facing side 766 of assembly 700). The plurality of elongated solar cells is arranged such that one or more elongated solar cells in the plurality of elongated solar cells do not contact adjacent elongated solar cells. In some embodiments, the plurality of elongated solar cells is arranged such that each of the elongated solar cells in the plurality of elongated solar cells does not directly contact (through transparent conductive layer 412) adjacent elongated solar cells 402. In some embodiments, the plurality of elongated solar cells is arranged such that each of the elongated solar cells in the plurality of elongated solar cells does directly contact the outer transparent casing 310 of adjacent elongated solar cells 402.

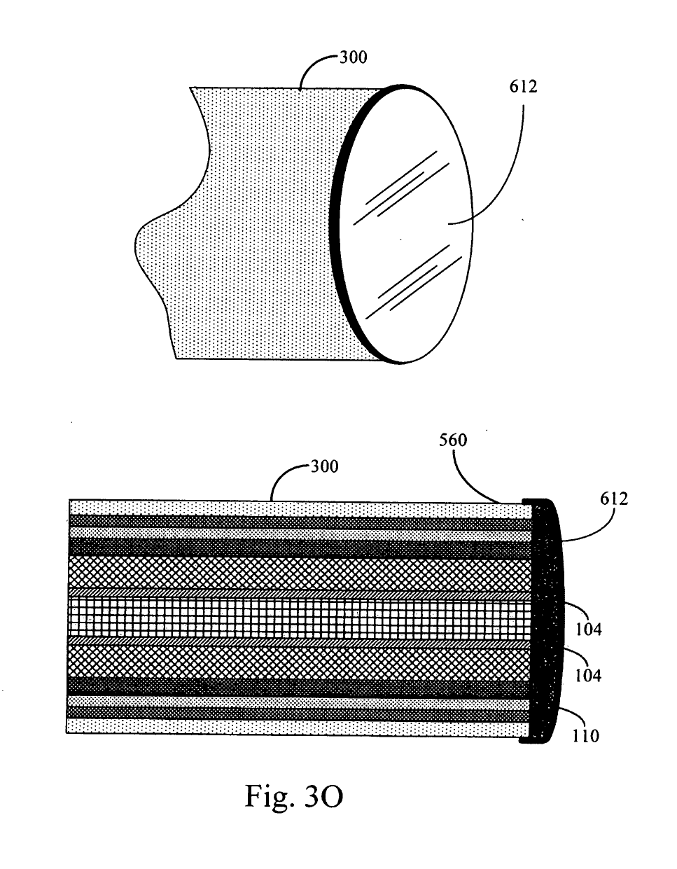

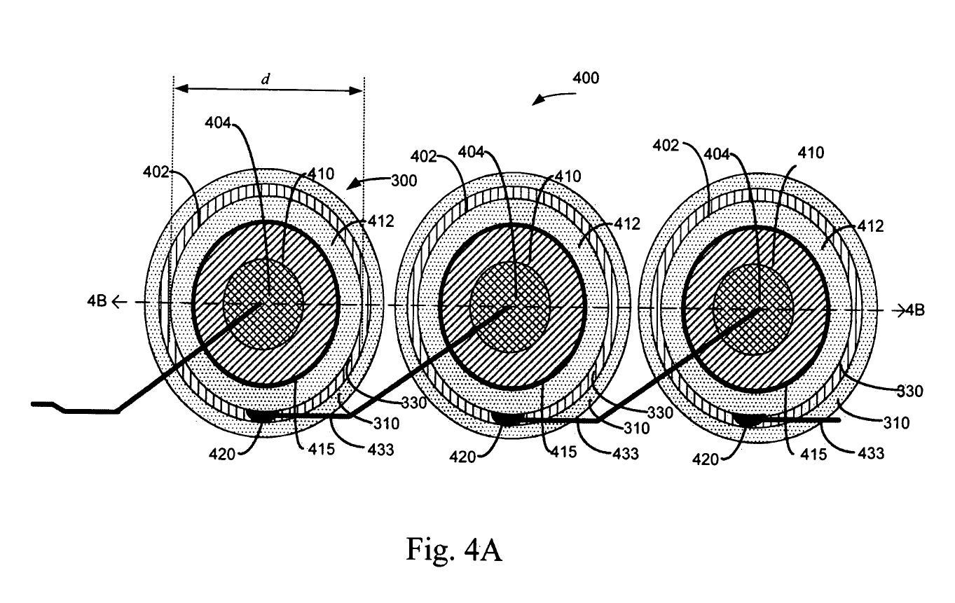

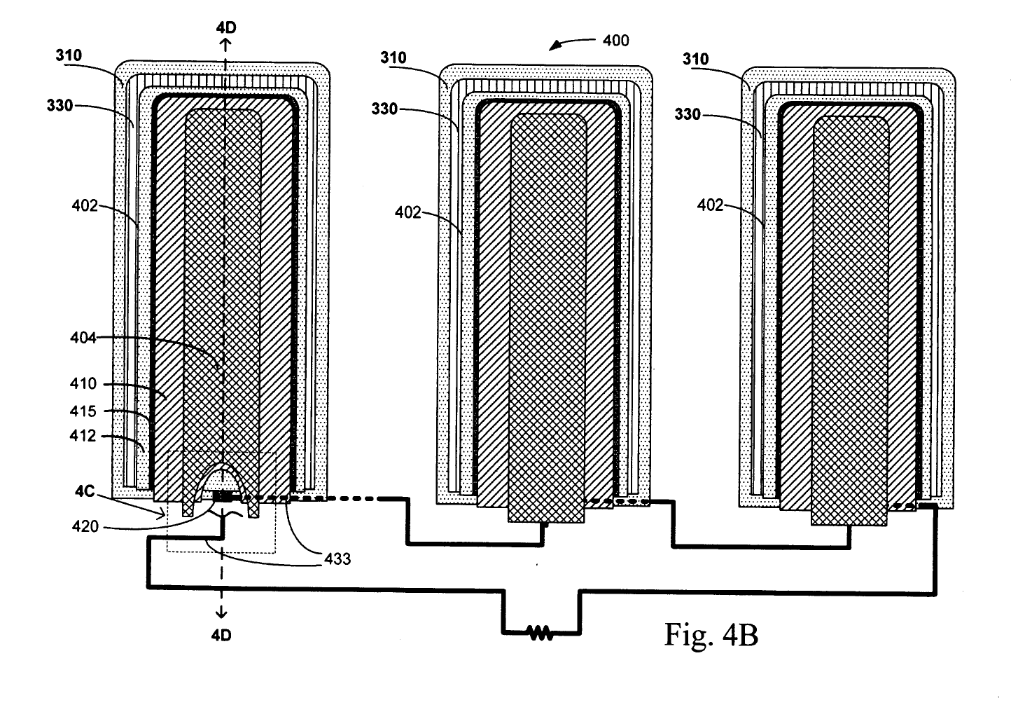

In some embodiments, there is a first groove 777-1 and a second groove 777-2 that each runs lengthwise on opposing sides of solar cell 402. In FIG. 7A, some but not all grooves 777 are labeled. In some embodiments, there is a counter-electrode 420 in one or both grooves of the solar cells. In the embodiment illustrated in FIG. 6A, there is a counter-electrode fitted lengthwise in both the first and second grooves of each solar cell in the plurality of solar cells. Such a configuration is useful because it reduces the path length of current drawn off of transparent conductive layer 412. In other words, the maximum length that current must travel in transparent conductive layer 412 before it reaches a counter-electrode 420 is a quarter of the circumference of the transparent conductive layer. By contrast, in configurations where there is only a single counter-electrode 420 associated with a given solar cell 402, the maximum length that current must travel in transparent conductive layer 412 before it reaches a counter-electrode 420 is a full half of the circumference of the transparent conductive layer 412. The present application encompasses grooves 777 that have a broad range of depths and shape characteristics and is by no means limited to the shape of the grooves 777 illustrated in FIG. 7A. In general, any groove shape 777 that runs along the long axis of a solar cell 402 and that can accommodate all or part of counter-electrode 420 is within the scope of the present application. For example, in some embodiments not illustrated by FIG. 7A, each groove 777 is patterned so that there is a tight fit between the contours of the groove 777 and the counter-electrode 420.

In the embodiment illustrated in FIG. 7A, there are a plurality of metal counter-electrodes 420, and each respective elongated solar cell 402 in the plurality of elongated solar cells is bound to at least a first corresponding metal counter-electrode 420 in the plurality of metal counter-electrodes such that the first metal counter-electrode lies in a groove 777 that runs lengthwise along the respective elongated solar cell. Furthermore, in the solar cell assembly illustrated in FIG. 7A, each respective elongated solar cell 402 is bound to a second corresponding metal counter-electrode 420 such that the second metal counter-electrode lies in a second groove 777 that runs lengthwise along the respective elongated solar cell 402. As further illustrated in FIG. 7A, the first groove 777 and the second groove 777 are on opposite or substantially opposite sides of the respective elongated solar cell 402 and run along the long axis of the cell.

In some embodiments, transparent casing 310, such as the transparent casing 310 depicted in FIG. 14, is used to encase elongated solar cells 402. Because it is useful to exclude air from the solar cell unit 402, an optional filler material 330 can be disposed between solar cell 402 and transparent casing 310 in the manner illustrated in FIG. 7A in some embodiments of the present application. For example, in some embodiments the filler material occupies at least 50%, or at least 75%, or at least 90%, or at least 95%, or 100%, of a volume formed between solar cell 402 and transparent casing 310.

In some embodiments, filler material 330 prevents the seepage of oxygen and water into solar cells 402. In some embodiments, filler material 330 includes EVA or silicone. In some embodiments, the optional filler material 330 is a laminate such as any of those disclosed in U.S. patent application Ser. No. 12/039,659, filed Feb. 28, 2008, the entire contents of which are hereby incorporated by reference herein. In some embodiments, the individually encased solar cells 402 are assembled into a planar array as depicted in FIG. 7A. The plurality of elongated solar cells 402 are configured to receive direct (unreflected) light from both face 733 and face 766 of the planar array.

FIG. 7B provides a cross-sectional view with respect to line 7B-7B of FIG. 7A. Solar cells 402 are electrically connected to each other in series by arranging the solar cells such that they do not touch each other, as illustrated in FIGS. 7A and 7B and by the use of electrical contacts as described below in conjunction with FIG. 7B. Although the individual solar cells are shown separate from each other to reveal the encapsulating features of transparent casing 310, no actual separation distance between solar cells 402 is required since transparent casing 310 shields the individual solar cells 402 of solar cell unit 300 from any unfavorable electrical contacts. However, tight space or no space packing is not a required for individually shielded solar cell unit 300. In fact, the presence of the transparent casing 310 provides more versatility in the solar cell assembly. For instance, in some embodiments, the distance between adjacent solar cell units 300 is 0 microns or greater, 0.1 microns or greater, 0.5 microns or greater, or between 1 and 5 microns, or correlated with the size and dimensions of the solar cell units 300.

Referring to FIG. 7B, serial electrical contact between solar cells 402 is made by electrical contacts 788 that electrically connect the back-electrode 404 of one elongated solar cell 402 to the corresponding counter-electrodes 120 of a different solar cell 402. FIG. 7B further illustrates a cutaway of metal conductive core 404 and semiconductor junction 410 in one solar cell 402 to further illustrate the architecture of solar cells 402.

The solar cell assembly illustrated in FIG. 7B has several useful aspects. First, the planar arrangement of the solar cells 402 leaves almost zero percent shading in the assembly. For instance, the assembly can receive direct sunlight from both face 733 and face 766. Second, in embodiments where individually encapsulated solar cells 402 are aligned parallel to each other with no or little space separation, the structure is completely self-supporting. Still another useful feature of the assembly is ease of manufacture. Unlike solar cells such as that depicted in FIG. 2B, no complicated grid or transparent conductive oxide on glass is required. For example, to assemble a solar cell 402 and its corresponding counter-electrodes 420 together to complete the circuit illustrated in FIG. 7A, counter-electrode 420, when it is in the form of a wire, can be covered with conductive epoxy and dropped in the groove 777 of solar cell 402 and allowed to cure.

As illustrated in FIG. 7B, conductive core 404, junction 410, and transparent conductive layer 412 are flush with each other at end 789 of elongated solar cells 402. In contrast, at end 799, the conductive core protrudes a bit with respect to junction 410 and transparent conductive layer 412 as illustrated. Junction 410 also protrudes a bit at end 799 with respect to transparent conductive layer 412. The protrusion of conductive core 404 at end 799 means that the sides of a terminal portion of the conductive core 404 are exposed (e.g., not covered by junction 410 and transparent conductive layer 412). One feature of this configuration is that it reduces the chances of shorting counter-electrode 420 (or the epoxy used to mount the counter-electrode in groove 777) with transparent conductive layer 412. In some embodiments, all or a portion of the exposed surface area of counter-electrodes 420 are shielded with an electrically insulating material in order to reduce the chances of electrical shortening. For example, in some embodiments, the exposed surface area of counter-electrodes 420 in the boxed regions of FIG. 7B is shielded with an electrically insulating material.

Still another useful feature of the assembly illustrated in FIG. 7B is that the counter-electrode 420 can have much higher conductivity without shadowing. In other words, counter-electrode 420 can have a substantial cross-sectional size (e.g., 1 mm in diameter when solar cell 402 has a 6 mm diameter). Thus, counter-electrode 420 can carry a significant amount of current so that the wires can be as long as possible, thus enabling the fabrication of larger panels.

The series connections between solar cells 402 can be between pairs of solar cells 402 in the manner depicted in FIG. 7B. However, the application is not so limited. In some embodiments, two or more solar cells 402 are grouped together (e.g., electrically connected in a parallel fashion) to form a group of solar cells and then such groups of solar cells are serially connected to each other. Therefore, the serial connections between solar cells can be between groups of solar cells where such groups have any number of solar cells 402 (e.g., 2, 3, 4, 5, 6, etc.). However, FIG. 7B illustrates one embodiment in which each contact 788 serially connects only a pair of solar cells 402.

Yet another useful feature of the assembly illustrated in FIG. 7B is that transparent casing 310 is circumferentially disposed on solar cells 402. In some embodiments, an optional filler material 330 lies between the outer surface of solar cell 402 and the inner surface of transparent casing 310. Although FIG. 7B only depicts electrical circuitry at one end of adjacent solar cell units 300, it is possible for electrical circuitry to be established at both ends of solar cell units 300 or between the two ends of solar cell units 300.

Some embodiments of solar cells in accordance with the present application have the feature that each individual solar cell 402 is encapsulated by transparent casing 310. Transparent casing 310 is at least partially transparent and made of non-conductive material such as plastics or glass. Accordingly, solar cell assemblies made according to the present design do not require insulator lengthwise between each solar cell 402. Yet another embodiment of solar cell assembly 700 is one in which there is substantially no extra absorption loss from a transparent conductive layer or a metal grid on one side of the assembly. Further, assembly 700 has the same performance or absorber area exposed on both sides 733 and 766. This makes assembly 700 symmetrical.

Still another useful feature of the illustrated embodiment of assembly 700 is that all electrical contacts 788 end at the same level (e.g., in the plane of line 7B-7B of FIG. 7A). As such, they are easier to connect and weld with very little substrate area wasted at the end. This simplifies construction of the solar cells 402 while at the same time serves to increase the overall efficiency of solar cell assembly 700. This increase in efficiency arises because the welds can be smaller.

Although not illustrated in FIG. 7A, in some embodiments in accordance with FIG. 7A, there is an intrinsic layer 415 disposed on all or a portion of between the semiconductor junction 410 and the transparent conductive layer 412 in an elongated solar cell 402 in the plurality of elongated solar cells 402. Intrinsic layer 415 can include an undoped transparent oxide such as zinc oxide, metal oxide, or any transparent metal that is highly insulating. In some embodiments, the semiconductor junction 410 of solar cells 402 in assembly 700 include an inner coaxial layer and an outer coaxial layer where the outer coaxial layer includes a first conductivity type and the inner coaxial layer includes a second, opposite, conductivity type. In an exemplary embodiment, the inner coaxial layer includes copper-indium-gallium-diselenide (CIGS) whereas the outer coaxial layer includes In₂Se₃, In₂S₃, ZnS, ZnSe, CdInS, CdZnS, ZnIn₂Se₄, Zn₁₋ₓMgₓO, CdS, SnO₂, ZnO, ZrO₂, or doped ZnO. In some embodiments not illustrated by FIG. 7A, conductive cores 404 in solar cells 402 are hollowed.

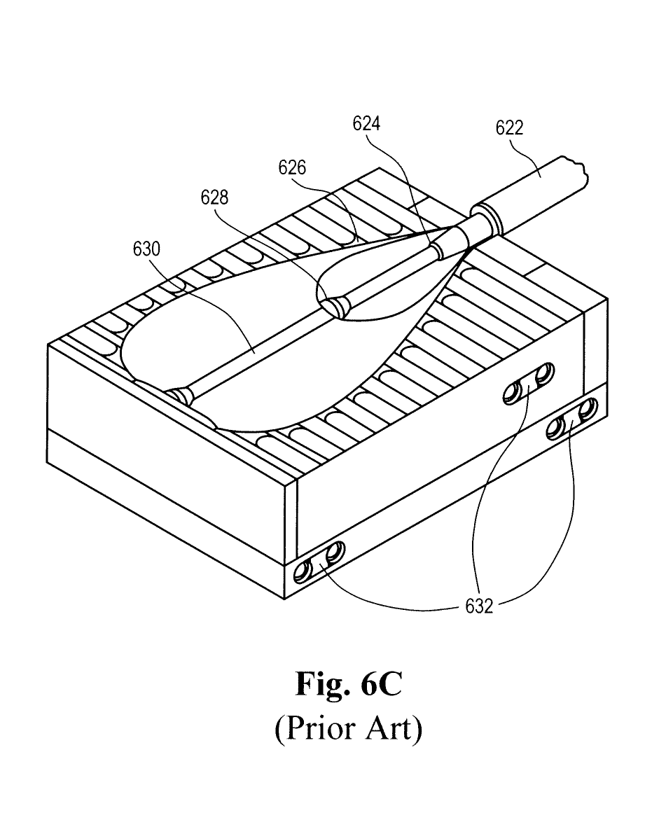

FIG. 8 illustrates an embodiment of a solar cell assembly 800 of the present application that is identical to solar cell assembly 700 of the present application with the exception that transparent conductive layer 412 is interrupted by breaks 810 that run along the long axis of solar cells 402 and cut completely through transparent conductive layer 412. In the embodiment illustrated in FIG. 8, there are two breaks 810 that run the length of solar cell 402. The effect of such breaks 810 is that they electrically isolate the two counter-electrodes 420 associated with each solar cell 402 in solar cell assembly 800. There are many ways in which breaks 800 can be made. For example, a laser or an HCl etch can be used.

In some embodiments, not all elongated solar cells 402 in assembly 800 are electrically arranged in series. For example, in some embodiments, there are pairs of elongated solar cells 402 that are electrically arranged in parallel. A first and second elongated solar cell can be electrically connected in parallel, and are thereby paired, by using a first electrical contact (e.g., an electrically conducting wire, etc., not shown) that joins the conductive core 404 of a first elongated solar cell to the second elongated solar cell. To complete the parallel circuit, transparent conductive layer 412 of the first elongated solar cell 402 is electrically connected to transparent conductive layer 412 of the second elongated solar cell 402 either by contacting the transparent conductive layers of the two elongated solar cells either directly or through a second electrical contact (not shown). The pairs of elongated solar cells are then electrically arranged in series. In some embodiments, three, four, five, six, seven, eight, nine, ten, eleven or more elongated solar cells 402 are electrically arranged in parallel. These parallel groups of elongated solar cells 402 are then electrically arranged in series.

In some embodiments, transparent casing 310, such as depicted in FIG. 14, is used to encase elongated solar cells 402. Because it is useful to exclude air from the solar cell unit 402, a filler material 330 may be used to prevent oxidation of the solar cell 402. As illustrated in FIG. 8, filler material 330 (for example EVA) prevents seepage of oxygen and water into solar cells 402. Filler material is disposed between solar cell 402 and the inner layer of transparent casing 310. In some embodiments, the individually encapsulated solar cells 402 are assembled into a planar array as depicted in the embodiment of FIG. 8.

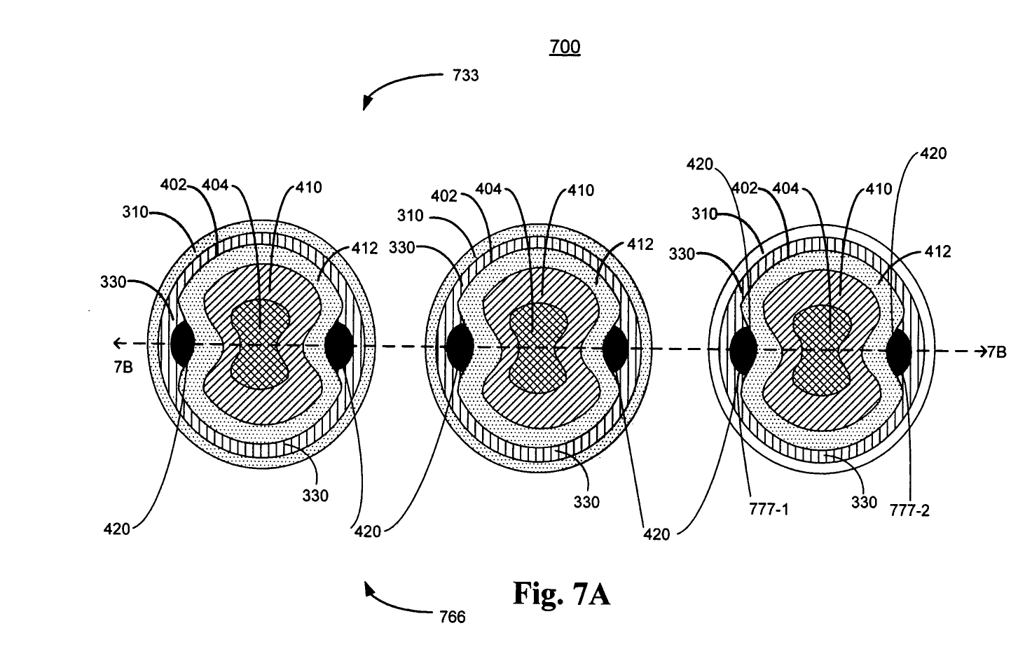

FIG. 9 illustrates an embodiment of a solar cell assembly 900 of the present application in which back-electrodes 404 are hollowed. In fact, back-electrode 404 can be hollowed in any of the embodiments of the present application. One useful aspect of a hollowed back-electrode 404 design is that it reduces the overall weight of the solar cell assembly. Back-electrode 404 is hollowed when there is a channel that extends lengthwise through all or a portion of back-electrode 404. In some embodiments, back-electrode 404 is metal tubing. In some embodiments, back-electrode 404 is a thin layer of electrically conducting material, e.g. molybdenum, that is disposed on all or a portion of a substrate 403 as illustrated in FIG. 3B. In some embodiments, substrate 403 is made of glass or any other suitable material (e.g., any of the materials described above in conjunction with the general description of substrate 403).

In some embodiments, not all elongated solar cells 402 in assembly 900 are electrically arranged in series. For example, in some embodiments, there are pairs of elongated solar cells 402 that are electrically arranged in parallel. The pairs of elongated solar cells are then electrically arranged in series. In some embodiments, three, four, five, six, seven, eight, nine, ten, eleven or more elongated solar cells 402 are electrically arranged in parallel. These parallel groups of elongated solar cells 402 are then electrically arranged in series.

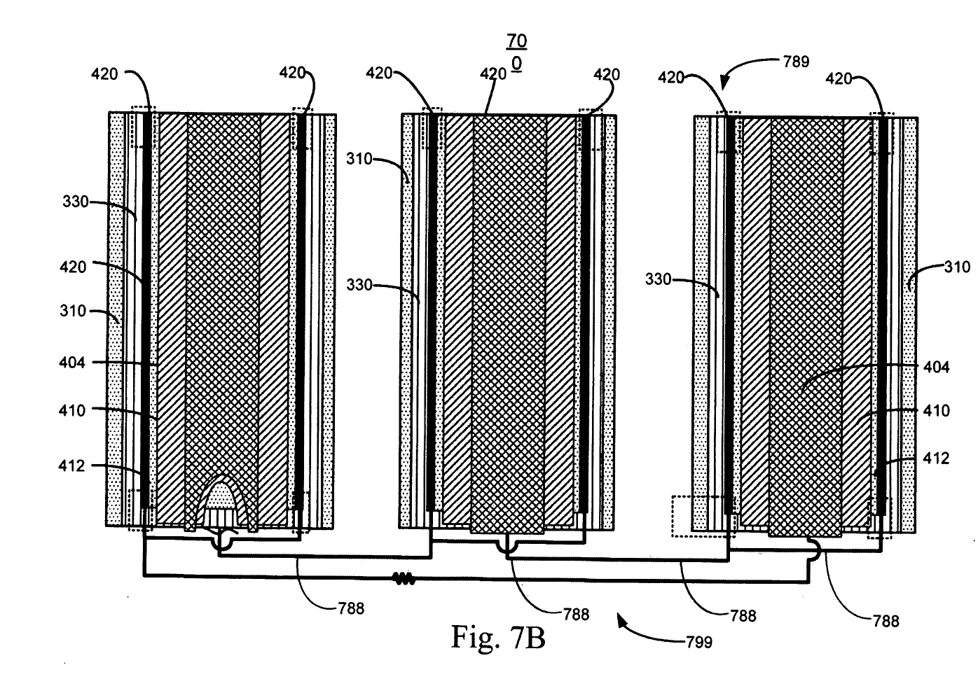

In some embodiments, a transparent casing 310, for example as depicted in FIG. 14, can be used to encase elongated solar cells 402. Because it is useful to exclude air from the solar cell unit 402, additional sealant may be used to prevent oxidation of the solar cell 402. Alternatively, as illustrated in FIG. 9, an optional filler material 330 (for example, EVA or silicone, etc.) may be used to reduce or inhibit seepage of oxygen and water into solar cells 402. In some embodiments, the individually encased solar cells 402 are assembled into a planar array as depicted in FIG. 9. FIG. 10 illustrates an embodiment of a solar cell assembly 1000 of the present application in which counter-electrodes 420, transparent conductive layers 412, and junctions 410 are pierced, in the manner illustrated, in order to form two discrete junctions in parallel. In some embodiments, transparent casing 310, for example as depicted in FIG. 14, may be used to encase elongated solar cells 402 with or without optional filler material 330.

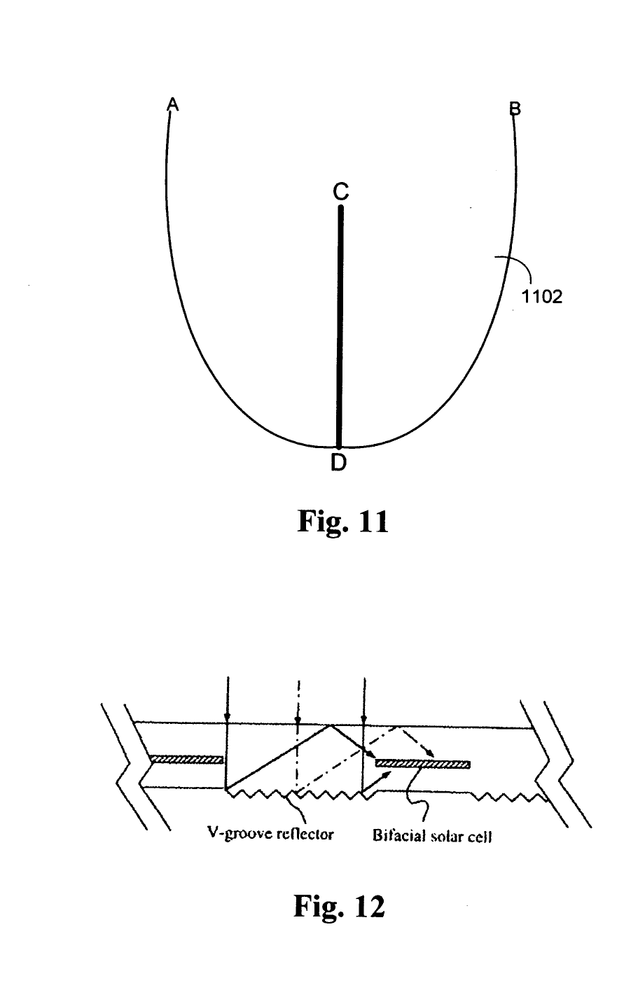

FIG. 15 illustrates an elongated solar cell 402 in accordance with the present application. A transparent casing 310 encases the elongated solar cell 402, leaving only ends of electrodes 420 exposed to establish suitable electrical connections. The ends of the elongated solar cell 402 are stripped and conductive layer 404 is exposed. As in previous embodiments, back-electrode 404 serves as the first electrode in the assembly and transparent conductive layer 412 on the exterior surface of each elongated solar cell 402 serves as the counter-electrode. In some embodiments in accordance with the present application as illustrated in FIG. 15, however, protruding counter-electrodes 420 and electrodes 440, which are attached to the elongated solar cell 402, provide convenient electrical connection.

In some embodiments as shown in FIG. 15, there is a first groove 677-1 and a second groove 677-2 that each runs lengthwise on opposing sides of elongated solar cell 402. In some embodiments, counter-electrodes 420 are fitted into grooves 677 in the manner illustrated in FIG. 15. Typically, such counter-electrodes 420 are glued into grooves 677 using a conductive ink or conductive glue. For example, CuPro-Cote (available from Lessemf.com, Albany, N.Y.), which is a sprayable metallic coating system using a non-oxidizing copper as a conductor, can be used. In some embodiments, counter-electrodes 420 are fitted in to grooves 677 and then a bead of conductive ink or conductive glue is applied. As in previous embodiments, the present application encompasses grooves 677 that have a broad range of depths and shape characteristics and is by no means limited to the shape of the grooves 677 illustrated in FIG. 15. In general, any type of groove 677 that runs along the long axis of a first solar cell 402 and that can accommodate all or part of counter-electrode 420 is within the scope of the present application. Counter-electrodes 420 conduct current from the combined layer 410/(415)/412. At the regions at both ends of elongated solar cell 402, counter-electrodes 420 are sheathed as shown in FIG. 15 so that they are electrically isolated from conductive layer 404. The ends of protruding counter-electrodes 420, however, are unsheathed so they can form electric contact with additional devices. In some embodiments, grooves 677 and counter-electrodes 420 are not present. For example, in some embodiments, a monolithic integration strategy such as disclosed in U.S. Pat. No. 7,235,736, entitled “Monolithic Integration of Cylindrical Solar Cells,” which is hereby incorporated by reference herein in its entirety, is used.

In the embodiments as depicted in FIG. 15, a second set of electrodes 440 are attached to the exposed back-electrode 404. The second set of electrodes 440 conduct current from back-electrode 404. As illustrated in FIG. 15, an embodiment in accordance with the present application has two electrodes 440 attached at two opposing ends of each elongated solar cell 402. Typically, electrodes 440 are glued onto back-electrode 404 using a conductive ink or conductive glue. For example, CuPro-Cote can be used. In some embodiments, electrodes 440 are glued to layer 404 and then a bead of conductive ink or conductive glue is applied. Care is taken so that electrodes 440 are not in electrical contact with layer 410/(415)/412. Additionally, electrodes 440 in the present application have a broad range of lengths and widths and shape characteristics and are by no means limited to the shape of 440 illustrated in FIG. 15. In the embodiments as shown in FIG. 15, the two electrodes 440 on opposite ends of the elongated solar cell 402 are not on the same side of the solar cell cylinder. The first electrode 440 is on the bottom side of the elongated solar cell 402 while the second electrode 440 is on the top side of the elongated solar cell 402. Such an arrangement facilitates the connection of the solar cells in a serial manner. In some embodiments in accordance with the present application, the two electrodes 440 can be on the same side of elongated solar cell 402.

In some embodiments, each electrode 440 is made of a thin strip of conductive material that is attached to conductive layer 404/1304 (FIG. 15). In some embodiments, each electrode 440 is made of a conductive ribbon of metal (e.g., copper, aluminum, gold, silver, molybdenum, or an alloy thereof) or a conductive ink. As will be explained in conjunction with subsequent drawings, counter-electrode 420 and electrodes 440 are used to electrically connect elongated solar cells 402, e.g., in series. However, such counter-electrodes are optional.

### 5.1.2 Transparent Casing

An at least partially transparent casing 310, such as those depicted in FIGS. 3A through 3C, encases a solar cell unit 402 to provide support and protection to the solar cell. The size and dimensions of transparent casing 310 are determined by the size and dimension of individual solar cells 402 in a solar cell assembly unit 402. Transparent casing 310 may be made of glass, plastic or any other suitable material. Examples of materials that can be used to make transparent casing 310 include, but are not limited to, glass (e.g., soda lime glass), acrylics such as polymethylmethacrylate, polycarbonate, fluoropolymer (e.g., Tefzel or Teflon), polyethylene terephthalate (PET), Tedlar, or some other suitable transparent material. Below are described exemplary methods used to make transparent casing 310. In some embodiments, the transparent casing 310 is then sealed with a filler material 330 that is poured into the casing 310 in liquid or semi-liquid form, thereby sealing the device.

### 5.1.2.1 Transparent Casing Construction

In some embodiments, transparent casing 310 is constructed using blow molding. Blow molding involves clamping the ends of a softened tube of polymers, which can be either extruded or reheated, inflating the polymer against the mold walls with a blow pin, and cooling the product by conduction or evaporation of volatile fluids in the container. Three general types of blow molding are extrusion blow molding, injection blow molding, and stretch blow molding. U.S. Pat. No. 237,168 describes a process for blow molding (e.g., 602 in FIG. 6A). Other forms of blow molding that can be used to make transparent casing 310 include low density polyethylene (LDPE) blow molding, high density polyethylene (HDPE) blow molding and polypropylene (PP) blow molding.

Extrusion blow molding. As depicted in FIG. 6A, the extrusion blow molding method includes a Parison (e.g., 602 in FIG. 6A) and mold halves that close onto the Parison (e.g., 604 in FIG. 6A). In extrusion blow molding (EBM), material is melted and extruded into a hollow tube (e.g., a Parison as depicted in FIG. 6A). The Parison is then captured by closing it into a cooled metal mold. Air is then blown into the Parison, inflating it into the shape of the hollow bottle, container or part. After the material has cooled sufficiently, the mold is opened and the part is ejected.

EBM processes consist of either continuous or intermittent extrusion of the Parison 602. The types of EBM equipment may be categorized accordingly. Typical continuous extrusion equipments usually include rotary wheel blow molding systems and a shuttle machinery that transports the finished products from the Parison. Exemplary intermittent extrusion machinery includes a reciprocating screw machinery and an accumulator head machinery. Basic polymers, such as PP, HDPE, PVC and PET are increasingly being coextruded with high barrier resins, such as EVOH or Nylon, to provide permeation resistance to water, oxygen, CO₂ or other substances.

Compared to injection molding, blow molding is a low pressure process, with typical blow air pressures of 25 to 150 psi. This low pressure process allows the production of economical low-force clamping stations, while parts can still be produced with surface finishes ranging from high gloss to textured. The resulting low stresses in the molded parts also help make the containers resistant to strain and environmental stress cracking.

Injection blow molding. In injection blow molding (IBM), as depicted in FIG. 6B, material is injection molded onto a core pin (e.g., 612 in FIG. 6B); then the core pin is rotated to a blow molding station (e.g., 614 in FIG. 6B) to be inflated and cooled. The process is divided in to three steps: injection, blowing and ejection. A typical IBM machine is based on an extruder barrel and screw assembly which melts the polymer. The molten polymer is fed into a manifold where it is injected through nozzles into a hollow, heated preform mold (e.g., 614 in FIG. 6B). The preform mold forms the external shape and is clamped around a mandrel (the core rod, e.g., 612 in FIG. 6B) which forms the internal shape of the preform. The preform consists of a fully formed bottle/jar neck with a thick tube of polymer attached, which will form the body.

The preform mold opens and the core rod is rotated and clamped into the hollow, chilled blow mold. The core rod 612 opens and allows compressed air into the preform 614, which inflates it to the finished article shape. After a cooling period the blow mold opens and the core rod is rotated to the ejection position. The finished article is stripped off the core rod and leak-tested prior to packing. The preform and blow mold can have many cavities, typically three to sixteen depending on the article size and the required output. There are three sets of core rods, which allow concurrent preform injection, blow molding and ejection.

Stretch blow molding In the stretch blow molding (SBM) process, as depicted in FIG. 6C, the material is first molded into a “preform,” e.g., 628 in FIG. 6C, using the injection molded process. A typical SBM system includes a stretch blow pin (e.g., 622 in FIG. 6C), an air entrance (e.g., 624 in FIG. 6C), mold vents (e.g., 626 in FIG. 6C), a preform (e.g., 628 in FIG. 6C), and cooling channels (e.g., 632 in FIG. 6C). These preforms are produced with the necks of the bottles, including threads (the “finish”) on one end. These preforms are packaged, and fed later, after cooling, into an EBM blow molding machine. In the SBM process, the preforms are heated, typically using infrared heaters, above their glass transition temperature, then blown using high pressure air into bottles using metal blow molds. Usually the preform is stretched with a core rod as part of the process (e.g., as in position 630 in FIG. 6C). The stretching of some polymers, such as PET (polyethylene terephthalate), results in strain hardening of the resin and thus allows the bottles to resist deforming under the pressures formed by carbonated beverages, which typically approach 60 psi.

FIG. 6C shows what happens inside the blow mold. The preform is first stretched mechanically with a stretch rod. As the rod travels down low-pressure air of 5 to 25 bar (70 to 350 psi) is introduced blowing a ‘bubble’. Once the stretch rod is fully extended, high-pressure air of up to 40 bar (580 psi) blows the expanded bubble into the shape of the blow mold.

Plastic tube manufacturing. In some embodiments, transparent casing 310 is made of plastic rather than glass. Production of transparent casing 310 in such embodiments differs from glass transparent casing 310 production even though the basic molding mechanisms remain the same. A typical plastic transparent casing 310 manufacturing process includes the following steps: extrusion, heading, decorating, and capping, with the latter two steps being optional.

In some embodiments, transparent casing 310 is made using extrusion molding. A mixture of resin is placed into an extruder hopper. The extruder is temperature controlled as the resin is fed through to ensure proper melt of the resin. The material is extruded through a set of sizing dies that are encapsulated within a right angle cross section attached to the extruder. The forming die controls the shape of transparent casing 310. The formed plastic sleeve cools under blown air or in a water bath and hardens on a moving belt. After cooling step, the formed plastic sleeve is ready for cutting to a given length by a rotating knife.

The forming die controls the shape of the transparent casing 310. In some embodiments in accordance with the present application, as depicted in FIG. 14, the forming dies are custom-made such that the shape of transparent casing 310 complements the shape of the solar cell unit 402. The forming die also controls the wall thickness of the transparent casing 310. In some embodiments in accordance with the present application, transparent casing 310 has a wall thickness of 2 mm or thicker, 1 mm or thicker, 0.5 mm or thicker, 0.3 mm or thicker, or of any thickness between 0 and 0.3 mm.

During the production of one open-ended transparent casings, the balance of the manufacturing process can be accomplished in one of three ways. The most common method in the United States is the “downs” process of compression, molding the head onto the tube. In this process, the sleeve is placed on a conveyor that takes it to the heading operation where the shoulder of the head is bound to the body of the tube while, at the same time, the thread is formed. The sleeve is then placed on a mandrel and transferred down to the slug pick-up station. The hot melt strip or slug is fused onto the end of the sleeve and then transferred onto the mold station. At this point, in one operation, the angle of the shoulder, the thread and the orifice are molded at the end of the sleeve. The head is then cooled, removed from the mold, and transferred into a pin conveyor. Two other heading methods are used in the United States and are found extensively worldwide: injection molding of the head to the sleeve, and an additional compression molding method whereby a molten donut of resin material is dropped into the mold station instead of the hot melt strip or slug. Transparent casings with one open-end are suitable to encase solar cell embodiments as depicted in FIG. 3A-3C, 4A-4D, 7A-7B, 8, 9, or 10. Plastic tubing with both ends open may be used to encase solar cell embodiments as depicted in FIGS. 3A-3C and 15.

The headed transparent casing 310 is then conveyed to the accumulator. The accumulator is designed to balance the heading and decorating operation. From here, the transparent casing 310 may go to the decorating operation. Inks for the press are premixed and placed in the fountains. At this point, the ink is transferred onto a plate by a series of rollers. The plate then comes in contact with a rubber blanket, picking up the ink and transferring it onto the circumference of the transparent casing 310. The wet ink on the tube is cured by ultra-violet light or heat. In the embodiments in accordance with the present application, transparency is required in the tube products so the color process is unnecessary. However, a similar method may be used to apply a protective coating to transparent casing 310.

After decorating, a conveyor transfers the tube to the capping station where the cap is applied and torqued to the customer's specifications. The capping step is unnecessary for the scope of this application.

Additional glass fabrication methods. Glass is a useful material choice for transparent casing 310 relative to plastics because glass can provide enhanced waterproofing and therefore prolong the lifetime of solar cell 402. Similar to plastics, glass may be made into transparent casing 310 using the standard blow molding technologies. In addition, techniques such as casting, extrusion, drawing, pressing, heat shrinking or other fabrication processes may also be applied to manufacture suitable glass transparent casing 310 to encase elongated solar cells 402. Molding technologies, in particular micromolding technologies for microfabrication, are discussed in greater detail in Madou, Fundamentals of Microfabrication, Chapter 6, pp. 325-379, second edition, CRC Press, New York, 2002; Polymer Engineering Principles. Properties, Processes, and Tests for Design, Hanser Publishers, New York, 1993; and Lee, Understanding Blow Molding, first edition., Hanser Gardner Publications, Munich, Cincinnati, 2000, each of which is hereby incorporated herein by reference in its entirety.

### 5.1.2.2 Exemplary Materials for Transparent Casing

Transparent casing made of glass. In some embodiments, transparent casing 310 is made of glass. In its pure form, glass is a transparent, relatively strong, hard-wearing, essentially inert, and biologically inactive material that can be formed with very smooth and impervious surfaces. The present application contemplates a wide variety of glasses for use in making transparent casing 310, some of which are described in this section and others of which are know to those of skill in the relevant arts. Common glass contains about 70% amorphous silicon dioxide (SiO₂), which is the same chemical compound found in quartz, and its polycrystalline form, sand. Common glass is used in some embodiments of the present application to make transparent casing 310. However, common glass is brittle and will break into sharp shards. Thus, in some embodiments, the properties of common glass are modified, or even changed entirely, with the addition of other compounds or heat treatment.

Pure silica (SiO₂) has a melting point of about 2000° C., and can be made into glass for special applications (for example, fused quartz). Two other substances can be added to common glass to simplify processing. One is soda (sodium carbonate Na₂CO₃), or potash, the equivalent potassium compound, which lowers the melting point to about 1000° C. However, the soda makes the glass water-soluble, which is undesirable, so lime (calcium oxide, CaO) is the third component, added to restore insolubility. The resulting glass contains about 70% silica and is called a soda-lime glass. Soda-lime glass is used in some embodiments of the present application to make transparent casing 310.

Besides soda-lime, most common glass has other ingredients added to change its properties. Lead glass, such as lead crystal or flint glass, is more ‘brilliant’ because the increased refractive index causes noticeably more “sparkles”, while boron may be added to change the thermal and electrical properties, as in PYREX. Adding barium also increases the refractive index. Thorium oxide gives glass a high refractive index and low dispersion, and was formerly used in producing high-quality lenses, but due to its radioactivity has been replaced by lanthanum oxide in modern glasses. Large amounts of iron are used in glass that absorbs infrared energy, such as heat absorbing filters for movie projectors, while cerium(IV) oxide can be used for glass that absorbs UV wavelengths (biologically damaging ionizing radiation). Glass having on or more of any of these additives is used in some embodiments of the present application to make transparent casing 310.

Common examples of glass material include but are not limited to aluminosilicate, borosilicate (e.g., PYREX, DURAN, SIMAX), dichroic, germanium/semiconductor, glass ceramic, silicate/fused silica, soda lime, quartz, chalcogenide/sulphide, cereated glass, and fluoride glass and transparent casing 310 can be made of any of these materials.

In some embodiments, transparent casing 310 is made of glass material such as borosilicate glass. Trade names for borosilicate glass include, but are not limited to, PYREX® (Corning), DURAN® (Schott Glass), and SIMAX® (Kavalier). Like most glasses, the dominant component of borosilicate glass is SiO₂ with boron and various other elements added. Borosilicate glass is easier to hot work than materials such as quartz, making fabrication less costly. Material cost for borosilicate glass is also considerably less than fused quartz. Compared to most glass, except fused quartz, borosilicate glass has low coefficient of expansion, three times less than soda lime glass. This makes borosilicate glass useful in thermal environments, without the risk of breakage due to thermal shock. Like soda lime glass, a float process can be used to make relatively low cost optical quality sheet borosilicate glass in a variety of thickness from less than 1 mm to over 30 mm thick. Relative to quartz, borosilicate glass is easily moldable. In addition, borosilicate glass has reduced devitrification when molding and flame working. This means high quality surfaces can be maintained when molding and slumping. Borosilicate glass is thermally stable up to 500° C. for continuous use. Borosilicate glass is also more resistant to non-fluorinated chemicals than household soda lime glass and mechanically stronger and harder than soda lime glass. Borosilicate is usually two to three times more expensive than soda lime glass.

Soda lime and borosilicate glass are only given as examples to illustrate the various aspects of consideration when using glass material to fabricate transparent casing 310. The preceding discussion imposes no limitation to the scope of the application. Indeed, transparent casing 310 can be made with glass such as, for example, aluminosilicate, borosilicate (e.g., PYREX®, DURAN®, SIMAX®), dichroic, germanium/semiconductor, glass ceramic, silicate/fused silica, soda lime, quartz, chalcogenide/sulphide, cereated glass and/or fluoride glass.

Transparent casing made of plastic. In some embodiments, transparent casing 310 is made of at least partially transparent (e.g., clear) plastic. Plastics are a cheaper alternative to glass. However, plastic material is in general less stable under heat, has less favorable optical properties and does not prevent molecular water from penetrating through transparent casing 310. The last factor, if not rectified, may damage solar cells 402 and severely reduces their lifetime. Accordingly, in some embodiments, the water resistant layer described in Section 5.1.1 can be used to reduce or inhibit water seepage into the solar cells 402 when transparent casing 310 is made of plastic.

A wide variety of materials can be used in the production of transparent casing 310, including, but not limited to, ethylene vinyl acetate (EVA), perfluoroalkoxy fluorocarbon (PFA), nylon/polyamide, cross-linked polyethylene (PEX), polyolefin, polypropylene (PP), polyethylene terephthalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), TYGON®, Vinyl, and VITON®.

### 5.1.2.3 Available Commercial Sources of Transparent Tubing Products

There are ample commercial sources for obtaining or custom manufacturing transparent casing 310. Technologies for manufacturing plastic or glass tubing have been standardized and customized plastic or glass tubing are commercially available from numerous companies. A search on GlobalSpec database for “clear round plastic or glass tubing,” a web center of engineering resources (www.globalspec.com; GlobalSpec Inc. Troy, N.Y.), results in over 950 catalog products. Over 180 companies make specialty pipe, tubing, hose and fittings. For example, Clippard Instrument Laboratory, Inc. (Cincinnati, Ohio) provides Nylon, Urethane or Plastic Polyurethane tubing that is as thin as 0.4 mm. Coast Wire & Plastic Tech., Inc. (Carson, Calif.) manufactures a comprehensive line of polyvinylidene fluoride clear round plastic tubing product under the trademark SUMIMARK™. Their product has a wall thickness as thin as 0.3 mm. Parker Hannifin/Fluid Connectors/Parflex Division (Ravenna, Ohio) provides vinyl, plastic polyurethane, polyether base, or polyurethane based clear plastic tubing of 0.8 mm or 1 mm thickness. Similar polyurethane products may also be found in Pneumadyne, Inc (Plymouth, Minn.). Saint-Gobain High-Performance Materials (U.S.A) further provides a line of 30 Tygon® tubing products of 0.8 mm in thickness. Vindum Engineering, Inc. (San Ramon, Calif.) also provides clear PFA Teflon tube of 0.8 mm in thickness. NewAge Industries, Inc. (Southampton, Pa.) provides 63 clear round plastic tubing products that have a wall thickness of 1 mm or thinner. In particular, VisiPak Extrusion (Arnold, Mo.), a division of Sinclair & Rush, Inc., provides clear round plastic tubing product as thin as 0.5 mm. Cleartec Packaging (St. Louis, Mo., a division of MOCAP Inc.) manufactures clear round plastic tubing as thin as 0.3 mm.

In addition, numerous companies can manufacture clear round plastic or glass tubing with customized specification such as with even thinner walls. Some examples are Elasto Proxy Inc. (Boisbriand, Canada), Flex Enterprises, Inc. (Victor, N.Y.), Grob, Inc. (Grafton, Wis.), Mercer Gasket & Shim (Bellmawr, N.J.), New England Small Tube Corporation (Litchfield, N.H.), Precision Extrusion, Inc. (Glens Falls, N.Y.), and PSI Urethanes, Inc. (Austin, Tex.).

### 5.1.3 Integrating Solar Cells into Transparent Casings

In the present application, some or all gaps or spaces between transparent casing 310 and solar cell 402 are eliminated in order to avoid adverse effects such as oxidation. Thus, in some embodiments of the present application, there is substantially no space (e.g., no annular space) between the inside wall of transparent casing 310 and the outer wall of solar cell 402. In some embodiments (e.g., FIG. 3B), a filler material 330 is provided to seal a solar cell unit 402 from adverse exposure to water or oxygen. In some embodiments, a filler material 330 may be eliminated such that solar cells 402 directly contacts transparent casing 310.

In some embodiments, a custom-designed transparent casing 310, e.g., made of either glass or plastics or other suitable transparent material, may be used to encase the corresponding embodiments of solar cell 402 to achieve tight fitting and better protection. FIG. 14 depicts exemplary embodiments of transparent casing 310 that can provide proper encapsulation to the solar cell embodiments depicted in FIGS. 4A-4C, 7A-7B, 8, 9, 10, and 13.

In some embodiments, non-planar, elongated solar cells 402 that are individually encased by transparent casing 310 can be assembled into solar cell assemblies of any shape and size. In some embodiments, the assembly can be bifacial arrays 400 (FIG. 4A), 700 (FIG. 7A), 800 (FIG. 8), 900 (FIG. 9), or 1000 (FIG. 10). There is no limit to the number of solar cells 402 in this plurality (e.g., 10 or more, 100 or more, 1000 or more, 10,000 or more, between 5,000 and one million solar cells 402, etc.).

Alternatively, instead of being encapsulated individually and then being assembled together for example into planar arrays, solar cells 402 may also be encapsulated as arrays. For example, as depicted in FIG. 7C, multiple transparent casings 310 may be manufactured as fused arrays. Some such embodiments require little or no additional connection between the individual solar cells 402. In general, there is no limit to the number of transparent casings 310 in the assembly as depicted in FIG. 7C (e.g., 10 or more, 100 or more, 1000 or more, 10,000 or more, between 5,000 and one million transparent casings 310, etc.). A solar cell assembly is further completed by loading elongated solar cells 402 (for example 402 in FIG. 4A) into all or a portion of the transparent casing 310 in the array of casings.

### 5.1.3.1 Integrating Solar Cells Having a Filler Material into Transparent Casings

In some embodiments in accordance with the present application, a solar cell 402 is encased with a transparent casing 310, and a filler material fills some or all of the space between the transparent casing and the solar cell. In some embodiments in accordance with the present application, filler material 330 demonstrates one or more of the properties of: electrical insulation, oxidation eliminating effect, water proofing, and/or physical protection of transparent conductive layer 412 of solar cell 402 during assembly of solar cell units.

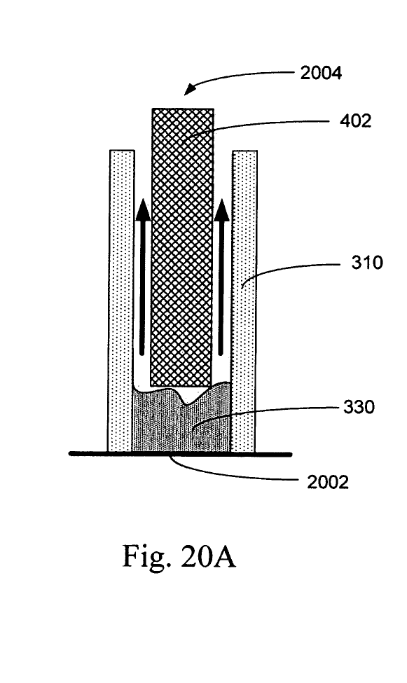

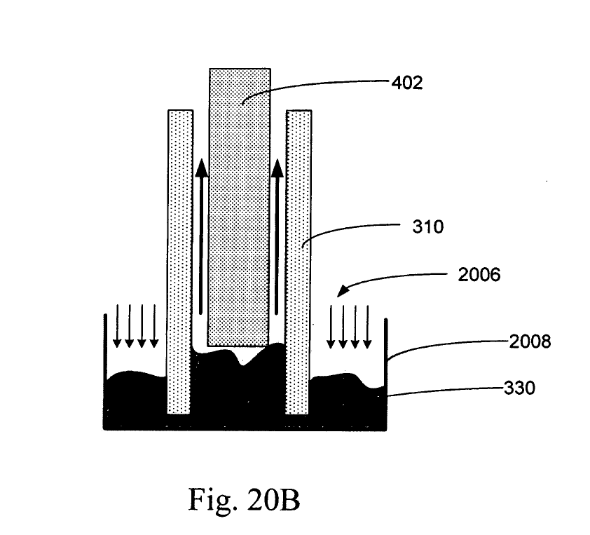

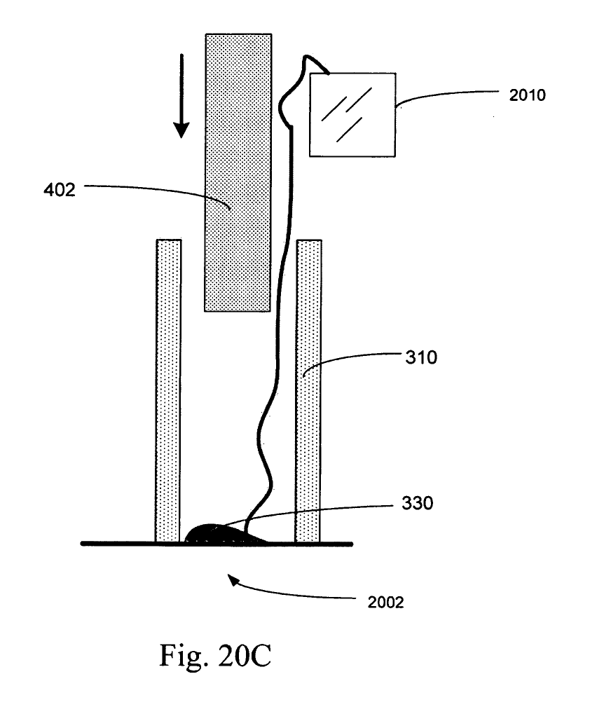

In some embodiments in accordance with the present application, an elongated solar cell 402, optional filler material 330, and a transparent casing 310 are assembled using a suction loading method illustrated in FIG. 20A. Transparent casing 310, made of transparent glass, plastics or other suitable material, is sealed at one end 2002. Materials that are used to form filler material 330, for example, silicone gel, is poured into the sealed transparent casing 310. The elongated solar cell 402 is then loaded into transparent casing 310. Optional suction force may be applied at the open end 2004 of transparent casing 310 to draw the filler material upwards to partially or completely fill the space between solar cell 402 and transparent casing 310.

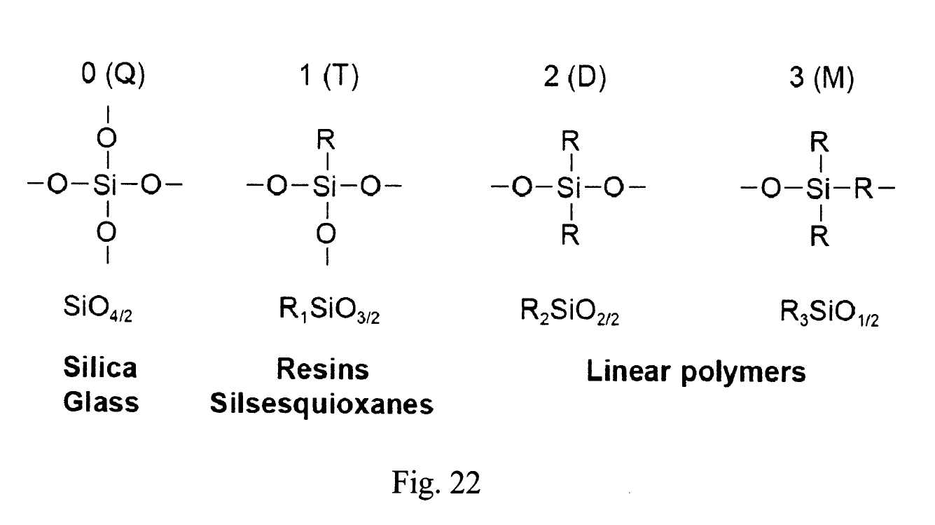

An example of a silicone gel suitable for use in filler material 330 is Wacker SILGEL® 612 (Wacker-Chemie GmbH, Munich, Germany). Wacker SILGEL® 612 is a pourable, addition-curing, RTV-2 silicone rubber that vulcanizes at room temperature to a soft silicone gel. Still another example of silicone gel is SYLGARD® silicone elastomer (Dow Corning). Another example of a silicone gel is Wacker ELASTOSIL® 601 (Wacker-Chemie GmbH, Munich, Germany). Wacker ELASTOSIL® 601 is a pourable, addition-curing, RTV-2 silicone rubber. Referring to FIG. 22, silicones can be considered a molecular hybrid between glass and organic linear polymers. As shown in FIG. 22, if there are no R groups, only oxygen, the structure is inorganic silica glass (called a Q-type Si). If one oxygen is substituted with an R group (e.g. methyl, ethyl, phenyl, etc.) a resin or silsequioxane (T-type Si) material is formed. These silsequioxanes are more flexible than the Q-type materials. Finally, if two oxygen atoms are replaced by organic groups a very flexible linear polymer (D-type silicone) is obtained. The last structure shown (M-type Si) has three oxygen atoms replaced by R groups, resulting in an end cap structure. Because the backbone chain flexibility is increasing as R groups are added, the modulus of the materials and their coefficients of thermal expansion (CTE) also change. In some embodiments of the present application the silicone used to form filler material is a Q-type silicone, a silsequioxane, a D-type silicone, or an M-type silicone.

In some embodiments in accordance with the present application, an elongated solar cell 402, filler material 330, and a transparent casing 310 may be assembled using the pressure loading method illustrated in FIG. 20B. Transparent casing 310, made of transparent glass, plastics or other suitable material, is dipped in container 2008 containing optional filler material (e.g., silicone gel) used to form optional filler material 330. Elongated solar cell 402 is then loaded into transparent casing 310. Pressure force is applied at filler material surface 2006 to push the filler material upwards to partially or completely fill the space between solar cell 402 and transparent casing 310.

In yet other embodiments in accordance with the present application, an elongated solar cell 402, filler material 330 and a transparent casing 310 is assembled using the pour-and-slide loading method depicted in FIG. 20C. A transparent casing 310, made of transparent glass, plastics or other suitable material, is sealed at one end 2002. A container 2010, containing filler material (e.g., silicone gel), is used to pour the filler material into the sealed transparent casing 310 while solar cell 402 is simultaneously slid into transparent casing 310. The filler material that is being poured into transparent casing 310 partially or completely fills up the space between solar cell 402 and transparent casing 310. Usefully, the filler material that is being poured down the side of transparent casing 310 provides lubrication to facilitate the slide-loading process.

### 5.1.3.2 Integrating Solar Cells Without an Optional Filler Material into Transparent Casings

In some embodiments in accordance with the present application, a casing 310 is assembled onto solar cell 402 without a filler material 330. In these embodiments, casing 310 may directly contact all or a portion of solar cell 402. Tight packing and casing 310 against solar cell 402 may be achieved, for example, by using one of the following methods. It will be appreciated that the methods for assembling a solar cell unit 300 described in this section can be used with solar cells 402 that are encased with a filler material 330.

Heat Shrink Loading. In some embodiments, transparent casing 310 heat shrinked around all or a portion of solar cell 402. The heat shrink method may be used to form both plastic and glass transparent casings 310. For example, heat-shrinkable plastic tubing made of polyolefin, fluoropolymer (PVC, FEP, PTFE, KYNAR® PVDF), chlorinated polyolefin (NEOPRENE) and highly flexible elastomer (VITON®) heat-shrinkable tubing may be used to form transparent casing 310. Among such materials, fluoropolymers offer increased lubricity for easy sliding, and low moisture absorption for enhanced dimensional stability. At least three such materials are commercially available: PTFE (polytetrafluoroethylene), FEP (fluorinated ethylene propylene) and PVDF (polyvinylidene fluoride, tradename KYNAR®). Transparent heat-shrinkable plastic tubing is available. In some embodiments, the heat shrink tubing is available in an expandable range of 2:1 to 3:1. In some embodiments, the heat shrink ratio of the tubing material is smaller than 2:1, for example, fluorinated ethylene-propylene (FEP) at 1.3:1. In other embodiments, a heat shrink tubing suitable for the manufacture of transparent casing 310 may have heat shrink ratio greater than 3:1.

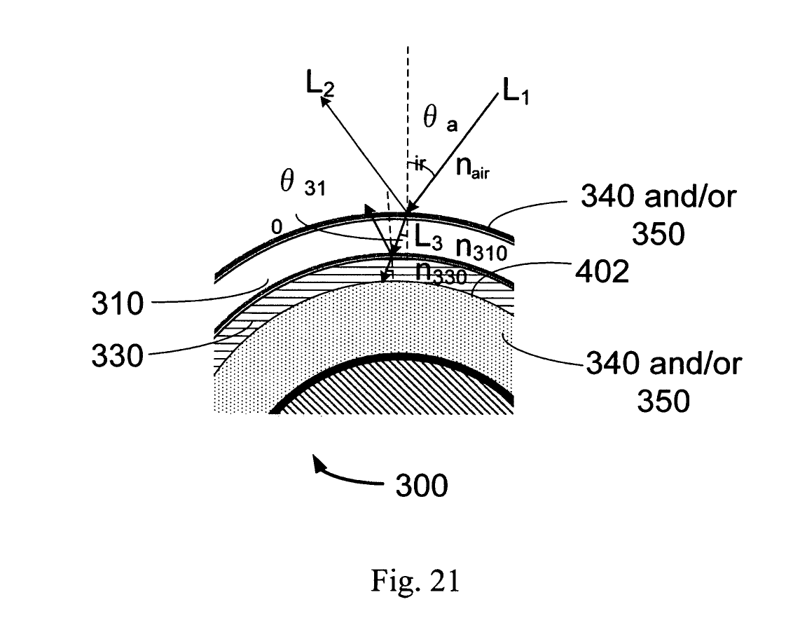

Injection molding to construct transparent casing. In some embodiments, transparent casing 310 may be disposed on all or a portion of solar cell 402 by using the method of injection molding. A more detailed description of the method is already included above. In these embodiments, solar cells 402 may be used as the preformed mold and transparent casing 310 (e.g., made of plastic material) is directly formed on the outer surface of solar cells 402. Plastic material does not completely seal molecular water from solar cells 402. Because water interferes with the function of a solar cell 402, it is therefore important to make the solar cell 402 resistant to water. In the embodiments where plastic transparent casings 310 are used to cover solar cells 402, this is accomplished by covering either the solar cell 402 or transparent casing 310 with one or more layers of transparent water-resistant coating 340 (FIG. 21). In some embodiments, both solar cell 402 and transparent casing 310 are coated with one or more layers of transparent water-resistant coating 340 to extend the functional life time of the solar cell unit 300. In other embodiments, an optional antireflective coating 350 is also disposed on transparent casing 310 to enhance solar cell efficiency.

Liquid Coating Followed by Polymerization. In some embodiments, solar cell 402 is dipped in a liquid-like suspension or resin and subsequently exposed to catalyst or curing agent to form transparent casing 310 through a polymerization process. In such embodiments, materials used to form transparent casing 310 include silicone, poly-dimethyl siloxane (PDMS), silicone gel, epoxy, acrylics, and any combination or variation thereof.

### 5.1.4 Optical and Chemical Properties of the Materials Used for Transparent Casing and Optional Filler Material

In order to enhance input of solar radiation, any layer outside a solar cell 402 (for example, optional filler material 330 or transparent casing 310) usefully does not significantly adversely affect the properties of incident radiation on the solar cell. There are multiple factors to consider in enhancing the efficiency of solar cells 402. A few significant factors will be discussed in detail in relation to solar cell production.

Transparency. In order to enhance input into solar cell absorption layer (e.g., semiconductor junction 410), absorption of the incident radiation by any layer outside a solar cell 402 should be reduced or inhibited. This transparency requirement varies as a function of the absorption properties of the underlying semiconductor junction 410 of solar cells 402. In general, transparent casing 310 and optional filler material 330 are usefully as transparent as possible to the wavelengths absorbed by the semiconductor junction 410. For example, when the semiconductor junction 410 is based on CIGS, materials used to make transparent casing 310 and optional filer layer 330 are usefully transparent to light in the 500 nm to 1200 nm wavelength range.

Ultraviolet Stability. Any material used to construct a layer outside solar cell 402 is usefully chemically stable and, in particular, stable upon exposure to UV radiation. More specifically, such material usefully does not become less transparent upon UV exposure. Ordinary glass partially blocks UVA (wavelengths 400 and 300 nm) and it totally blocks UVC and UVB (wavelengths lower than 300 nm). The UV blocking effect of glass is usually due to additives, e.g. sodium carbonate, in glass. In some embodiments, additives in transparent casings 310 made of glass can render the casing 310 entirely UV protective. In such embodiments, because the transparent casing 310 provides complete protection from UV wavelengths, the UV stability requirements of the underlying optional filler material 330 are reduced. For example, EVA, PVB, TPU (urethane), silicones, polycarbonates, and acrylics can be adapted to form a filler material 330 when transparent casing 310 is made of UV protective glass. Alternatively, in some embodiments, where transparent casing 310 is made of plastic material, UV stability requirement is usefully adopted.

Plastic materials that are sensitive to UV radiation are generally not used in transparent casing 310 because yellowing of the material and/or optional filler material 330 can block radiation input into the solar cells 402 and can reduce their efficiency. In addition, cracking of transparent casing 310 due to UV exposure can permanently damage solar cells 402. For example, fluoropolymers like ETFE, and THV (Dyneon) are UV stable and highly transparent, while PET is transparent, but not sufficiently UV stable. In some embodiments, transparent casing 310 is made of fluoropolymer based on monomers of tetrafluoroethylene, hexafluoropropylene and vinylidene fluoride. In addition, polyvinyl chloride (“PVC” or “vinyl”), one of the most common synthetic materials, is also sensitive to UV exposure. Methods have been developed to render PVC UV-stabilized, but even UV stabilized PVC is typically not sufficiently durable (for example, yellowing and cracking of PVC product will occur over relative short term usage). Urethanes are better suited, but depend on the exact chemical nature of the polymer backbone. Urethane material is stable when the polymer backbone is formed by less reactive chemical groups (e.g., aliphatic or aromatic). On the other hand when the polymer backbone is formed by more reactive groups (e.g., double bonds), yellowing of the material occurs as a result of UV-catalyzed breakdown of the double bonds. Similarly, EVA will yellow and so will PVB upon continued exposure to UV light. Other options are polycarbonate (can be stabilized against UV for up to 10 years OD exposure) or acrylics (inherently UV stable).

Reflective Properties. Referring to FIG. 21, an incident beam L₁ hits the surface of transparent casing 310. Part of the incident beam L₁ is reflected as L₂ while the remainder of incident beam L₁ (e.g., as refracted beam L₃ in FIG. 21) travels through transparent casing 310. In some embodiments in accordance with the present application, the refracted beam L₃ directly hits transparent conductive layer 412 of solar cell 402 (e.g., when optional filler material 330 is absent). Alternatively, when filler material 330 is present, as depicted in FIG. 21, L₃ hits the outer surface of the filler material 330, and the processes of reflection and refraction is repeated as it was when L₁ hit the surface of transparent casing 310, with some of L₃ reflected into filler material 330 and some of L₃ refracted by filler material 330.

In order to enhance input of solar radiation, reflection at the outer surface of transparent casing 310 is usefully reduced or inhibited in some embodiments. For example, an antireflective coating, either as a separate layer 350 or in combination with the water resistant coating 340, may be applied on all or a portion of the outside of transparent casing 310. In some embodiments, this antireflective coating is made of MgF₂. In some embodiments, this antireflective coating is made of silicon nitrate or titanium nitrate. In other embodiments, this antireflective coating is made of one or more layers of silicon monoxide (SiO). For example, shiny silicon can act as a mirror and reflects more than thirty percent of the light that shines on it. A single layer of SiO reduces surface reflection to about ten percent, and a second layer of SiO can lower the reflection to less than four percent. Other organic antireflective materials, in particular, those which inhibit or reduce back reflection from the surface of or lower layers in the semiconductor device and reduce or eliminate the standing waves and reflective notching due to various optical properties of lower layers on the wafer and the photosensitive film, are disclosed in U.S. Pat. No. 6,803,172, which is hereby incorporated by reference herein in its entirety. Additional antireflective coating materials and methods are disclosed in U.S. Pat. Nos. 6,689,535; 6,673,713; 6,635,583; 6,784,094; and 6,713,234, each of which is hereby incorporated herein by reference in its entirety.

The outer surface of transparent casing 310 may also, or alternatively, be textured to reduce reflected radiation. Chemical etching creates a pattern of cones and pyramids, which capture light rays that might otherwise be deflected away from the cell. Reflected light is redirected down into the cell, where it has another chance to be absorbed. Material and methods for creating an anti-reflective layer by etching or by a combination of etching and coating techniques are disclosed in U.S. Pat. Nos. 6,039,888; 6,004,722; and 6,221,776; each of which is hereby incorporated herein by reference in its entirety.

Refractive Properties. As depicted in FIG. 21, part of incident beam L₁ is refracted as refracted beam L₃. How much and to which direction incident beam L₁ is bent from its path is determined by the refractive indices of the media in which beams L₁ and L₃ travel. Snell's law specifies:

η₁ sin(θ₁)=η₂ sin(θ₂),

where η₁ and η₂ are the refractive indices of the two bordering media 1 and 2 while θ₁ and θ₂ represent the angle of incidence and the angle of refraction, respectively.

In FIG. 21, the first refraction process occurs when incident beam L₁ travels from air through transparent casing 310 as L₃. Ambient air has a refractive index around 1 (vacuum space has a refractive index of 1, which is the smallest among all known materials), which is much smaller than the refractive index of glass material (ranging from 1.4 to 1.9 with the commonly used material having refractive indices around 1.5) or plastic material (around 1.45). Because ηₐᵢᵣ is always much smaller than Θ₃₁₀ whether casing is formed by glass or plastic material, the refractive angle θ₃₁₀ is always much smaller than the incident angle θₐᵢᵣ, i.e., the incident beam is always bent towards solar cell 402 as it travels through transparent casing 310.

In the presence of a filler material 330, beam L₃ becomes the new incident beam when it travels through the filler material 330. Ideally, according to Snell's law and the preceding analysis, the refractive index of the filler material 330 (e.g., η₃₁₀ in FIG. 21) should be larger than the refractive index of transparent casing 310 so that the refracted beam of incident beam L₃ will also be bent towards solar cell 402. In this ideal situation, every incident beam on transparent casing 310 will be bent towards solar cell 402 after two reflection processes. In some embodiments, however, optional filler material 330 is made of a fluid-like material (albeit sometimes very viscous fluid-like material) such that loading of solar cells 402 into transparent casing 310 may be achieved as described above. In practice, efficient solar radiation absorption is achieved by choosing filler material that has refractive index close to those of transparent casing 310. In some embodiments, materials that form transparent casing 310 include transparent materials (either glass or plastic or other suitable materials) with refractive indices around 1.5. For example, fused silica glass has a refractive index of 1.46. Borosilicate glass materials have refractive indices between 1.45 and 1.55 (e.g., PYREX® glass has a refractive index of 1.47). Flint glass materials with various amounts of lead additive have refractive indices between 1.5 and 1.9. Common plastic materials have refractive indices between 1.46 and 1.55.

Exemplary materials with the appropriate optical properties for forming filler material 330 further include silicone, polydimethyl siloxane (PDMS), silicone gel, epoxy, and acrylic material. Because silicone-based adhesives and sealants have a high degree of flexibility, they lack the strength of other epoxy or acrylic resins. Transparent casing 310, optional filler material 330, optional antireflective layer 350, water-resistant layer 340, or any combination thereof form a package to enhance and maintain solar cell 402 efficiency, provide physical support, and prolong the life time of solar cell units 402.

In some embodiments, glass, plastic, epoxy or acrylic resin may be used to form transparent casing 310. In some embodiments, optional antireflective 350 and/or optional water resistant coating 340 are disposed on all or a portion of transparent casing 310. In some such embodiments, filler material 330 is formed by softer and more flexible optically suitable material such as silicone gel. For example, in some embodiments, filler material 330 is formed by a silicone gel such as a silicone-based adhesives or sealants. In some embodiments, filler material 330 is formed by GE RTV 615 Silicone. RTV 615 is an optically clear, two-part flowable silicone product that requires SS4120 as primer for polymerization. (RTV615-1P), both available from General Electric (Fairfield, Conn.). Silicone-based adhesives or sealants are based on tough silicone elastomeric technology. The characteristics of silicone-based materials, such as adhesives and sealants, are typically controlled by three factors: resin mixing ratio, potting life and curing conditions.

Usefully, silicone adhesives have a high degree of flexibility and very high temperature resistance (up to 600° F.). Silicone-based adhesives and sealants have a high degree of flexibility. Silicone-based adhesives and sealants are available in a number of technologies (or cure systems). These technologies include pressure sensitive, radiation cured, moisture cured, thermo-set and room temperature vulcanizing (RTV). In some embodiments, the silicone-based sealants use two-component addition or condensation curing systems or single component (RTV) forms. RTV forms cure easily through reaction with moisture in the air and give off acid fumes or other by-product vapors during curing.

Pressure sensitive silicone adhesives typically adhere to many surfaces with very slight pressure and retain their tackiness. This type of material forms viscoelastic bonds that are aggressively and permanently tacky, and adheres without the need of more than finger or hand pressure. In some embodiments, radiation is used to cure silicone-based adhesives. In some embodiments, ultraviolet light, visible light or electron bean irradiation is used to initiate curing of sealants, which allows a permanent bond without heating or excessive heat generation. While UV-based curing requires one substrate to be UV transparent, the electron beam can penetrate through material that is opaque to UV light. Certain silicone adhesives and cyanoacrylates based on a moisture or water curing mechanism may need additional reagents properly attached to the solar cell 402 without affecting the proper functioning of solar cells 402. Thermo-set silicone adhesives and silicone sealants are cross-linked polymeric resins cured using heat or heat and pressure. Cured thermo-set resins do not melt and flow when heated, but they may soften. Vulcanization is a thermosetting reaction involving the use of heat and/or pressure in conjunction with a vulcanizing agent, resulting in greatly increased strength, stability and elasticity in rubber-like materials. RTV silicone rubbers are room temperature vulcanizing materials. The vulcanizing agent is a cross-linking compound or catalyst. In some embodiments in accordance with the present application, sulfur is added as the traditional vulcanizing agent.

In some embodiments, for example, when optional filler material 330 is absent, epoxy or acrylic material may be applied directly on all or a portion of solar cell 402 to form transparent casing 310 directly. In such embodiments, care is taken to ensure that the non-glass transparent casing 310 is also equipped with water resistant and/or antireflective properties to ensure efficient operation over a reasonable period of usage time.

Electrical Insulation. In some embodiments, a useful characteristic of transparent casing 310 and optional filler material 330 is that these layers provide substantially complete electrical insulation. In some embodiments, no conductive material is used to form either transparent casing 310 or optional filler material 330.

Dimension requirement. The combined width of each of the layers outside solar cell 402 (e.g., the combination of transparent casing 310 and/or optional filler material 330) in some embodiments is:

$${r}_{i} \geq \frac{{r}_{o}}{{η}_{outer ring}}$$

where, referring to FIG. 3B,

rᵢ is the radius of solar cell 402, assuming that semiconductor junction 410 is a thin-film junction;

rₒ is the radius of the outermost layer of transparent casing 310 and/or optional filler material 330; and

η_{outer ring} is the refractive index of the outermost layer of transparent casing 310 and/or optional filler material 330.

As noted above, the refractive index of many, but not all, of the materials used to make transparent casing 310 and/or optional filler material 330 is about 1.5. Thus, in typical embodiments, values of rₒ are permissible that are less than 1.5*rᵢ. This constraint places a boundary on allowable thickness for the combination of transparent casing 310 and/or optional filler material 330.

### 5.1.3.5 Additional Methods for Forming Transparent Casing

In some embodiments, transparent casing 310 is formed on all or a portion of an underlying layer (e.g., is formed on transparent conductive layer 412, filler material 330 or a water resistant layer) by spin coating, dip coating, plastic spraying, casting, Doctor's blade or tape casting, glow discharge polymerization, or UV curing. These technologies are discussed in greater detail in Madou, Fundamentals of Microfabrication, Chapter 3, pp. 159-161, second edition, CRC Press, New York, 2002, which is hereby incorporated by reference in its entirety. Casting is particularly suitable in instances where transparent casing 310 is formed from acrylics or polycarbonates. UV curing is particularly suitable in instances where transparent casing 310 is formed from an acrylic.

### 5.2 Exemplary Semiconductor Junctions

Referring to FIG. 5A, in one embodiment, semiconductor junction 410 is a heterojunction between an absorber layer 502, disposed on all or a portion of back-electrode 404, and a junction partner layer 504, disposed on all or a portion of absorber layer 502. In other embodiments, junction partner layer 504 is disposed on all or a portion of back-electrode 404, and absorber layer 502 is disposed on all or a portion of junction partner layer 504. Absorber layer 502 and junction partner layer 504 include different semiconductor types with different band gaps and electron affinities such that junction partner layer 504 has a larger band gap than absorber layer 502.

For example, in some embodiments, absorber layer 502 is p-doped and junction partner layer 504 is n-doped. In such embodiments, transparent conductive layer 412 is n⁺-doped. In alternative embodiments, absorber layer 502 is n-doped and junction partner layer 504 is p-doped. In such embodiments, transparent conductive layer 412 is p⁺-doped. In some embodiments, the semiconductors listed in Pandey, Handbook of Semiconductor Electrodeposition, Marcel Dekker Inc., 1996, Appendix 5, which is hereby incorporated by reference herein in its entirety, are used to form semiconductor junction 410.

Characteristics of solar cells based on p-n junctions. The principles of operation of solar cells based on p-n junctions (which is one form of semiconductor junction 410) are well understood. Briefly, a p-type semiconductor is placed in intimate contact with an n-type semiconductor. At equilibrium, electrons diffuse from the n-type side of the junction to the p-type side of the junction, where they recombine with holes, and holes diffuse from the p-type side of the junction to the n-type side of the junction, where they recombine with electrons. The resultant imbalance of charges creates a potential difference across the junction and forms a “space charge region” or “depletion layer,” which no longer contains mobile charge carriers, near the junction.

The p-type and n-type sides of the junction are connected to respective electrodes that are connected to an external load. In operation, one of the two junction layers behaves as an absorber, and the other junction layer is referred to as a “junction partner layer.” The absorber absorbs photons having energies above the band gap of the material of which it is made (more below), which generates electrons that drift under the influence of the potential generated by the junction. “Drift” is a charged particle's response to an applied electric field. The electrons drift to the electrode connected to the absorber, drift through the external load (thus generating electricity), and then into the junction partner layer. At the junction partner layer, the electrons recombine with holes in the junction partner layer. In some junctions 410 of the present application, a significant portion if not substantially all of the electricity generated by the junction (e.g., the electrons in the external load) derives from the absorption of photons by the absorber, e.g., greater than 30%, greater than 50%, greater than 60%, greater than 70%, greater than 80%, greater than 90%, greater than 95%, greater than 98%, greater than 99%, or substantially all of the electricity generated by the junction 410 derives from the absorption of photons by the absorber. In some embodiments, a significant portion if not substantially all of the electricity generated by solar cell units 300 (e.g., the electrons in the external load) derives from the absorption of photons by the absorber, e.g., greater than 30%, greater than 50%, greater than 60%, greater than 70%, greater than 80%, greater than 90%, greater than 95%, greater than 98%, greater than 99%, or substantially all of the electricity generated by the junction 410 derives from the absorption of photons by the absorber. For further details, see Chapter 3 of Handbook of Photovoltaic Science and Engineering, 2003, Luque and Hegedus (eds.), Wiley & Sons, West Sussex, England, the entire contents of which are hereby incorporated by reference herein.

Note that dye and polymer-based thin-film solar cells are generally not p-n-junction solar cells, and the dominant mode of electron-hole separation is via charge carrier diffusion, not drift in response to an applied electric field. For further details on dye- and polymer-based thin film solar cells, see Chapter 15 of Handbook of Photovoltaic Science and Engineering, 2003, Luque and Hegedus (eds.), Wiley & Sons, West Sussex, England, the entire contents of which are hereby incorporated by reference herein.

Material Characteristics. In some embodiments, materials for use in the semiconductor junctions 410 are inorganic meaning that they substantially do not contain reduced carbon, noting that negligible amounts of reduced carbon may naturally exist as impurities in such materials. As used herein, the term “inorganic compound” refers to all compounds, except hydrocarbons and derivatives of hydrocarbons as set forth by Moeller, 1982, Inorganic Chemistry, A modern Introduction, Wiley, New York, p. 2, which is hereby incorporated by reference.

In some embodiments, materials for use in semiconductor junctions are solids, that is, the atoms making up the material have fixed positions in space relative to each other, with the exception that the atoms may vibrate about those positions due to the thermal energy in the material. A solid object is in the state of matter characterized by resistance to deformation and changes of volume. At the microscopic scale, a solid has the following properties. First, the atoms or molecules that make up a solid are packed closely together. Second, the constituent elements of a solid have fixed positions in space relative to each other. This accounts for the solid's rigidity. A crystal structure, which is one non-limiting form of a solid, is a unique arrangement of atoms in a crystal. A crystal structure is composed of a unit cell, a set of atoms arranged in a particular way; which is periodically repeated in three dimensions on a lattice. The spacing between unit cells in various directions is called its lattice parameters. The symmetry properties of the crystal are embodied in its space group. A crystal's structure and symmetry play a role in determining many of its properties, such as cleavage, electronic band structure, and optical properties. Third, if sufficient force is applied, either of the first and second properties identified above can be disrupted, causing permanent deformation.

In some embodiments, the semiconductor junction is in a solid state. In some embodiments, all of the layers in the solar cell are in a solid state. In some embodiments, any combination of the substrate 403, the back-electrode 404, the semiconductor junction 410, the optional intrinsic layer 415, the transparent conductive layer 412, the optional filler material 330, the transparent casing 310, the water resistant layer, and the antireflective coating is in the solid state.

Many, but not all, of the described semiconductor materials are crystalline, or polycrystalline. By “crystalline” it is meant that the atoms or molecules making up the material are arranged in an ordered, repeating pattern that extends in all three spatial dimensions. By “polycrystalline” it is meant that the material includes crystalline regions, but that the arrangement of atoms or molecules within each particular crystalline region is not necessarily related to the arrangement of atoms or molecules within other crystalline regions. In polycrystalline materials, grain boundaries typically separate one crystalline region from another. In some embodiments, more than 10%, more than 20%, more than 30%, more than 40%, more than 50%, more than 60%, more than 70%, more than 80%, more than 90%, more than 99% or more of the material making up the absorber and/or the junction partner layer is in a crystalline state. In other words, in some embodiments more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals, where such crystals are in the triclinic, monoclinic, orthorhombic, tetragonal, trigonal (rhombohedral lattice), trigonal (hexagonal lattice), hexagonal, or cubic crystal system defined by Table 3.1 of Stout and Jensen, 1989, X-ray Structure Determination, A Practical Guide, John Wiley & Sons, p. 42, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals that each conform to the symmetry of the triclinic crystal system, that each conform to the symmetry of the monoclinic crystal system, that each conform to the symmetry of the orthorhombic crystal system, that each conform to the symmetry of the tetragonal crystal system, that each conform to the symmetry of the trigonal (rhombohedral lattice) crystal system, that each conform to the symmetry of the trigonal (hexagonal lattice) crystal system, that that each conform to the symmetry of the hexagonal crystal system, or that each conform to the symmetry of the cubic crystal system. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals, where each of the one or more crystals is independently in any one of the 230 possible space groups. For a list of the 230 possible space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in a cubic space group. For a list of each of the cubic space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in a tetragonal space group. For a list of each of the tetragonal space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in the Fm3m space group. The absorber and/or the junction partner layer of a semiconductor junction may include one or more grain boundaries.

In typical embodiments, the materials used in semiconductor junctions 410 are solid inorganic semiconductors. That is, such materials are inorganic, they are in a solid state, and they are semiconductors. A direct consequence of such materials being in such a state is that the electronic band structure of such materials has a unique band structure in which there is an almost fully occupied valence band and an almost fully unoccupied conduction band, with a forbidden gap between the valence band and the conduction band that is referred to herein as the band gap. In some embodiments, at least 80%, or at least 90%, or substantially of the molecules in the absorber layer are inorganic semiconductor molecules, and at least 80%, or at least 90%, or substantially all of the molecules in the junction partner layer are inorganic semiconductor molecules.

Others of the described semiconductor materials, such as Si in some embodiments, are amorphous. By “amorphous” it is meant a material in which there is no long-range order of the positions of the atoms or molecules making up the material. For example, on length scales greater than 10 nm, or greater than 50 nm, there is typically no recognizable order in an amorphous material. However, on small length scales (e.g., less than 5 nm, or less than 2 nm) even amorphous materials may have some short-range order among the atomic positions such that, on small length scales, such materials obey the requirements of one of the 230 possible space groups in standard orientation.

In some embodiments, semiconducting materials suitable for use in various embodiments of solar cells, such as those described herein, are non-polymeric (e.g., not based on organic polymers). In general, although a polymer may have a repeating chemical structure based on the monomeric units of which it is made, those of skill in the art recognize that polymers are typically found in the amorphous state because there is typically no long-range order to the spatial positions of portions of the polymer relative to other portions and because the spatial positions of such polymers do not obey the symmetry requirements of any of the 230 possible space groups or any of the symmetry requirements of any of the seven crystal systems. However, it is recognized that polymer materials may have short-range crystalline regions.

Band gaps. In some embodiments of the present application, at least forty percent, at least fifty percent, at least sixty percent, at least seventy percent, at least eighty percent, at least ninety percent, at least ninety-five percent, at least 99 percent or substantially all of the energy generated in the solar cell is generated by the absorber layer (e.g., layer 502, 510, 520, or 540 of FIGS. 5A-5D, or any layer that is deemed to be an absorber layer in a semiconductor junction 410 disclosed herein) absorbing photons with energies at or above the band gap of the absorber layer. For example, at least about 30%, at least about 40%, at least about 50%, at least about 60%, at least about 70%, at least about 80%, at least about 85%, at least about 90%, at least about 95%, at least about 98%, at least about 99%, or even more of the energy generated in the solar cell is generated by the absorber layer (e.g., layer 502, 510, 520, or 540 of FIGS. 5A-5D, or any layer that is deemed to be an absorber layer in a semiconductor junction 410 disclosed herein) absorbing photons with energies at or above the band gap of the absorber layer.

Usefully, in many embodiments, the semiconductor junction, e.g., absorber layer 502 and junction partner layer 504, each have a band gap between, e.g., about 0.6 eV (about 2066 nm) and about 2.4 eV (about 516 nm). In some embodiments, a semiconductor junction 410 has a band gap between, e.g., about 0.7 eV (about 1771 nm) and about 2.2 eV (about 563 nm). In some embodiments, the absorber layer or the junction partner layer in a semiconductor junction 410 band gap has a band gap between, e.g., about 0.8 eV (about 1550 nm) and about 2.0 eV (about 620 nm). In some embodiments, an absorber layer or a junction partner layer in a semiconductor junction 410 has a band gap between, e.g., about 0.9 eV (about 1378 nm) and about 1.8 eV (about 689 nm). In some embodiments, an absorber layer or a junction partner layer in a semiconductor junction 410 has a band gap between, e.g., about 1 eV (about 1240 nm) and about 1.6 eV (about 775 nm). In some embodiments, an absorber layer or a junction partner layer in a semiconductor junction 410 has a band gap between, e.g., about 1.1 eV (about 1127 nm) and about 1.4 eV (about 886 nm). In some embodiments, an absorber layer or a junction partner layer in a semiconductor junction 410 has a band gap between, e.g., about 1.1 eV (about 1127 nm) and about 1.2 eV (about 1033 nm). In some embodiments, an absorber layer or a junction partner layer in a semiconductor junction 410 has a band gap between, e.g., about 1.2 eV (about 1033 nm) and about 1.3 eV (about 954 nm).

In some embodiments, the absorber layer and/or the junction partner layer in a semiconductor junction 410 has a band gap between, e.g., 0.6 eV (2066 nm) and 2.4 eV (516 nm), 0.7 eV (1771 nm) and 2.2 eV (563 nm), 0.8 eV (1550 nm) and 2.0 eV (620 nm), 0.9 eV (1378 nm) and 1.8 eV (689 nm), 1 eV (1240 nm) and 1.6 eV (775 nm), 1.1 eV (1127 nm) and 1.4 eV (886 nm), or 1.2 eV (1033 nm) and 1.3 eV (954 nm). In some embodiments, an absorber layer in a semiconductor junction 410 has a band gap between, e.g., 0.6 eV (2066 nm) and 2.4 eV (516 nm), 0.7 eV (1771 nm) and 2.2 eV (563 nm), e.g., 0.8 eV (1550 nm) and 2.0 eV (620 nm), 0.9 eV (1378 nm) and 1.8 eV (689 nm), 1 eV (1240 nm) and 1.6 eV (775 nm), 1.1 eV (1127 nm) and 1.4 eV (886 nm), or 1.2 eV (1033 nm) and 1.3 eV (954 nm). In some embodiments, a junction partner layer in a semiconductor junction 410 has a band gap between, e.g., 0.6 eV (2066 nm) and 2.4 eV (516 nm), e.g., 0.7 eV (1771 nm) and 2.2 eV (563 nm), 0.8 eV (1550 nm) and 2.0 eV (620 nm), e.g., 0.9 eV (1378 nm) and 1.8 eV (689 nm), e.g., 1 eV (1240 nm) and 1.6 eV (775 nm), 1.1 eV (1127 nm) and 1.4 eV (886 nm) or between, e.g., 1.2 eV (1033 nm) and 1.3 eV (954 nm).

As noted above, the absorber layer 502 and the junction partner layer 504 include different semiconductors with different band gaps and electron affinities such that junction partner layer 504 has a larger band gap than absorber layer 502. For example, the absorber may have a band gap between about 0.9 eV and about 1.8 eV. In some embodiments, the absorber layer in a semiconductor junction 410 includes copper-indium-gallium-diselenide (CIGS) and the band gap of the absorber layer is in the range of 1.04 eV to 1.67 eV. In some embodiments, the absorber layer in a semiconductor junction 410 includes copper-indium-gallium-diselenide (CIGS) and the minimum band gap of the absorber layer is between 1.1 eV and 1.2 eV.

In some embodiments the absorber layer in a semiconductor junction 410 is graded such that the band gap of the absorber layer varies as a function of absorber layer depth. As is known in the art, for the purposes of modeling, such a graded absorber layer can be modeled as stacked layers, each with a different composition and corresponding band gap. For instance, in some embodiments, the absorber layer in a semiconductor junction 410 includes copper-indium-gallium-diselenide having the stoichiometry CuIn₁₋ₓGaₓSe₂ with non-uniform Ga/In composition versus absorber layer depth. Such non-uniform Ga/In composition can be achieved, for example, by varying elemental fluxes of Ga and In during deposition of the absorber layer onto a nonplanar back-electrode. In some embodiments, the absorber layer in a semiconductor junction 410 includes copper-indium-gallium-diselenide with the stoichiometry CuIn₁₋ₓGaₓSe₂ in which the band gap ranges of the absorber varies between a first value in the range 1.04 eV to 1.67 eV and a second value in the range of 1.04 eV to 1.67 eV as a function of absorber depth, where the first value is greater than the second value. In some embodiments, the absorber layer in a semiconductor junction 410 includes copper-indium-gallium-diselenide having the stoichiometry CuIn₁₋ₓGaₓSe₂ in which the band gap of the absorber layer ranges between a first value in the range of 1.04 eV to 1.67 eV to a second value in the range of 1.04 eV to 1.67 eV as a function of absorber layer depth, where the first value is less than the second value. Typically, in such embodiments, the band gap ranges between the first value and the second value in a continuous linear gradient as a function of absorber layer depth. However, in some embodiments, the band gap ranges between the first value and the second value in a nonlinear gradient or even a discontinuous fashion as a function of absorber layer depth.

In some embodiments, the absorber layer or the junction partner layer in a semiconductor junction 410 is characterized by a band gap that ranges between a first value in the range 1.04 eV to 1.67 eV to a second value in the range of 1.04 eV to 1.67 eV as a function of absorber layer depth, where the first value is greater than the second value. In some embodiments, the absorber layer in a semiconductor junction 410 includes copper-indium-gallium-diselenide having the stoichiometry CuIn₁₋ₓGaₓSe₂ in which the band gap ranges between a first value in the range of 1.04 eV to 1.67 eV to a second value in the range of 1.04 eV to 1.67 eV as a function of absorber depth, where the first value is less than the second value. In some embodiments, the band gap ranges between the first value and the second value in a continuous linear gradient as a function of absorber depth. However, in some embodiments, the band gap ranges between the first value and the second value in a nonlinear gradient or even a discontinuous fashion as a function of absorber depth. Moreover, in some embodiments, the band gap ranges between the first value and the second value in such a manner that the band gap increases and decreases a plurality of times as a function of absorber layer depth.

In some embodiments, the absorber layer or the junction partner layer in a semiconductor junction 410 of the present application is characterized by a band gap that ranges between a first value in the range of 0.6 eV (2066 nm) to 2.4 eV (516 nm) and a second value in the range of 0.6 eV (2066 nm) to 2.4 eV (516 nm), where the first value is less than the second value. In some embodiments, the absorber layer or the junction partner layer in a semiconductor junction 410 of the present application is characterized by a band gap that ranges between a first value in the range of 0.7 eV (1771 nm) to 2.2 eV (563 nm) and a second value in the range of 0.7 eV (1771 nm) to 2.2 eV (563 nm), where the first value is less than the second value. In some embodiments, the absorber layer or the junction partner layer in a semiconductor junction 410 of the present application is characterized by a band gap that ranges between a first value in the range of 0.8 eV (1550 nm) to 2.0 eV (620 nm) and a second value in the range of 0.8 eV (1550 nm) to 2.0 eV (620 nm), where the first value is less than the second value. In some embodiments, the absorber layer or the junction partner layer in a semiconductor junction 410 of the present application is characterized by a band gap that ranges between a first value in the range of 0.9 eV (1378 nm) to 1.8 eV (689 nm) and a second value in the range of 0.9 eV (1378 nm) to 1.8 eV (689 nm), where the first value is less than the second value. In some embodiments, the absorber layer or the junction partner layer in a semiconductor junction 410 of the present application is characterized by a band gap that ranges between a first value in the range of 1 eV (1240 nm) to 1.6 eV (775 nm) and a second value in the range of 1 eV (1240 nm) to 1.6 eV (775 nm), where the first value is less than the second value. In some embodiments, the absorber layer or the junction partner layer in a semiconductor junction 410 of the present application is characterized by a band gap that ranges between a first value in the range of 1.1 eV (1127 nm) to 1.4 eV (886 nm) and a second value in the range of 1.1 eV (1127 nm) to 1.4 eV (886 nm), where the first value is less than the second value. In some embodiments, the absorber layer or the junction partner layer in a semiconductor junction 410 of the present application is characterized by a band gap that ranges between a first value in the range of 1.2 eV (1033 nm) to 1.3 eV (954 nm) and a second value in the range of 1.2 eV (1033 nm) to 1.3 eV (954 nm), where the first value is less than the second value. In some embodiments, the band gap ranges between the first value and the second value in a continuous linear gradient as a function of absorber layer or junction partner layer depth. However, in some embodiments, the band gap ranges between the first value and the second value in a nonlinear gradient or even a discontinuous fashion as a function of absorber layer depth or junction partner layer depth. Moreover, in some embodiments, the band gap ranges between the first value and the second value in such a manner that the band gap increases and decreases a plurality of times as a function of absorber layer or junction partner layer depth.

In some embodiments, the absorber layer or the junction partner layer in a semiconductor junction 410 of the present application is characterized by a band gap that ranges between a first value in the range of 0.6 eV (2066 nm) to 2.4 eV (516 nm) and a second value in the range of 0.6 eV (2066 nm) to 2.4 eV (516 nm), where the first value is greater than the second value. In some embodiments, the absorber layer or the junction partner layer in a semiconductor junction 410 of the present application is characterized by a band gap that ranges between a first value in the range of 0.7 eV (1771 nm) to 2.2 eV (563 nm) and a second value in the range of 0.7 eV (1771 nm) to 2.2 eV (563 nm), where the first value is greater than the second value. In some embodiments, the absorber layer or the junction partner layer in a semiconductor junction 410 of the present application is characterized by a band gap that ranges between a first value in the range of 0.8 eV (1550 nm) to 2.0 eV (620 nm) and a second value in the range of 0.8 eV (1550 nm) to 2.0 eV (620 nm), where the first value is greater than the second value. In some embodiments, the absorber layer or the junction partner layer in a semiconductor junction 410 of the present application is characterized by a band gap that ranges between a first value in the range of 0.9 eV (1378 nm) to 1.8 eV (689 nm) and a second value in the range of 0.9 eV (1378 nm) to 1.8 eV (689 nm), where the first value is greater than the second value. In some embodiments, the absorber layer or the junction partner layer in a semiconductor junction 410 of the present application is characterized by a band gap that ranges between a first value in the range of 1 eV (1240 nm) to 1.6 eV (775 nm) and a second value in the range of 1 eV (1240 nm) to 1.6 eV (775 nm), where the first value is greater than the second value. In some embodiments, the absorber layer or the junction partner layer in a semiconductor junction 410 of the present application is characterized by a band gap that ranges between a first value in the range of 1.1 eV (1127 nm) to 1.4 eV (886 nm) and a second value in the range of 1.1 eV (1127 nm) to 1.4 eV (886 nm), where the first value is greater than the second value. In some embodiments, the absorber layer or the junction partner layer in a semiconductor junction 410 of the present application is characterized by a band gap that ranges between a first value in the range of 1.2 eV (1033 nm) to 1.3 eV (954 nm) and a second value in the range of 1.2 eV (1033 nm) to 1.3 eV (954 nm), where the first value is greater than the second value. In some embodiments, the band gap ranges between the first value and the second value in a continuous linear gradient as a function of absorber layer or junction partner layer depth. However, in some embodiments, the band gap ranges between the first value and the second value in a nonlinear gradient or even a discontinuous fashion as a function of absorber layer or junction partner layer depth. Moreover, in some embodiments, the band gap ranges between the first value and the second value in such a manner that the band gap increases and decreases a plurality of times as a function of absorber layer or junction partner layer depth.

Table 1 lists exemplary band gaps of several semiconductors suitable for use in semiconductor junctions such as those described herein, as well as some other physical properties of the semiconductors. “D” indicates a direct band gap, and “I” indicates an indirect band gap.

TABLE 1
Properties of various semiconductors (adapted from Pandey, Handbook of Semiconductor
Electrodeposition, Marcel Dekker Inc., 1996, Appendix 5) that may be used
in semiconductor junctions 410 of the present application

| | | Band | | Electron | Hole | |
|---|---|---|---|---|---|---|
| | Density | gap | Gap | Mobility | Mobility | Dielectric |
| Material (type) | (g/cm³) | (eV) | transition | (cm²V¹s¹) | (cm²V¹s¹) | Constant |
| B | — | 1.53 | I | 6,000 | 4000 | — |
| Si (n, p) | 2.33 | 1.11 | I | 1,350 | 480 | 12 |
| Ge (n, p) | 5.33 | 0.66 | I | 3,600 | 1800 | 16 |
| SiC (n, p) | 3.22 | 2.75-3.1 | I | 60-120 | 10.2 | 4.84 |
| CdS (n, p) | 4.83 | 2.42 | D | 340 | — | 9-10.3 |
| CdSe (n) | 5.74 | 1.7 | D | 600 | — | 9.3-10 |
| CdTe (n, p) | 5.86 | 1.44 | D | 700 | 65 | 9.6 |
| ZnS (n) | 4.09 | 3.58 | D | 120 | — | 8.3 |
| ZnSe (n) | 5.26 | 2.67 | D | 530 | — | 9.1 |
| ZnTe (p) | 5.70 | 2.26 | D | 530 | 130 | 10.1 |
| HgSe | 7.1-8.9 | 0.6 | — | 18,500 | — | 5.8 |
| HgTe | | 0.025 | — | 22,000 | 160 | — |
| PbS | 7.5 | 0.37 | I | 600 | 200 | — |
| PbSe | 8.10 | 0.26 | I | 1,400 | 1400 | — |
| PbTe (n, p) | 8.16 | 0.29 | I | 6,000 | 4000 | — |
| Bi₂S₃ (n) | | 1.3 | I | 200 | — | — |
| Sb₂Se₃ | | 1.2 | — | 15 | 45 | — |
| Sb₂S₃ | | 1.7 | — | — | — | — |
| As₂Se₃ | | 1.6 | — | 15 | 45 | — |
| In₂S₃ | | 2.28 | — | — | — | — |
| In₂Se₃ | | 1.25 | — | 30 | — | — |
| Mg₂Si | | 0.77 | — | 370 | 65 | — |
| ZnAs₂ | | 0.9 | — | — | 50 | — |
| CdAs₂ | | 1.0 | — | — | 100 | — |
| AlAs (n, p) | 3.79 | 2.15 | I | — | 280 | 10.1 |
| AlSb (n, p) | 4.26 | 1.6 | I | 900 | 400 | 10.3 |
| GaAs (n, p) | 5.32 | 1.43 | D | 58,000 | 300 | 11.5 |
| GaSb (n, p) | 5.60 | 0.68 | D | 5,000 | 1000 | 14.8 |
| GaP (n, p) | 4.13 | 2.3 | D | 110 | 75 | 8.5 |
| InP (n, p) | 4.78 | 1.27 | D | 4,500 | 100 | 12.1 |
| InSb (n, p) | 5.77 | 0.17 | D | 80,000 | 450 | 15.07 |
| InAs (n, p) | 5.60 | 0.36 | D | 33,000 | 450 | 11.7 |
| MoS₂ (n, p) | 4.8 | 1.75 | I, D | — | 200 | — |
| MoSe₂ (n, p) | | 1.4 | I, D | 10-50 | — | — |
| MoTe₂ (n, p) | | 1.0 | I | — | — | — |
| WSe₂ (n, p) | | 1.57 | I | 100-150 | — | — |
| ZrSe₂ (p) | | 1.05-1.22 | I | — | — | — |
| CuInS₂ (n, p) | 4.75 | 1.3-1.5 | — | — | — | — |
| CuInSe₂ (n, p) | 5.77 | 0.9-1.11 | — | — | — | — |
| CuGaS₂ (p) | 4.35 | 2.1 | — | — | — | — |
| CuGaSe₂ (p) | 5.56 | 1.5 | — | — | — | — |
| CuInS_{0.5}Se_{1.5} (p) | | 1.5 | — | — | — | — |
| CuInSSe (p) | | 1.2 | — | — | — | — |
| CuInS_{1.5}S_{o.5} (n, p) | | 1.3 | — | — | — | — |
| CuGa_{0.5}In_{0.5}S₂ (p) | | 1.4 | — | — | — | — |
| CuGA_{0.5}In_{0.5}Se₂ (p) | | 1.1 | — | — | — | — |
| CuGa_{0.75}In_{0.25}Se₂ (p) | | 1.35 | — | — | — | — |
| CuGa_{0.25}In_{0.75}Se₂ | | 1.0 | — | — | — | — |
| CuGa_{0.5}In_{0.5}SSe (p) | | 1.2 | — | — | — | — |
| CuGa_{0.25}In_{0.75}S_{0.5}Se_{1..5} | | 1.0 | — | — | — | — |
| (p) | | | | | | |
| CuGa_{0.75}In_{0.25}SSe_{1.5} | | 1.1 | — | — | — | — |
| (p) | | | | | | |
| Cu₂CdSnSe₄ (p) | | 1.5 | — | — | — | — |
| CuInSnS₄ (p) | | 1.1 | — | — | — | — |
| CuInSnSe₄ (p) | | 0.9 | — | — | — | — |
| CuIn₅Se₈ (p) | | 1.3 | — | — | — | — |
| CuGa₃S₅ (p) | | 1.8 | — | — | — | — |
| CuGa₅Se₈ (p) | | 2.0 | — | — | — | — |
| CuGa₅Se₈ | | 1.2 | — | — | — | — |
| CuGa_{2.5}In_{2.5}S₄Se₈ | | 1.4 | — | — | — | — |

In some embodiments, the density of the semiconductor materials in the absorber layer and/or the junction partner of a semiconductor junction 410 ranges between about 2.33 g/cm³ and 8.9 g/cm³. In some embodiments, the absorber layer has a density of between about 5 g/cm³ and 6 g/cm³. In some embodiments the absorber layer includes CIGS. The density of CIGS changes with its composition because the unit crystal cell changes from cubic to tetragonal. The chemical formula for CIGS is: Cu(In₁₋ₓGaₓ)Se₂. At gallium mole fractions below 0.5, the CIGS takes on a tetragonal chalcopyrite structure. At mole fractions above 0.5, the cell structure is cubic zinc-blende. In some embodiments, the absorber layer of a semiconductor junction 410 includes CIGS in which the mole fraction (x) is between 0.2 and 0.6, a density of between 5 g/cm³ and 6 g/cm³ and a band gap between about 1.2 eV and 1.4 eV. In an embodiment, the absorber layer of a semiconductor junction 410 includes CIGS in which the mole fraction (x) is between 0.2 and 0.6, the density of the CIGS is between 5 g/cm³ and 6 g/cm³ and the band gap of the CIGS is between about 1.2 eV and 1.4 eV. In an embodiment, the absorber layer of a semiconductor junction 410 includes CIGS in which the mole fraction (x) is 0.4, the density of the CIGS is about 5.43 g/cm³, and the band gap of the CIGS is about 1.2 eV.

Solar cell model. In some embodiments a solar cell can be modeled using the framework provided in the following table using FIG. 3B as a guide:

| Layer | | |
|---|---|---|
| Identification | | |
| (from FIG. 3B) | Exemplary Thickness | Exemplary composition |
| 310 | 0.1 micron to 1000 microns | Glass |
| 330 | 0.1 micron to 1000 microns | As described herein |
| 412 | between 10 nanometers and | zinc oxide |
| | 500 nanometers | |
| 415 | between 20 nanometers and | CdS |
| | 50 nanometers | |
| 410 | between 1 nanometer and 10 | CIGS |
| | nanometers (recombination | |
| | layer) | |
| 410 | between 5 nanometers and | CIGS |
| | 15 nanometers (ordered | |
| | defect compound layer) | |
| 410 | between 25 nanometers and | CIGS n-type depletion, |
| | 100 nanometers | absorber layer |
| 410 | between 200 nanometers and | CIGS p-type depletion, |
| | 500 nanometers | absorber layer |
| 410 | between 1 nanometer and | CIGS p-type, absorber |
| | 1000 nanometers | layer |
| 404 | between 10 nanometers and | molybdenum, |
| | 5000 nanometers | |

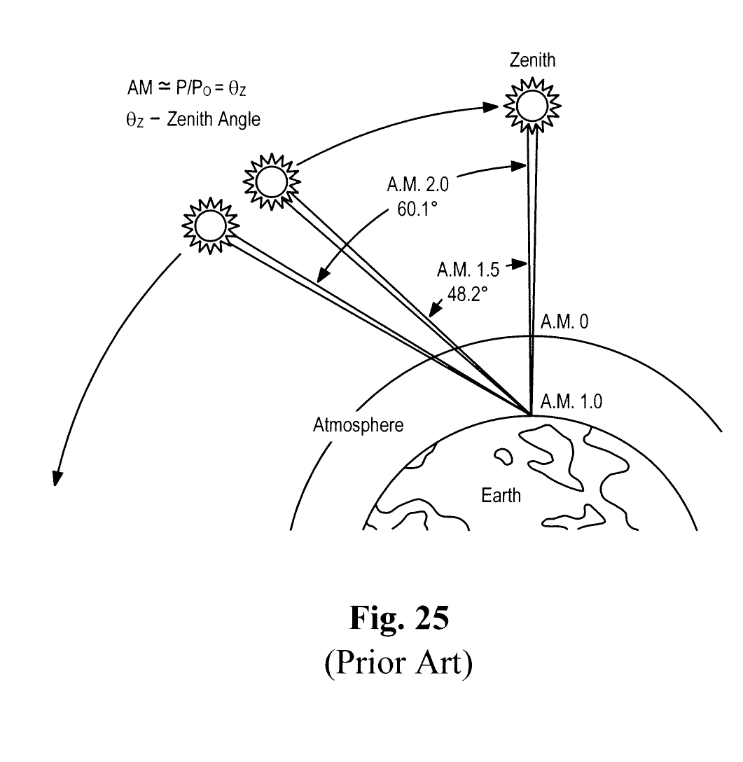

Current Densities. The combination of materials used in the semiconductor junction, e.g., absorber layer and junction partner layer, are selected to generate a sufficient current density (also commonly called the “short circuit current density,” or J_{sc}) upon irradiation with photons with energies at or above the band gap of the absorber layer, to efficiently produce electricity. In order to enhance J_{sc}, it is desirable to (1) absorb as much of the incident light as possible, e.g., to have a small band gap with high absorption over a wide energy range, and (2) to have material properties such that the photoexcited electrons and holes are able to be collected by the internal electric field generated by the junction and pass into an external circuit before they recombine, e.g., a material with a high minority carrier lifetime and mobility. At the same time, the band gap of the junction partner layer is usefully large relative to that of the absorber layer so that the bulk of the photon absorption occurs in the absorber layer. For example, in some embodiments, the compounds in the semiconductor junction 410 (e.g., the absorber layer and/or the junction partner layer) are selected such that the solar cell generates a current density J_{sc} of at least 10 mA/cm², at least 15 mA/cm², at least 20 mA/cm², at least 25 mA/cm², at least 30 mA/cm², at least 35 mA/cm², or at least 39 mA/cm² upon irradiation with an air mass (AM) 1.5 global spectrum, an AM1.5 direct terrestrial spectra, an AM0 reference spectra as defined in Section 16.2.1 of Handbook of Photovoltaic Science and Engineering, 2003, Luque and Hegedus (eds.), Wiley & Sons, West Sussex, England (2003), which is hereby incorporated by reference herein. Referring to FIG. 25, the air-mass value 0 equates to insolation at sea leve with the Sun at its zenith, as shown, AM 1.0 represents sunlight with the Sun at zenith above the Earth's atmosphere and absorbing oxygen and nitrogen gases, AM 1.5 is the same, but with the Sun at an oblique angle of 48.2°, which simulates a longer optical path through the Earth's atmosphere, and AM 2.0 extends that oblique angle to 60.1°. See Jeong, 2007, Laser Focus World 43, 71-74, which is hereby incorporated by reference herein.

In some embodiments, the solar cells of the present invention exhibit a JS, when measured under standard conditions (25° C., AM 1.5 G 100 mW/cm²), that is between 22 mA/cm² and 35 mA/cm². In some embodiments, the solar cells of the present invention exhibit a J_{sc}, when measured under AM 1.5 G, that is between 22 mA/cm² and 35 mA/cm² at any temperature between 0° C. and 70° C. In some embodiments, the solar cells of the present invention exhibit a J_{sc}, when measured under AM 1.5 G conditions, that is between 22 mA/cm² and 35 mA/cm² at any temperature between 10° C. and 60° C. For computing current density, illumination intensities are calibrated, for example, by the standard amorphous Si solar cell in the manner used to report values in Nishitani et al., 1998, Solar Energy Materials and Solar Cells 50, p. 63-70 and the references cited therein, which is hereby incorporated by reference in its entirety.

In some embodiments, the materials of the absorber layer and/or the junction partner layer of the semiconductor junction 410 have electron mobilities between, e.g., 10 cm²V¹s¹ and 80,000 10 cm²V¹s¹.

In some embodiments, substantially all, or some of the photovoltaic current generated by the solar cells is from absorption of light by a semiconductor in the semiconductor junction 410. In some embodiments, the semiconductor junction is in a crystalline or polycrystalline state. In some embodiments, at least fifty percent, or at least sixty percent, or at least seventy percent, or at least eighty percent, or at least ninety percent, or at least ninety-five percent of the photovoltaic current generated by the solar cell is from absorption of light by a semiconductor in the semiconductor junction.

Open circuit voltage. In some embodiments, the solar cells of the present invention exhibit an open circuit voltage V_{oc} (V), when measured under standard conditions (25° C., AM 1.5 G 100 mW/cm²), that is between 0.4V and 0.8V. In some embodiments, the solar cells of the present invention exhibit an V_{oc}, when measured under AM 1.5 G, that is between 0.4V and 0.8V at any temperature between 0° C. and 70° C. In some embodiments, the solar cells of the present invention exhibit a V_{oc}, when measured under AM 1.5 G conditions, that is between 0.4V and 0.8V at any temperature between 10° C. and 60° C. For computing open circuit voltage, illumination intensities are calibrated, for example, by the standard amorphous Si solar cell in the manner used to report values in Nishitani et al., 1998, Solar Energy Materials and Solar Cells 50, p. 63-70 and the references cited therein, which is hereby incorporated by reference in its entirety.

### 5.2.1 Thin-Film Semiconductor Junctions Based on Copper Indium Diselenide and Other Type I-III-VI₂ Materials

Material Characteristics. Continuing to refer to FIG. 5A, in some embodiments, absorber layer 502 is a group I-III-VI₂ compound such as copper indium di-selenide (CuInSe₂; also known as CIS). In some embodiments, the absorber layer of a semiconductor junction 410 is a group I-III-VI₂ ternary compound selected from the group consisting of CdGeAs₂, ZnSnAs₂, CuInTe₂, AgInTe₂, CuInSe₂, CuGaTe₂, ZnGeAs₂, CdSnP₂, AgInSe₂, AgGaTe₂, CuInS₂, CdSiAs₂, ZnSnP₂, CdGeP₂, ZnSnAs₂, CuGaSe₂, AgGaSe₂, AgInS₂, ZnGeP₂, ZnSiAs₂, ZnSiP₂, CdSiP₂, or CuGaS₂ of either the p-type or the n-type when such compound is known to exist. In some embodiments, the absorber layer of a semiconductor junction 410 is a “thin film,” e.g., having a thickness between 0.1 μm and 10.0 μm

In some embodiments, the junction partner layer of a semiconductor junction is CdS, ZnS, ZnSe, CdZnS, Zn(O,S), or (Zn, Mg)O. In one embodiment, absorber layer of a semiconductor junction is p-type CIS and junction partner layer 504 is n-type CdS, ZnS, ZnSe, or CdZnS. Such semiconductor junctions 410 are described in Chapter 6 of Bube, Photovoltaic Materials, 1998, Imperial College Press, London, which is hereby incorporated by reference herein in its entirety.

In some embodiments, the absorber layer of a semiconductor junction 410 is copper-indium-gallium-diselenide (CIGS). Such a layer is also known as Cu(InGa)Se₂. As those of skill in the art know, the stoichiometric ratio of In to Ga in CIGS is not limited to 1:1 (although the nomenclature would imply this), but instead can take any ratio between x:(1−x), where x is between zero and 1, inclusive. The ratio of In to Ga in CIGS can affect the band gap of the material, as well as the current density generated by the semiconductor junction. In some embodiments, some or all of the Se is replaced by S. Some exemplary CIGS formulations are listed in Table 2. Moreover, as those of skill in the art know, the stoichiometric ratio of Cu to Se is not limited to 1:2, but instead can vary based on the desired electrical characteristics of the semiconductor junction. Atoms from underlying layers, e.g., from the substrate, may also become incorporated into a CIGS absorber layer, and modify or enhance the semiconductor junction's performance. For example, sodium atoms from a soda-lime glass substrate may become incorporated into the CIGS layer. In some embodiments, the composition ratio of Cu/(In+Ga) in layer of a semiconductor junction 410 is between 0.7 and 0.95. In some embodiments, the composition ratio of Ga/(In+Ga) in the absorber layer of a semiconductor junction 410 is between 0.1 and 0.7.

In some embodiments, the absorber layer of a semiconductor junction 410 is CIGS and junction partner layer 504 is CdS, ZnS, ZnSe, CdZnS, Zn(O,S), or (Zn, Mg)O. In some embodiments, the absorber layer of a semiconductor junction 410 is p-type CIGS and the junction partner layer of a semiconductor junction 410 is n-type CdS, ZnS, ZnSe, CdZnS, Zn(O,S), or (Zn, Mg)O. Such semiconductor junctions 410 are described in Chapter 13 of Handbook of Photovoltaic Science and Engineering, 2003, Luque and Hegedus (eds.), Wiley & Sons, West Sussex, England, which is hereby incorporated herein by reference in its entirety.

In some embodiments, the group I-III-VI₂ compound (e.g., CIGS) used in absorber layer 502 has a <110> crystallographic orientation. In some embodiments, the group I-III-VI₂ compound (e.g., CIGS) used in absorber layer 502 has a <112> crystallographic orientation. In some embodiments, the group I-III-VI₂ compound (e.g., CIGS) absorber layer 502 is randomly oriented.

Methods of Making. In some embodiments, the semiconductor junction layers are formed using methods described in U.S. patent application Ser. No. 11/893,416, filed Aug. 16, 2007 and entitled “Real Time Process Monitoring and Control for Semiconductor Layers,” the entire contents of which are hereby incorporated by reference herein. Section 6, below, describes one exemplary method of making a solar cell that includes a CIGS layer.

In some embodiments, CIGS is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety.

In some embodiments CIGS absorber layer 502 is grown on a molybdenum back-electrode 404 by evaporation from elemental sources in accordance with a three stage process described in U.S. Pat. No. 5,441,897, the entire contents of which are incorporated herein by reference, or Ramanathan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety. In some embodiments layer 504 is a ZnS(O,OH) buffer layer as described, for example, in Ramanathan et al., Conference Paper, “CIGS Thin-Film Solar Research at NREL: FY04 Results and Accomplishments,” NREL/CP-520-37020, January 2005, which is hereby incorporated by reference herein in its entirety.

### 5.2.2 Semiconductor Junctions Based on Amorphous Silicon or Polycrystalline Silicon

In some embodiments, referring to FIG. 5B, semiconductor junction 410 includes amorphous silicon. In some embodiments this is an n/n type heterojunction. For example, in some embodiments, layer 514 includes SnO₂(Sb), layer 512 includes undoped amorphous silicon, and layer 510 includes n+ doped amorphous silicon.

In some embodiments, semiconductor junction 410 is a p-i-n type junction. For example, in some embodiments, layer 514 is p⁺ doped amorphous silicon, layer 512 is undoped amorphous silicon, and layer 510 is n⁺ amorphous silicon. Such semiconductor junctions 410 are described in Chapter 3 of Bube, Photovoltaic Materials, 1998, Imperial College Press, London, which is hereby incorporated by reference herein in its entirety.

In some embodiments of the present application, semiconductor junction 410 is based upon thin-film polycrystalline. Referring to FIG. 5B, in one example in accordance with such embodiments, layer 510 is a p-doped polycrystalline silicon, layer 512 is depleted polycrystalline silicon and layer 514 is n-doped polycrystalline silicon. Such semiconductor junctions are described in Green, Silicon Solar Cells. Advanced Principles & Practice, Centre for Photovoltaic Devices and Systems, University of New South Wales, Sydney, 1995; and Bube, Photovoltaic Materials, 1998, Imperial College Press, London, pp. 57-66, which is hereby incorporated by reference herein in its entirety.

In some embodiments of the present application, semiconductor junctions 410 based upon p-type microcrystalline Si:H and microcrystalline Si:C:H in an amorphous Si:H solar cell are used. Such semiconductor junctions are described in Bube, Photovoltaic Materials, 1998, Imperial College Press, London, pp. 66-67, and the references cited therein, which is hereby incorporated by reference herein in its entirety.

### 5.2.3 Semiconductor Junctions Based on Tandem Junctions

In some embodiments, of the present application, semiconductor junction 410 is a tandem junction. Tandem junctions are described in, for example, Kim et al., 1989, “Lightweight (AlGaAs)GaAs/CuInSe₂ tandem junction solar cells for space applications,” Aerospace and Electronic Systems Magazine, IEEE Volume 4, Issue 11, November 1989 Page(s):23-32; Deng, 2005, “Optimization of a-SiGe based triple, tandem and single-junction solar cells Photovoltaic Specialists Conference, 2005 Conference Record of the Thirty-first IEEE 3-7 Jan. 2005 Page(s):1365-1370; Arya et al., 2000, Amorphous silicon based tandem junction thin-film technology: a manufacturing perspective,” Photovoltaic Specialists Conference, 2000. Conference Record of the Twenty-Eighth IEEE 15-22 Sep. 2000 Page(s): 1433-1436; Hart, 1988, “High altitude current-voltage measurement of GaAs/Ge solar cells,” Photovoltaic Specialists Conference, 1988, Conference Record of the Twentieth IEEE 26-30 Sep. 1988 Page(s):764-765 vol. 1; Kim, 1988, “High efficiency GaAs/CuInSe₂ tandem junction solar cells,” Photovoltaic Specialists Conference, 1988, Conference Record of the Twentieth IEEE 26-30 Sep. 1988 Page(s):457-461 vol. 1; Mitchell, 1988, “Single and tandem junction CuInSe2 cell and module technology,” Photovoltaic Specialists Conference, 1988., Conference Record of the Twentieth IEEE 26-30 Sep. 1988 Page(s):1384-1389 vol. 2; and Kim, 1989, “High specific power (AlGaAs)GaAs/CuInSe₂ tandem junction solar cells for space applications,” Energy Conversion Engineering Conference, 1989, IECEC-89, Proceedings of the 24^{th} Intersociety 6-11 Aug. 1989 Page(s):779-784 vol. 2, each of which is hereby incorporated by reference herein in its entirety.

### 5.2.4 Semiconductor Junctions Based on Gallium Arsenide and Other Type III-V Materials

In some embodiments, semiconductor junctions 410 are based upon gallium arsenide (GaAs) or other III-V materials such as InP, AlSb, and CdTe. GaAs is a direct-band gap material having a band gap of 1.43 eV and can absorb 97% of AM1 radiation in a thickness of about two microns. Suitable type III-V junctions that can serve as semiconductor junctions 410 of the present application are described in Chapter 4 of Bube, Photovoltaic Materials, 1998, Imperial College Press, London, which is hereby incorporated by reference in its entirety.

Furthermore, in some embodiments semiconductor junction 410 is a hybrid multijunction solar cell such as a GaAs/Si mechanically stacked multijunction as described by Gee and Virshup, 1988, 20^{th} IEEE Photovoltaic Specialist Conference, IEEE Publishing, New York, p. 754, which is hereby incorporated by reference herein in its entirety, a GaAs/CuInSe₂ MSMJ four-terminal device, consisting of a GaAs thin film top cell and a ZnCdS/CuInSe₂ thin bottom cell described by Stanbery et al., 19^{th} IEEE Photovoltaic Specialist Conference, IEEE Publishing, New York, p. 280, and Kim et al., 20^{th} IEEE Photovoltaic Specialist Conference, IEEE Publishing, New York, p. 1487, each of which is hereby incorporated by reference herein in its entirety. Other hybrid multijunction solar cells are described in Bube, Photovoltaic Materials, 1998, Imperial College Press, London, pp. 131-132, which is hereby incorporated by reference herein in its entirety.

### 5.2.5 Semiconductor Junctions Based on Cadmium Telluride and Other Type II-VI Materials

In some embodiments, semiconductor junctions 410 are based upon II-VI compounds that can be prepared in either the n-type or the p-type form. Accordingly, in some embodiments, referring to FIG. 5C, semiconductor junction 410 is a p-n heterojunction in which layers 520 and 540 are any combination set forth in the following table or alloys thereof.

| Layer 520 | Layer 540 |
|---|---|
| n-CdSe | p-CdTe |
| n-ZnCdS | p-CdTe |
| n-ZnSSe | p-CdTe |
| n-ZnTe | n-CdSe |
| n-CdS | p-CdTe |
| n-CdS | p-ZnTe |
| p-ZnTe | n-CdTe |
| n-ZnSe | p-CdTe |
| n-ZnSe | p-ZnTe |
| n-ZnS | p-CdTe |
| n-ZnS | p-ZnTe |

Methods for manufacturing semiconductor junctions 410 based upon II-VI compounds are described in Chapter 4 of Bube, Photovoltaic Materials, 1998, Imperial College Press, London, which is hereby incorporated by reference in its entirety.

### 5.2.5 Semiconductor Junctions Based on Crystalline Silicon

While several embodiments semiconductor junctions 410 that are made from thin film semiconductor films are described herein, the application is not so limited. In some embodiments semiconductor junctions 410 are based upon crystalline silicon. For example, referring to FIG. 5D, in some embodiments, semiconductor junction 410 includes a layer of p-type crystalline silicon 540 and a layer of n-type crystalline silicon 550. Methods for manufacturing crystalline silicon semiconductor junctions 410 are described in Chapter 2 of Bube, Photovoltaic Materials, 1998, Imperial College Press, London, which is hereby incorporated by reference herein in its entirety.

### 5.3 Albedo Embodiments

Some embodiments of the solar cell design of the present application are useful because, among other things, they can generally collect light through the entire surface. Accordingly, in some embodiments of the present application, these solar cell assemblies (e.g., solar cell assembly 400, 700, 800, 900, etc.) are arranged in a reflective environment in which surfaces around the solar cell assembly have some amount of albedo. Albedo is a measure of reflectivity of a surface or body. It is the ratio of electromagnetic radiation (EM radiation) reflected to the amount incident upon it. This fraction is usually expressed as a percentage from 0% to 100%. In some embodiments, surfaces in the vicinity of the solar cell assemblies of the present application are prepared so that they have a high albedo by painting such surfaces a reflective white color. In some embodiments, other materials that have a high albedo can be used. For example, the albedo of some materials around such solar cells approach or exceed ninety percent. See, for example, Boer, 1977, Solar Energy 19, 525, which is hereby incorporated by reference herein in its entirety. However, surfaces having any amount of albedo (e.g., five percent or more, ten percent or more, twenty percent or more) are within the scope of the present application. In one embodiment, the solar cells assemblies of the present application are arranged in rows above a gravel surface, where the gravel has been painted white in order to improve the reflective properties of the gravel. In general, any Lambertian or diffuse reflector surface can be used to provide a high albedo surface.

By way of example, in some embodiments of the present application, the bifacial solar cell assemblies (panels) of the present application have a first and second face and are placed in rows facing South in the Northern hemisphere (or facing North in the Southern hemisphere). Each of the panels is placed some distance above the ground (e.g., 100 cm above the ground). The East-West separation between the panels is somewhat dependent upon the overall dimensions of the panels. By way of illustration only, panels having overall dimensions of about 106 cm×44 cm are placed in the rows such that the East-West separation between the panels is between 10 cm and 50 cm. In one specific example the East-West separation between the panels is 25 cm.

In some embodiments, the central point of the panels in the rows of panels is between 0.5 meters and 2.5 meters from the ground. In one specific example, the central point of the panels is 1.55 meters from the ground. The North-South separation between the rows of panels is dependent on the dimensions of the panels. By way of illustration, in one specific example, in which the panels have overall dimensions of about 106 cm×44 cm, the North-South separation is 2.8 meters. In some embodiments, the North-South separation is between 0.5 meters and 5 meters. In some embodiments, the North-South separation is between 1 meter and 3 meters.

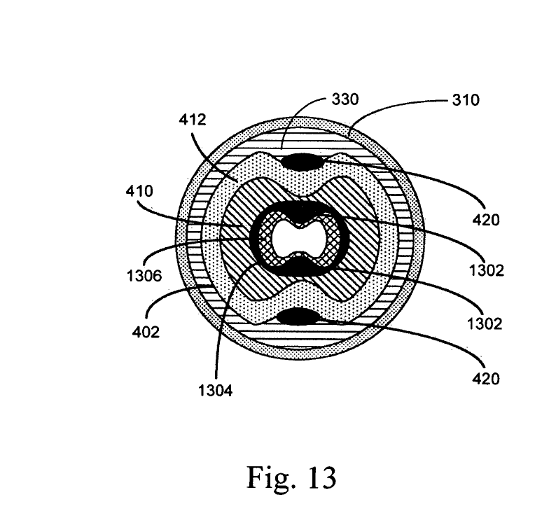

In some embodiments, models for computing the amount of sunlight received by solar panels as put forth in Lorenzo et al., 1985, Solar Cells 13, pp. 277-292, which is hereby incorporated by reference herein in its entirety, are used to compute the optimum horizontal tilt and East-West separation of the solar panels in the rows of solar panels that are placed in a reflective environment. In some embodiments, internal or external reflectors are implemented in the solar cell assembly to take advantage of the albedo effect and enhance light input into the solar cell assembly. An exemplary embodiment of the internal reflectors (e.g., reflector 1404) is depicted in FIG. 16. More description of albedo surfaces that can be used in conjunction with the present application are disclosed in U.S. patent application Ser. No. 11/315,523, which is hereby incorporated by reference in its entirety.

### 5.4 Dual Layer Core Embodiments

Embodiments of the present application in which conductive core 404 of the solar cells 402 of the present application is made of a uniform conductive material have been disclosed. The application is not limited to these embodiments. In some embodiments, conductive core 404 in fact has an inner core and an outer conductive core. The inner core can be referred to as a substrate 403 while the outer core can be referred to as back-electrode 404 in such embodiment. In such embodiments, the outer conductive core is disposed around all or a part of substrate 403. In such embodiments, substrate 403 is typically nonconductive whereas the outer core is conductive. Substrate 403 has an elongated shape consistent with other embodiments of the present application. In some embodiments, substrate 403 is an electrically conductive nonmetallic material. However, the present application is not limited to embodiments in which substrate 403 is electrically conductive because the outer core can function as the electrode. In some embodiments, substrate 403 is tubing (e.g., glass tubing).

In some embodiments, substrate 403 is made of a material such as polybenzamidazole (e.g., CELAZOLE®, available from Boedeker Plastics, Inc., Shiner, Tex.). In some embodiments, the inner core is made of polymide (e.g., DuPont™ VESPEL®, or DuPont™ KAPTON®, Wilmington, Del.). In some embodiments, the inner core is made of polytetrafluoroethylene (PTFE) or polyetheretherketone (PEEK), each of which is available from Boedeker Plastics, Inc. In some embodiments, substrate 403 is made of polyamide-imide (e.g., TORLON® PAI, Solvay Advanced Polymers, Alpharetta, Ga.).

In some embodiments, substrate 403 is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” A variety of resin types and cloth materials can be used to manufacture thermoset laminates with a range of mechanical, thermal, and electrical properties. In some embodiments, substrate 403 is a phenoloic laminate having a NEMA grade of G-3, G-5, G-7, G-9, G-10 or G-11. Exemplary phenolic laminates are available from Boedeker Plastics, Inc.

In some embodiments, substrate 403 is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, substrate 403 is made of cross-linked polystyrene. One example of cross-linked polystyrene is REXOLITE® (C-Lec Plastics, Inc). REXOLITE is a thermoset, in particular a rigid and translucent plastic produced by cross linking polystyrene with divinylbenzene.

In other embodiments, substrate 403 is made of polycarbonate. Such polycarbonates can have varying amounts of glass fibers (e.g., 10%, 20%, 30%, or 40%) in order to adjust tensile strength, stiffness, compressive strength, as well as the thermal expansion coefficient of the material. Exemplary polycarbonates are ZELUX® M and ZELUX® W, which are available from Boedeker Plastics, Inc.

In some embodiments, substrate 403 is made of polyethylene. In some embodiments, substrate 403 is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173, which is hereby incorporated by reference herein in its entirety. In some embodiments, substrate 403 is made of acrylonitrile-butadiene-styrene, polytetrifluoro-ethylene (TEFLON), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 6-175, which is hereby incorporated by reference herein in its entirety.

Additional exemplary materials that can be used to form substrate 403 are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In general, outer core is made out of any material that can support the photovoltaic current generated by solar cell with negligible resistive losses. In some embodiments, outer core is made of any conductive metal, such as aluminum, molybdenum, steel, nickel, silver, gold, or an alloy thereof. In some embodiments, outer core is made out of a metal-, graphite-, carbon black-, or superconductive carbon black-filled oxide, epoxy, glass, or plastic. In some embodiments, outer core is made of a conductive plastic. In some embodiments, this conductive plastic is inherently conductive without any requirement for a filler. In some embodiments, inner core is made out of a conductive material and outer core is made out of molybdenum. In some embodiments, inner core is made out of a nonconductive material, such as a glass rod, and outer core is made out of molybdenum.

### 5.5 Exemplary Dimensions

The present application encompasses solar cell assemblies having any dimensions that fall within a broad range of dimensions. For example, referring to FIG. 4B, the present application encompasses solar cell assemblies having a length l between 1 cm and 50,000 cm and a width w between 1 cm and 50,000 cm. In some embodiments, the solar cell assemblies have a length l between 10 cm and 1,000 cm and a width w between 10 cm and 1,000 cm. In some embodiments, the solar cell assemblies have a length l between 40 cm and 500 cm and a width w between 40 cm and 500 cm.

As illustrated in FIG. 3A, a solar cell 300 has a length l that is great compared to a width of its cross-section. In some embodiments, a solar cell 300 has a length l between 10 millimeters (mm) and 100,000 mm and a width w between 3 mm and 10,000 mm. In some embodiments, a solar cell 300 has a length l between 10 mm and 5,000 mm and a width w between 10 mm and 1,000 mm. In some embodiments, a solar cell 300 has a length 1 between 40 mm and 15000 mm and a width d between 10 mm and 50 mm.

In some embodiments, a solar cell 300 may be elongated as illustrated in FIG. 3A. As illustrated in FIG. 3A, an elongated solar cell 300 is one that is characterized by having a longitudinal dimension l and a width dimension w. In some embodiments of an elongated solar cell 300, the longitudinal dimension l exceeds the width dimension w by at least a factor of 4, at least a factor of 5, or at least a factor of 6. In some embodiments, the longitudinal dimension 1 of the solar cell 300 is 10 centimeters or greater, 20 centimeters or greater, or 100 centimeters or greater. In some embodiments, the width w (e.g., diameter) of the solar cell 300 is 5 millimeters or more, 10 millimeters or more, 50 millimeters or more, 100 millimeters or more, 500 millimeters or more, 1000 millimeters or more, or 2000 millimeters or more.

In some embodiments, the solar cell units 300 have a length of between 0.5 microns and 1×10¹⁸ microns, between 0.5 microns and 1×10¹⁷ microns, between 0.5 microns and 1×10¹⁶ microns, between 0.5 microns and 1×10¹⁵ microns, between 0.5 microns and 1×10¹⁴ microns, between 0.5 microns and 1×10¹³ microns, between 0.5 microns and 1×10¹² microns, between 0.5 microns and 1×10¹¹ microns, between 0.5 microns and 1×10¹⁰ microns, between 0.5 microns and 1×10⁹ microns, between 0.5 microns and 1×10⁸ microns, between 0.5 microns and 1×10⁷ microns, between 0.5 microns and 1×10⁶ microns, between 0.5 microns and 1×10⁵ microns, between 0.5 microns and 1×10⁴ microns, between 0.5 microns and 1×10³ microns, between 0.5 microns and 1×10² microns, between 0.5 microns and 10 microns, or between 0.5 microns and 1×1 micron. In some embodiments, each solar cell unit 300 in an assembly has the same length. In some embodiments, each solar cell unit 300 can have the same length or different length than other solar cell units 300 in the assembly.

In some embodiments, each solar cell unit is cylindrical and has a cross-section that has a diameter of between 1 micron and 1×10¹² microns, a diameter of greater than 1×10⁶ microns, a diameter of greater than 1×10⁷ microns, a diameter of greater than 1×10⁸ microns, a diameter of greater than 1×10⁹ microns, a diameter of greater than 1×10¹⁰ microns, a diameter of greater than 1×10¹¹ microns, a diameter of greater than 1×10¹² microns, or a diameter of greater than 1×10¹³ microns.

### 5.6 Additional Solar Cell Embodiments

Using FIG. 3B for reference to element numbers, in some embodiments, copper-indium-gallium-diselenide (Cu(InGa)Se₂), referred to herein as CIGS, is used to make the absorber layer of junction 110. In such embodiments, back-electrode 404 can be made of molybdenum. In some embodiments, back-electrode 404 includes an inner core of polyimide and an outer core that is a thin film of molybdenum sputtered onto the polyimide core prior to CIGS deposition. On top of the molybdenum, the CIGS film, which absorbs the light, is evaporated. Cadmium sulfide (CdS) is then deposited on the CIGS in order to complete semiconductor junction 4. Optionally, a thin intrinsic layer (i-layer) 415 is then deposited on the semiconductor junction 410. The i-layer 415 can be formed using a material including but not limited to, zinc oxide, metal oxide or any transparent material that is highly insulating. Next, transparent conductive layer 412 is disposed on either the i-layer (when present) or the semiconductor junction 410 (when the i-layer is not present). Transparent conductive layer 412 can be made of a material such as aluminum doped zinc oxide (ZnO:Al), gallium doped zinc oxide, boron dope zinc oxide, indium-zinc oxide, or indium-tin oxide.

ITN Energy Systems, Inc., Global Solar Energy, Inc., and the Institute of Energy Conversion (IEC), have collaboratively developed technology for manufacturing CIGS photovoltaics on polyimide substrates using a roll-to-roll co-evaporation process for deposition of the CIGS layer. In this process, a roll of molybdenum-coated polyimide film (referred to as the web) is unrolled and moved continuously into and through one or more deposition zones. In the deposition zones, the web is heated to temperatures of up to ˜450° C. and copper, indium, and gallium are evaporated onto it in the presence of selenium vapor. After passing out of the deposition zone(s), the web cools and is wound onto a take-up spool. See, for example, 2003, Jensen et al., “Back Contact Cracking During Fabrication of CIGS Solar Cells on Polyimide Substrates,” NCPV and Solar Program Review Meeting 2003, NREL/CD-520-33586, pages 877-881, which is hereby incorporated by reference in its entirety. Likewise, Birkmire et al., 2005, Progress in Photovoltaics: Research and Applications 13, 141-148, hereby incorporated by reference, disclose a polyimide/Mo web structure, specifically, PI/Mo/Cu(InGa)Se₂/CdS/ZnO/ITO/Ni—Al. Deposition of similar structures on stainless foil has also been explored. See, for example, Simpson et al., 2004, “Manufacturing Process Advancements for Flexible CIGS PV on Stainless Foil,” DOE Solar Energy Technologies Program Review Meeting, PV Manufacturing Research and Development, P032, which is hereby incorporated by reference herein in its entirety.

In some embodiments of the present application, an absorber material is deposited onto a polyimide/molybdenum web, such as those developed by Global Solar Energy (Tucson, Ariz.), or a metal foil (e.g., the foil disclosed in Simpson et al.). In some embodiments, the absorber material is any of the absorbers disclosed herein. In a particular embodiment, the absorber is Cu(InGa)Se₂. In some embodiments, the elongated core is made of a nonconductive material such as undoped plastic. In some embodiments, the elongated core is made of a conductive material such as a conductive metal, a metal-filled epoxy, glass, or resin, or a conductive plastic (e.g., a plastic containing a conducting filler). Next, semiconductor junction 410 is completed by depositing a window layer onto the absorber layer. In the case where the absorber layer is Cu(InGa)Se₂, CdS can be used. Finally, optional i-layer 415 and transparent conductive layer 412 are added to complete the solar cell. Next, the foil is wrapped around and/or glued to the elongated core. One useful aspect of such a fabrication method is that material that cannot necessarily withstand the deposition temperature of the absorber layer, window layer, i-layer or transparent conductive layer 412 can be used as an inner core for the solar cell. This manufacturing process can be used to manufacture any of the solar cells 402 disclosed in the present application, where the conductive core 402 includes an inner core and an outer conductive core. The inner core can be any conductive or nonconductive material, such as those disclosed herein, whereas the outer conductive core is the web or foil onto which the absorber layer, window layer, and transparent conductive layer were deposited prior to rolling the foil onto the inner core. In some embodiments, the web or foil is glued onto the inner core using appropriate glue.

An aspect of the present application provides a method of manufacturing a solar cell including depositing an absorber layer on a first face of a metallic web or a conducting foil. Next, a window layer is deposited on to the absorber layer. Next, a transparent conductive layer is deposited on to the window layer. The metallic web or conducting foil is then rolled around an elongated core, thereby forming an elongated solar cell 402. In some embodiments, the absorber layer is copper-indium-gallium-diselenide (Cu(InGa)Se₂) and the window layer is cadmium sulfide. In some embodiments, the metallic web is a polyimide/molybdenum web. In some embodiments, the conducting foil is steel foil or aluminum foil. In some embodiments, the elongated core is made of a conductive metal, a metal-filled epoxy, a metal-filled glass, a metal-filled resin, or a conductive plastic.

In some embodiments, a transparent conducting oxide conductive film is deposited on a nonplanar elongated core rather than wrapping a metal web or foil around the elongated core. In such embodiments, the nonplanar elongated core can be, for example, a plastic rod, a glass rod, a glass tube, or a plastic tube. Such embodiments require some form of conductor in electrical communication with the interior face or back contact of the semiconductor junction. In some embodiments, divots in the nonplanar elongated core are filled with a conductive metal in order to provide such a conductor. The conductor can be inserted in the divots prior to depositing the transparent conductive layer or conductive back contact film onto the core. In some embodiments such a conductor is formed from a metal source that runs lengthwise along the side of the elongated solar cell 402. This metal can be deposited by evaporation, sputtering, screen printing, inkjet printing, metal pressing, conductive ink or glue used to attach a metal wire, or other means of metal deposition.

More specific embodiments will now be disclosed. In some embodiments, the elongated core is a glass tubing having a divot that runs lengthwise on the outer surface of the glass tubing, and the manufacturing method includes depositing a conductor in the divot prior to the rolling step. In some embodiments, the glass tubing has a second divot that runs lengthwise on the surface of the glass tubing. In such embodiments, the first divot and the second divot are on approximate or exact opposite circumferential sides of the glass tubing. In such embodiments, accordingly, the method further includes depositing a conductor in the second divot prior to the rolling or, in embodiments in which rolling is not used, prior to the deposition of an inner transparent conductive layer or conductive film, junction, and outer transparent conductive layer onto the elongated core.

In some embodiments, the elongated core is a glass rod having a first divot that runs lengthwise on the surface of the glass rod and the method includes depositing a conductor in the first divot prior to the rolling. In some embodiments, the glass rod has a second divot that runs lengthwise on the surface of the glass rod and the first divot and the second divot are on approximate or exact opposite sides of the glass rod. In such embodiments, accordingly, the method further includes depositing a conductor in the second divot prior to the rolling or, in embodiments in which rolling is not used, prior to the deposition of an inner transparent conductive layer or conductive film, junction, and outer transparent conductive layer onto the elongated core. Suitable materials for the conductor are any of the materials described as a conductor herein including, but not limited to, aluminum, molybdenum, titanium, steel, nickel, silver, gold, or an alloy thereof.

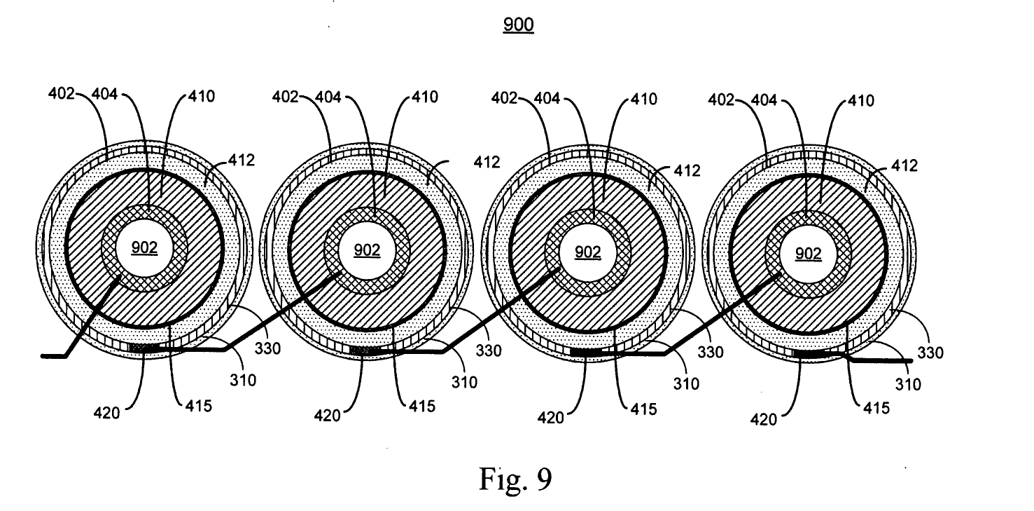

FIG. 13 details a cross-section of a solar cell 402 in accordance with some embodiments of the present application. Solar cell 402 can be manufactured using either the rolling method or deposition techniques. Components that have reference numerals corresponding to other embodiments of the present application (e.g., 410, 412, and 420) are made of the same materials disclosed in such embodiments. In FIG. 13, there is an elongated tubing 1306 having a first and second divot running lengthwise along the tubing (perpendicular to the plane of the page) that are on opposing sides of tubing 1306 as illustrated. In typical embodiments, tubing 1306 is not conductive. For example, tubing 1306 is made of plastic or glass in some embodiments. Conductive wiring 1302 is placed in the first and second divot as illustrated in FIG. 13. In some embodiments, the conductive wiring is made of any of the conductive materials of the present application. In some embodiments, conductive wiring 1302 is made out of aluminum, molybdenum, steel, nickel, titanium, silver, gold, or an alloy thereof. In embodiments where 1304 is a conducting foil or metallic web, the conductive wiring 1302 is inserted into the divots prior to wrapping the metallic web or conducting foil 1304 around the elongated core 1306. In embodiments where 1304 is a transparent conductive oxide or conductive film, the conductive wiring 1302 is inserted into the divots prior to depositing the transparent conductive oxide or conductive film 1304 onto elongated core 1306. As noted, in some embodiments the metallic web or conducting foil 1304 is wrapped around tubing 1306. In some embodiments, metallic web or conducting foil 1304 is glued to tubing 1306. In some embodiments layer 1304 is not a metallic web or conducting foil. For instance, in some embodiments, layer 1304 is a transparent conductive layer. Such a layer is useful because it allows for thinner absorption layers in the semiconductor junction. In embodiments where layer 1304 is a transparent conductive layer, the transparent conductive layer, semiconductor junction 410 and outer transparent conductive layer 412 are deposited using deposition techniques.

One aspect of the application provides a solar cell assembly including a plurality of elongated solar cells 402 each having the structure disclosed in FIG. 13. That is, each elongated solar cell 402 in the plurality of elongated solar cells includes an elongated tubing 1306, a metallic web or a conducting foil (or, alternatively, a layer of TCO) 1304 disposed around all or part of the elongated tubing 1306, a semiconductor junction 410 disposed around all or part of the metallic web or the conducting foil (or, alternatively, a layer of TCO) 1304 and a transparent conductive oxide layer 412 disposed around all or part of the semiconductor junction 410. The elongated solar cells 402 in the plurality of elongated solar cells are geometrically arranged in a parallel or a near parallel manner thereby forming a planar array having a first face and a second face. The plurality of elongated solar cells is arranged such that one or more elongated solar cells in the plurality of elongated solar cells are not in electrically conductive contact with adjacent elongated solar cells. In some embodiments, the elongated solar cells can be in physical contact with each other if there is an insulative layer between adjacent elongated solar cells. The solar cell assembly further includes a plurality of metal counter-electrodes. Each respective elongated solar cell 402 in the plurality of elongated solar cells is bound to a first corresponding metal counter-electrode 420 in the plurality of metal counter-electrodes such that the first metal counter-electrode lies in a first groove that runs lengthwise on the respective elongated solar cell 402. The apparatus further includes a transparent electrically insulating substrate that covers all or a portion of the face of the planar array. A first and second elongated solar cell in the plurality of elongated solar cells are electrically connected in series by an electrical contact that connects the first electrode of the first elongated solar cell to the first corresponding counter-electrode of the second elongated solar cell. In some embodiments, the elongated tubing 1306 is glass tubing or plastic tubing having a one or more grooves filled with a conductor 1302. In some embodiments, each respective elongated solar cell 402 in the plurality of elongated solar cells is bound to a second corresponding metal counter-electrode 420 in the plurality of metal counter-electrodes such that the second metal counter-electrode lies in a second groove that runs lengthwise on the respective elongated solar cell 402 and such that the first groove and the second groove are on opposite or substantially opposite circumferential sides of the respective elongated solar cell 402. In some embodiments, the plurality of elongated solar cells 402 is configured to receive direct light from the first face and the second face of the planar array.

### 5.7 Static Concentrators

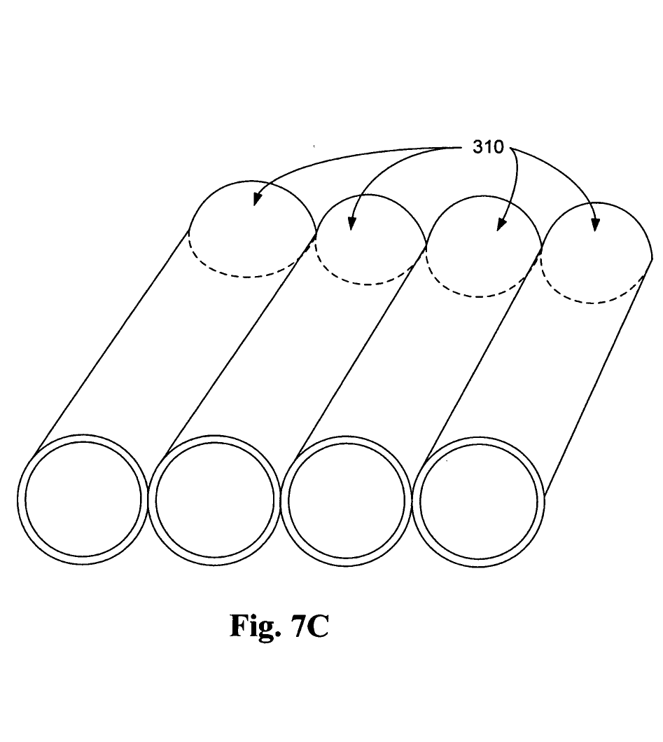

Encapsulated solar cell unit 300 may be assembled into bifacial arrays as, for example, any of assemblies 400 (FIG. 4), 700 (FIG. 7), 800 (FIG. 8), 900 (FIG. 9), or 1000 (FIG. 10). In some embodiments, static concentrators are used to improve the performance of the solar cell assemblies of the present application. The use of a static concentrator in one exemplary embodiment is illustrated in FIG. 11, where static concentrator 1102, with aperture AB, is used to increase the efficiency of bifacial solar cell assembly CD, where solar cell assembly CD is, for example, any of assemblies 400 (FIG. 4), 700 (FIG. 7), 800 (FIG. 8), 900 (FIG. 9), or 1000 (FIG. 10) of other assemblies of solar cell units 300 of the present application. Static concentrator 1102 illustrated in FIG. 11 can be formed from any static concentrator materials known in the art such as, for example, a simple, properly bent or molded aluminum sheet, or reflector film on polyurethane. Concentrator 1102 is an example of a low concentration ratio, nonimaging, compound parabolic concentrator (CPC)-type collector. Any (CPC)-type collector can be used with the solar cell assemblies of the present application. For more information on (CPC)-type collectors, see Pereira and Gordon, 1989, Journal of Solar Energy Engineering, 111, pp. 111-116, which is hereby incorporated by reference herein in its entirety.

Additional static concentrators that can be used with the present application are disclosed in Uematsu et al., 1999, Proceedings of the 11^{th} International Photovoltaic Science and Engineering Conference, Sapporo, Japan, pp. 957-958; Uematsu et al., 1998, Proceedings of the Second World Conference on Photovoltaic Solar Energy Conversion, Vienna, Austria, pp. 1570-1573; Warabisako et al., 1998, Proceedings of the Second World Conference on Photovoltaic Solar Energy Conversion, Vienna, Austria, pp. 1226-1231; Eames et al., 1998, Proceedings of the Second World Conference on Photovoltaic Solar Energy Conversion, Vienna Austria, pp. 2206-2209; Bowden et al., 1993, Proceedings of the 23^{rd} IEEE Photovoltaic Specialists Conference, pp. 1068-1072; and Parada et al., 1991, Proceedings of the 10^{th} EC Photovoltaic Solar Energy Conference, pp. 975-978, each of which is hereby incorporated by reference herein in its entirety.

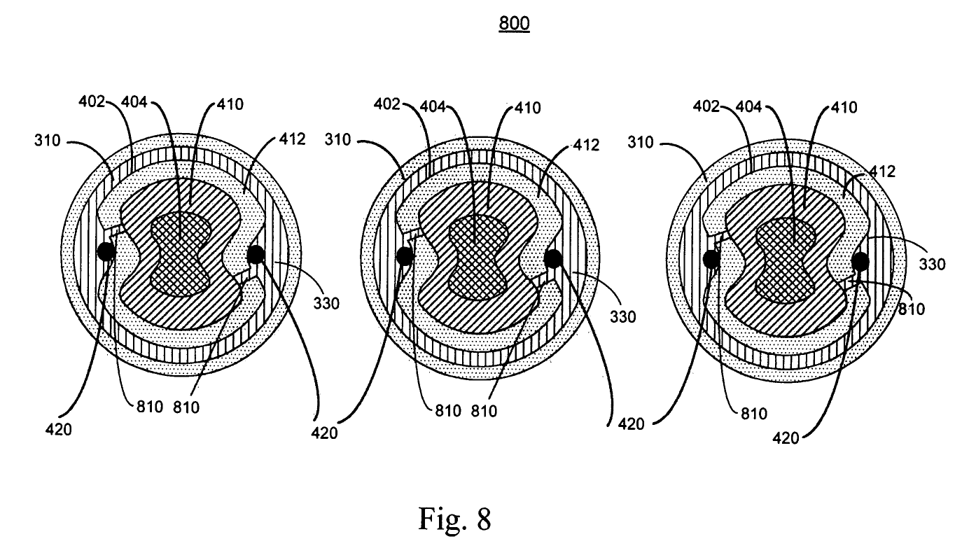

In some embodiments, a static concentrator as illustrated in FIG. 12 is used. The bifacial solar cells illustrated in FIG. 12 can be any bifacial solar cell assembly of the present application including. but not limited to assembly 400 (FIG. 4), 700 (FIG. 7), 800 (FIG. 8), 900 (FIG. 9), or 1000 (FIG. 10). The static concentrator illustrated in FIG. 12 uses two sheets of cover glass on the front and rear of the module with submillimeter V-grooves that are designed to capture and reflect incident light as illustrated in the figure. More details of such concentrators are found in Uematsu et al., 2001, Solar Energy Materials & Solar Cell 67, 425-434 and Uematsu et al., 2001, Solar Energy Materials & Solar Cell 67, 441-448, each of which is hereby incorporated by reference herein in its entirety. Additional static concentrators that can be used with the present application are discussed in Handbook of Photovoltaic Science and Engineering, 2003, Luque and Hegedus (eds.), Wiley & Sons, West Sussex, England, Chapter 12, which is hereby incorporated by reference herein in its entirety.

### 5.8 Internal Reflector Embodiments

After elongated solar cells 402 are encapsulated as depicted, for example, in FIG. 15, they may be arranged to form solar cell assemblies. FIG. 16 illustrates a solar cell assembly 1600 in accordance with the present application. In this exemplary embodiment, an internal reflector 1404 is used to enhance solar input into the solar cell system. As shown in FIG. 16, elongated solar cells 402 and an internal reflector 1404 are assembled into an alternating array as shown. Elongated solar cells 402 in solar cell assembly 1600 have counter-electrodes 420 and electrodes 440. As illustrated in FIG. 16, solar cell assembly 1600 includes a plurality of elongated solar cells 402. There is no limit to the number of solar cells 402 in this plurality (e.g., 10 or more, 100 or more, 1000 or more, 10,000 or more, between 5,000 and one million solar cells 402, etc.). Accordingly, solar cell assembly 1600 also includes a plurality of internal reflectors 1404. There is no limit to the number of internal reflectors 1404 in this plurality (e.g., 10 or more, 100 or more, 1000 or more, 10,000 or more, between 5,000 and one million reflector 1404, etc.).

Within solar cell assembly 1600, internal reflectors 1404 run lengthwise along corresponding elongated solar cells 402. In some embodiments, internal reflectors 1404 have a hollow core. As in the case of elongated conductive core 404, a hollow nonconductive core (e.g. substrate 403 of FIG. 3B) is useful in many instances because it reduces the amount of material needed to make such devices, thereby lowering costs. In some embodiments, internal reflector 1404 is a plastic casing with a layer of highly reflective material (e.g., polished aluminum, aluminum alloy, silver, nickel, steel, etc.) deposited on the plastic casing. In some embodiments, internal reflector 1404 is a single piece made out of polished aluminum, aluminum alloy, silver, nickel, steel, etc. In some embodiments, internal reflector 1404 is a metal or plastic casing onto which is layered a metal foil tape. Exemplary metal foil tapes include, but are not limited to, 3M aluminum foil tape 425, 3M aluminum foil tape 427, 3M aluminum foil tape 431, and 3M aluminum foil tape 439 (3M, St. Paul, Minn.). Internal reflector 1404 can adopt a broad range of designs, only one of which is illustrated in FIG. 16. Central to the design of reflectors 1404 found in some embodiments of the present application is the desire to reflect direct light that enters into both sides of solar cell assembly 1600 (i.e., side 1620 and side 1640).

In general, reflectors 1404 of the present application are designed to enhance reflection of light into adjacent elongated solar cells 402. Direct light that enters one side of solar cell assembly 1600 (e.g., side 1940, above the plane of the solar cell assembly drawn in FIG. 16) is directly from the sun whereas light that enters the other side of the solar cell (e.g., side 1620, below the plane of the solar cell assembly drawn in FIG. 16) will have been reflected off of a surface. In some embodiments, this surface is Lambertian, a diffuse or an involute reflector. Thus, because each side of the solar cell assembly faces a different light environment, the shape of internal reflector 1404 on side 1620 may be different than on side 1640.

Although internal reflector 1404 is illustrated in FIG. 16 as having a symmetrical four-sided cross-sectional shape, the cross-sectional shape of the internal reflectors 1404 of the present application are not limited to such a configuration. In some embodiments, a cross-sectional shape of an internal reflector 1404 is asteroid. In some embodiments, a cross-sectional shape of an internal reflector 1404 is four-sided and at least one side of the four-sided cross-sectional shape is linear. In some embodiments, a cross-sectional shape of an internal reflector 1404 is four-sided and at least one side of the four-sided cross-sectional shape is parabolic. In some embodiments, a cross-sectional shape of an internal reflector 1404 is four-sided and at least one side of the four-sided cross-sectional shape is concave. In some embodiments, a cross-sectional shape of an internal reflector 1404 is four-sided; and at least one side of the four-sided cross-sectional shape is circular or elliptical. In some embodiments, a cross-sectional shape of an internal reflector in the plurality of internal reflectors is four-sided and at least one side of the four-sided cross-sectional shape defines a diffuse surface on the internal reflector. In some embodiments, a cross-sectional shape of an internal reflector 1404 is four-sided and at least one side of the four-sided cross-sectional shape is the involute of a cross-sectional shape of an elongated solar cell 402. In some embodiments, a cross-sectional shape of an internal reflector 1404 is two-sided, three-sided, four-sided, five-sided, or six-sided. In some embodiments, a cross-sectional shape of an internal reflector in the plurality of internal reflectors 1404 is four-sided and at least one side of the four-sided cross-sectional shape is faceted.

Additional features are added to reflectors 1404 to enhance the reflection onto adjacent elongated solar cells 402 in some embodiments. Modified reflectors 1404 are equipped with a strong reflective property such that incident light is effectively reflected off the side surfaces 1610 of the reflectors 1404. In some embodiments, the reflected light off surfaces 1610 does not have directional preference. In other embodiments, the reflector surfaces 1610 are designed such that the reflected light is directed towards the elongated solar cell 402 for enhanced absorbance.

In some embodiments, the connection between an internal reflector 1404 and an adjacent elongated solar cell is provided by an additional adaptor piece. Such an adapter piece has surface features that are complementary to both the shapes of internal reflectors 1404 as well as elongated solar cells 402 in order to provide a tight fit between such components. In some embodiments, such adaptor pieces are fixed on internal reflectors 1404. In other embodiments, the adaptor pieces are fixed on elongated solar cells 402. In additional embodiments, the connection between elongated solar cells 402 and reflectors 1404 may be strengthened by electrically conducting glue or tapes.

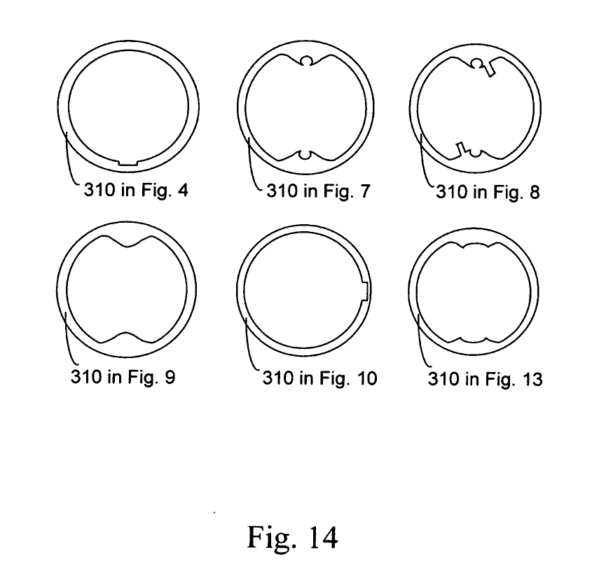

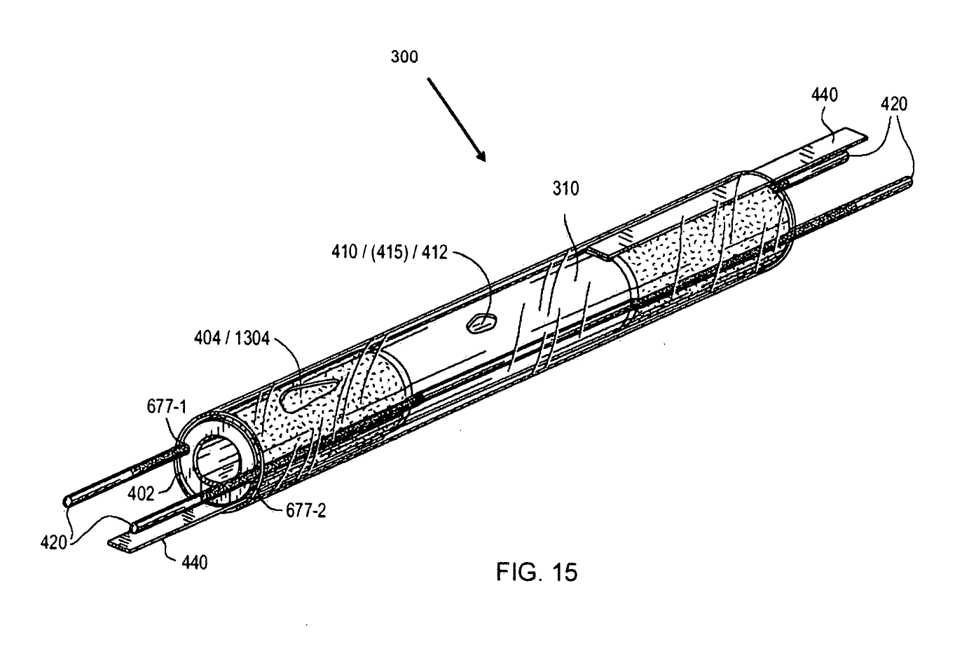

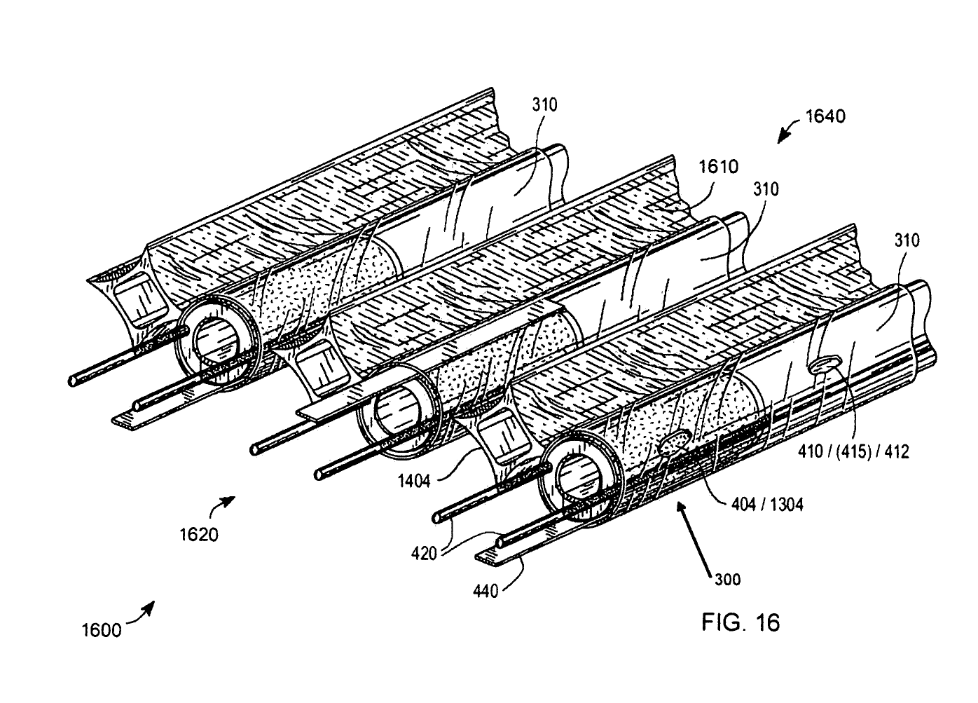

Diffuse Reflection. In some embodiments in accordance with the present application, the side surface 1610 of reflector 1404 is a diffuse reflecting surface (e.g., 1610 in FIG. 16). The concept of diffuse reflection can be better appreciated with a first understanding of specular reflection. Specular reflection is defined as the reflection off smooth surfaces such as mirrors or a calm body of water (e.g., 1702 in FIG. 17A). On a specular surface, light is reflected mainly in the direction of the reflected ray and is attenuated by an amount dependent upon the physical properties of the surface. Since the light reflected from the surface is mainly in the direction of the reflected ray, the position of the observer (e.g., the position of the elongated solar cells 402) determines the perceived illumination of the surface. Specular reflection models the light reflecting properties of shiny or mirror-like surfaces. In contrast to specular reflection, reflection off rough surfaces such as clothing, paper, and the asphalt roadway leads to a different type of reflection known as diffuse reflection (FIG. 17B). Light incident on a diffuse reflection surface is reflected equally in all directions and is attenuated by an amount dependent upon the physical properties of the surface. Since light is reflected equally in all directions the perceived illumination of the surface is not dependent on the position of the observer or receiver of the reflected light (e.g. the position of the elongated solar cell 402). Diffuse reflection models the light reflecting properties of matt surfaces.

Diffuse reflection surfaces reflect off light with no directional dependence for the viewer. Whether the surface is microscopically rough or smooth has a tremendous impact upon the subsequent reflection of a beam of light. Input light from a single directional source is reflected off in all directions on a diffuse reflecting surface (e.g., 1704 in FIG. 17B). Diffuse reflection originates from a combination of internal scattering of light, e.g., the light is absorbed and then re-emitted, and external scattering from the rough surface of the object.

Lambertian reflection. In some embodiments in accordance with the present application, surface 1610 of reflector 1404 is a Lambertian reflecting surface (e.g., 1706 in FIG. 17C). A Lambertian source is defined as an optical source that obeys Lambert's cosine law, i.e., that has an intensity directly proportional to the cosine of the angle from which it is viewed (FIG. 17C). Accordingly, a Lambertian surface is defined as a surface that provides uniform diffusion of incident radiation such that its radiance (or luminance) is the same in all directions from which it can be measured (e.g., radiance is independent of viewing angle) with the caveat that the total area of the radiating surface is larger than the area being measured.

On a perfectly diffusing surface, the intensity of the light emanating in a given direction from any small surface component is proportional to the cosine of the angle of the normal to the surface. The brightness (luminance, radiance) of a Lambertian surface is constant regardless of the angle from which it is viewed.

The incident light \vec{l} strikes a Lambertian surface (FIG. 17C) and reflects in different directions. When the intensity of \vec{l} is defined as Iₘ, the intensity (e.g., Iₒᵤₜ) of a reflected light \vec{v} can be defined as following in accordance to Lambert's cosine law:

$${I}_{out} ( \vec{v} ) = {I}_{i n} ( \vec{l} ) ϕ ( \vec{v} , \vec{l} ) \frac{cos {θ}_{i n}}{cos {θ}_{out}}$$

where φ(\vec{v},\vec{l})=k_{d} cos θₒᵤₜ and k_{d} is related to the surface property. The incident angle is defined as θₘ, and the reflected angle is defined as θₒᵤₜ. Using the vector dot product formula, the intensity of the reflected light can also be written as:

Iₒᵤₜ(\vec{v})=k_{d}Iᵢₙ(\vec{l})\vec{l}·\vec{n},

where \vec{n} denotes a vector that is normal to the Lambertian surface.

Such a Lambertian surface does not lose any incident light radiation, but re-emits it in all the available solid angles with a 2π radians, on the illuminated side of the surface. Moreover, a Lambertian surface emits light so that the surface appears equally bright from any direction. That is, equal projected areas radiate equal amounts of luminous flux. Though this is an ideal, many real surfaces approach it. For example, a Lambertian surface can be created with a layer of diffuse white paint. The reflectance of such a typical Lambertian surface may be 93%. In some embodiments, the reflectance of a Lambertian surface may be higher than 93%. In some embodiments, the reflectance of a Lambertian surface may be lower than 93%. Lambertian surfaces have been widely used in LED design to provide optimized illumination, for example in U.S. Pat. No. 6,257,737 to Marshall, et al.; U.S. Pat. No. 6,661,521 to Stern; and U.S. Pat. No. 6,603,243 to Parkyn, et al., which are hereby incorporated by reference in their entireties.

Usefully, Lambertian surfaces 1610 on reflector 1404 effectively reflect light in all directions. The reflected light is then directed towards the elongated solar cell 402 to enhance solar cell performance.

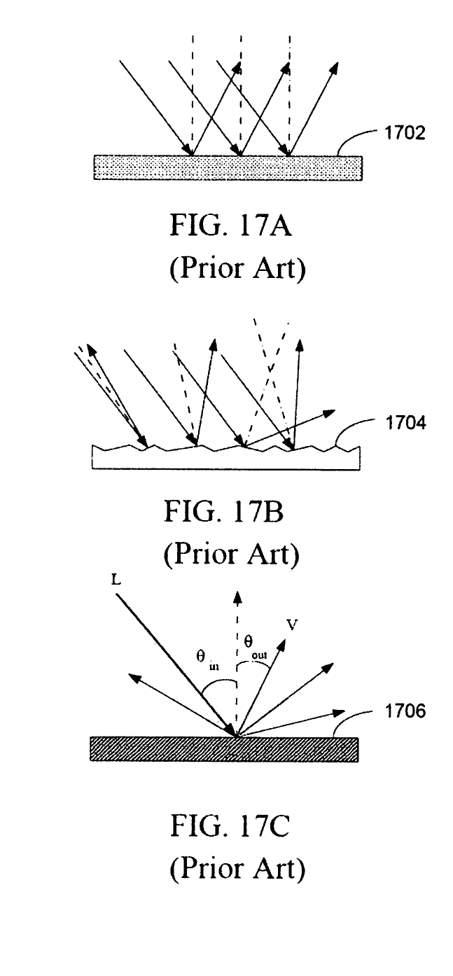

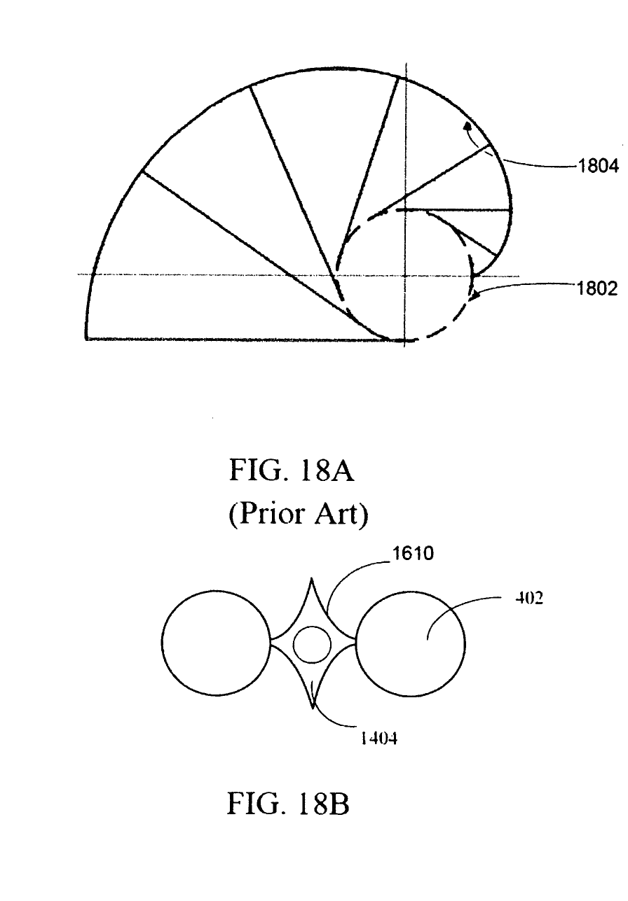

Reflection on involute surfaces. In some embodiments in accordance with the present application, surface 1610 of the reflector 1404 is an involute surface of the elongated solar cell tube 402. In some embodiments, the elongated solar cell tube 402 is circular or near circular. Reflector surface 1610 is, in some embodiments, the involute of a circle (e.g. 1804 in FIG. 18A). The involute of circle 1802 is defined as the path traced out by a point on a straight line that rolls around a circle. For example, the involute of a circle can be drawn in the following steps. First, attach a string to a point on a curve. Second, extend the string so that it is tangent to the curve at the point of attachment. Third, wind the string up, keeping it always taut. The locus of points traced out by the end of the string (e.g. 1804 in FIG. 18) is called the involute of the original circle 1802. The original circle 1802 is called the evolute of its involute curve 1804.

Although in general a curve has a unique evolute, it has infinitely many involutes corresponding to different choices of initial point. An involute can also be thought of as any curve orthogonal to all the tangents to a given curve. For a circle of radius r, at any time t, its equation can be written as:

x=r cos t.

y=r sin t

Correspondingly, the parametric equation of the involute of the circle is:

x₁=r(cos t+t sin t).

y₁=r(sin t−t cos t)

Evolute and involute are reciprocal functions. The evolute of an involute of a circle is a circle.

Involute surfaces have been implemented in numerous patent designs to enhance light reflections. For example, a flash lamp reflector (U.S. Pat. No. 4,641,315 to Draggoo, hereby incorporated by reference herein in its entirety) and concave light reflector devices (U.S. Pat. No. 4,641,315 to Rose, hereby incorporated by reference herein in its entirety), which are hereby incorporated by reference in their entireties, both utilize involute surfaces to enhance light reflection efficiency.

In FIG. 18B, an internal reflector 1404 is connected to two elongated solar cells 402. Details of both reflector 1404 and solar cell 402 are omitted to highlight the intrinsic relationship between the shapes of the elongated solar cell 402 and the shape of the side surface 1610 of the internal reflector 1404. Side surfaces 1610 are constructed such that they are the involute of the circular elongated solar cell 402.

Usefully, the involute-evolute design imposes optimal interactions between the side surfaces 1610 of reflectors 1404 and the adjacent elongated solar cell 402. When the side surface 1610 of the reflector 1404 is an involute surface corresponding to the elongated solar cell 402 that is adjacent or attached to the reflector 1404, light reflects effectively off the involute surface in a direction that is optimized towards the elongated solar cell 402.

In some embodiments not illustrated in FIG. 16, elongated solar cells 402 are swaged at their ends such that the diameter at the ends is less than the diameter towards the center of such cells. Electrodes 440 are placed on these swaged ends.

Solar cell assembly. As illustrated in FIG. 16, solar cells in the plurality of elongated solar cells 402 are geometrically arranged in a parallel or near parallel manner. In some embodiments, elongated conductive core 404 is any of the dual layer cores described in Section 5.4. In some embodiments, rather than forming a conductive core 404, back-electrode 404 is a thin layer of metal deposited on a substrate 403 as illustrated, for example, in FIG. 3B. In some embodiments, the terminal ends of elongated solar cells 402 can be stripped down to the outer core. For example, consider the case in which elongated solar cell 402 is constructed out of an inner core made of a cylindrical substrate 403 and an outer core (back-electrode 404) made of molybdenum. In such a case, the end of elongated solar cell 402 can be stripped down to the molybdenum back-electrode 404 and electrode 440 can be electrically connected with back-electrode 404.

In some embodiments, each internal reflector 1404 connects to two encapsulated elongated solar cells 402 (e.g., depicted as 300 in FIGS. 15 and 16), for example, in the manner illustrated in FIG. 16. Because of this, elongated solar cells 402 are effectively joined into a single composite device. In FIG. 16, electrodes 440 extend the connection from back-electrode 404. In some embodiments, internal reflector units 1404 are connected to encapsulated solar cells 300 via indentations on transparent casing 310. In some embodiments, the indentations on transparent casing 310 are created to complement the shape of the internal reflector unit 1404. Indentations on two transparent casing 310 are used to lock in one internal reflector unit 1404 that is positioned between the two encapsulated solar cells 300. In some embodiments, adhesive materials, e.g., epoxy glue, are used to fortify the connections between the internal reflector unit 1404 and the adjacent encapsulated solar cell units 300 such that solar radiation is properly reflected towards the encapsulated solar cell units 300 for absorption.

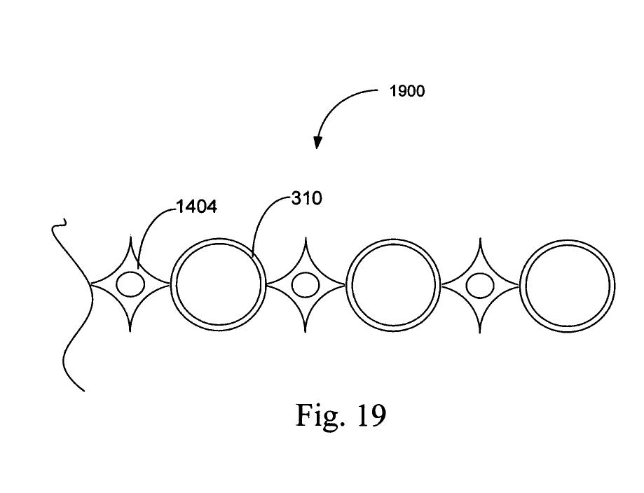

In some embodiments in accordance with the present application, internal reflector unit 1404 and transparent casing 310 may be created in the same molding process. For example, an array of alternating transparent casing 310 and asteroid reflectors 1404, e.g., shown as 1900 in FIG. 19, can be made as a single composite entity. Additional modifications may be done to enhance the albedo effect from the internal reflector unit 1404 or to promote better fitting between transparent casing 310 and solar cell 402. The casing 310 may contain internal modifications that complement the shapes of some embodiments of the solar cell 402. There is no limit to the number of internal reflectors 1404 or casing 310 in the assembly as depicted in FIG. 19 (e.g., 10 or more, 100 or more, 1000 or more, 10,000 or more, between 5,000 and one million internal reflectors 1404 and casing 310, etc.).

### 6. EXEMPLARY METHODS OF MAKING A SOLAR CELL UNIT

The methods and materials described in this section are intended to be merely illustrative, and not intended to be limiting of the application.

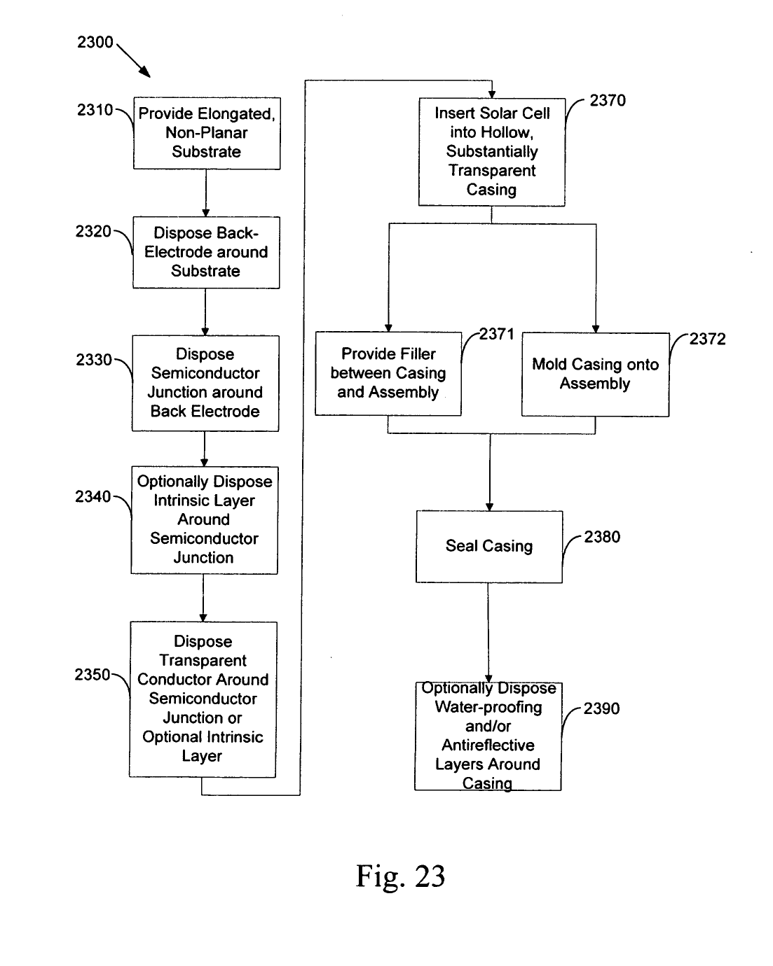

FIG. 23 illustrates an exemplary method 2300 for forming a solar cell unit. First, a solar cell is formed, and then the solar cell is encased inside a substantially transparent, hollow casing to form the solar cell unit. The solar cell unit is optionally further treated to enhance the solar cell unit's transparency. Steps 2310-2360 describe the formation of the solar cell, and steps 2370-2391 describe the encasement of the solar cell into the hollow casing to form the solar cell unit, and optional further treatment.

First, an elongated, nonplanarsubstrate is provided (2310), e.g., a cylindrical soda glass substrate having a diameter of between 1 centimeter and 10 centimeter and a length of between ten centimeters and 2000 centimeters. The substrate can be commercially obtained.

A back-electrode is disposed around all or a portion of the substrate (2320) such that the back-electrode extends along all or a portion of the length of the substrate. In one example, the back-electrode is deposited by physical vapor depositing (e.g., sputtering) a metallic layer (e.g., molybdenum) of thickness of about 1 micron around the substrate.

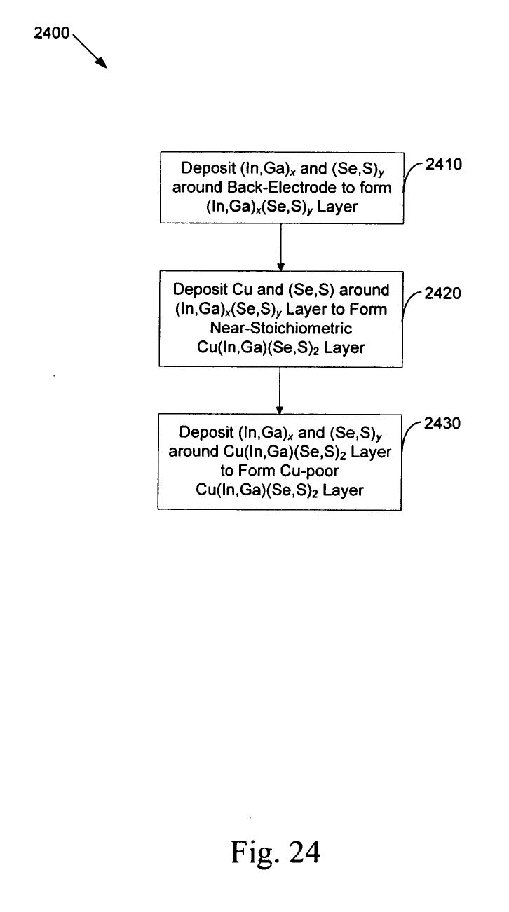

A semiconductor junction is disposed around all or a portion of the back-electrode (2330). Further details on an exemplary method of disposing the semiconductor junction are provided below with respect to FIG. 24.

An intrinsic layer, e.g. high quality zinc oxide, is optionally disposed around all or a portion of the semiconductor junction (2340). A transparent conductor, e.g. indium tin oxide) is then disposed around all or a portion of the semiconductor junction, or, if an intrinsic layer was disposed, the transparent conductor is disposed around all or a portion of the intrinsic layer (2350) by physical vapor deposition.

Then, the solar cell (having the substrate, back-electrode, semiconductor junction, optional intrinsic layer, and transparent conductor) is inserted into a hollow, substantially transparent casing (2370). In one example, the casing is a hollow tube formed of glass, e.g., soda-lime glass or borosilicate glass. In another example, the casing is formed of plastic. The casing is typically pre-formed and can be purchased commercially. The casing is open at one or both ends, and has an internal opening with a width that is at least as large as the width of the solar cell.

In embodiments where a filler (e.g., silicone gel) is used, the filler is provided between the casing and the solar cell (2371), e.g., before, during, or after the solar cell is inserted into the casing. In one example, the casing is sealed at one end, and filler material is poured into that end. The solar cell is then loaded into the casing, and suction force is used to draw the filler material upwards to partially or completely fill the space between the solar cell and the casing. In another example, the casing is open at both ends, and one end is dipped into a container of the filler. The solar cell is then loaded into the casing, and pressure applied to the filler to force the filler upwards to partially or completely fill the space between the solar cell and the casing. In another example, the casing is open at one end, and the filler material is poured into the casing while the solar cell is loaded into the casing.

In embodiments where no filler is used, the casing is molded onto the solar cell assembly (2372), for example, using heat shrink loading or injection molding. Note that the casing can alternatively be molded onto a solar cell that is pre-surrounded with filler (e.g., a semi-solid or solid filler).

Note that as described above in section 5.1.3.2, in some embodiments (not shown in FIG. 23) the casing is not pre-formed, but instead is deposited around the assembly, e.g., by dipping the solar cell in a liquid and then polymerizing the liquid to form a solid casing circumferentially disposed on the solar cell.

The transparent casing is sealed (2380) as disclosed, for example in U.S. patent application Ser. No. 11/437,928, entitled “Hermetically Sealed Cylindrical Solar Cells,” filed May 19, 2006, which is hereby incorporated by reference herein.

A water resistant layer and/or antireflective coating are optionally disposed around all or a portion of the transparent casing (2390). Alternatively, a water resistant layer can be disposed in an earlier step, e.g., over the transparent conductor, as described in greater detail above.

FIG. 24 illustrates an exemplary method 2400 of forming a semiconductor junction (e.g., between steps 2320 and 2340 of the method of FIG. 23). Specifically, FIG. 24 illustrates an exemplary method 2400 of forming a thin film Cu(In,Ga)(Se,S)₂-based semiconductor junction having suitable photovoltaic properties for use in one or more of the solar cells of the present application. For further details on the method, see U.S. Pat. No. 5,441,897, the entire contents of which are hereby incorporated by reference herein.

The term Cu(In,Ga)(Se,S)₂ generally refers to the classes of materials called CIS and/or CIGS, in which the ratio of indium to gallium is n:(1−n), where n is between zero and 1, inclusive, and in which the ratio of selenium to sulfur is m:(1−m), where m is between zero and 1, inclusive. Those of skill in the art can readily adapt the method of FIG. 24 to any desired values of n and m. The term (In,Ga) means any stoichiometric ratio of indium and gallium, and the term (Se,S) means any stoichiometric ratio of selenium to sulfur. In general as used herein the expression (a,b) means any stoichiometric ratio of element or compound a to element or compound b in a layer of a solar cell 402.

First, a layer of (In,Ga)ₓ(Se,S)_{y} is disposed around the back-electrode (2410). The layer can be deposited by any suitable method, including evaporation, sputtering, electrodeposition, or chemical vapor deposition, at a temperature between, e.g., about 25° C. and about 600° C., e.g., about 260° C. In one example, the (In,Ga) and (Se,S) are co-deposited or sequentially deposited from elemental (In,Ga) and (Se,S), and in another example, the binary (or greater) compound (In,Ga)ₓ(Se,S)_{y}, such as (In_{1-δ}Ga_{δ})₂(Se_{1-σ}S_{σ})₃, where both δ and σ are between 0 and 1 and δ+σ=1, is deposited. Exemplary binary compounds include, but are not limited to e.g., In₂Se₃, Ga₂Se₃, In₂S₃, and/or Ga₂S₃. In some embodiments, (In,Ga)ₓ(Se,S)_{y} represents a combination of elements and compounds. The deposited layer of (In,Ga)ₓ(Se,S)_{y} has a known thickness, which is used to determine the proportions of materials used in one or more later steps. In some embodiments, elements or compounds are deposited at this stage sequentially instead of all at the same time. For example, 50% In₂Se₃ may be deposited during step 2410 and followed by another 50% during step 2430. In other embodiments, 80% In₂Se₃ may be deposited during step 2410 and followed by another 20% during step 2430. In yet other embodiments, 90% In₂Se₃ may be deposited during step 2410 and followed by another 10% during step 2430. In some embodiments, between 90-99% of the (In,Ga) and (Se,S) of the finished film is deposited during step 2410, and the remainder during step 2430 (below). In some embodiments, the resulting film from step 2410 is over 500 Å, 1000 Å, over 2000 Å, over 4000 Å, over 8000 Å, over 10,000 Å, over 20,000 Å.

Next, a layer of Cu(In,Ga)(Se,S)₂ is formed by depositing Cu and (Se,S) around the (In,Ga)ₓ(Se,S)_{y} layer (2420). In one example, the Cu and (Se,S) are co-deposited or sequentially deposited from elemental Cu and (Se,S), and in another example, the binary (or greater) compound Cuₓ(Se,S), such as Cu₂Se_{1-δ}S_{δ}, where δ is between 0 and 1, is deposited. Exemplary compounds include, but are not limited to, e.g., Cu₂Se and Cu₂S. In some embodiments, Cu and (Se,S) represents a combination of elements and compounds. Suitable temperatures for step 2420 include, but are not limited to, from between about 350° C. and about 1200° C., e.g., about 600° C., or about 565° C. During deposition, the Cu and (Se,S) does not stay segregated from the (In,Ga)ₓ(Se,S)_{y} layer; instead, a substantially homogeneous film is formed (although some phase separation is possible in some embodiments). The Cu and (Se,S) are deposited until the overall composition of the resulting film has a stoichiometric ratio of Cu to (In,Ga) of between about 0.9 and about 1.2. In some embodiments, the stoichiometric ratio of Cu to (In,Ga) may be smaller than about 0.9 or greater than about 1.2. In some embodiments, 100% of the Cu of the finished film is deposited during step 2420. In some embodiments, elements or compounds are also deposited at this stage sequentially instead of all at the same time. For example, 50% Cu₂Se may be deposited during step 2420 and followed by another 50%. In other embodiments, 80% Cu₂Se may be deposited during step 2420 and followed by another 20%. In yet other embodiments, 90% Cu₂Se may be deposited during step 2420 and followed by another 10%. In some embodiments, the resulting film from step 2420 is over 500 Å, 1000 Å, over 2000 Å, over 4000 Å, over 8000 Å, over 10,000 Å, over 20,000 Å.

Next, a Cu-poor layer of Cu(In,Ga)(Se,S)₂ is formed by depositing (In,Ga) and (Se,S) around the layer of Cu(In,Ga)(Se,S)₂ (2430). Specifically, the remaining 1-10% of the (In,Ga)ₓ and (Se,S)_{y} are deposited, e.g., by co-depositing or sequentially depositing elemental (In,Ga) and (Se,S), or by depositing the binary (or greater) compound (In,Ga)ₓ(Se,S)_{y}, e.g., In₂Se₃, Ga₂Se₃, In₂S₃, or Ga₂S₃, at a temperature of between about 350° C. and about 1200° C., e.g., about 600° C., or about 565° C. The (In,Ga) and (Se,S) do not stay segregated from the Cu(In,Ga)(Se,S)₂ film; instead, a homogeneous film is formed (although some phase separation is possible in some embodiments). The (In,Ga) and (Se,S) are deposited in an amount sufficient to result in a Cu-poor layer of Cu(In,Ga)(Se,S)₂, e.g., a layer having a stoichiometric ratio of Cu to (In,Ga) of between about 0.8 and 0.99. In some embodiments, the stoichiometric ratio of Cu to (In,Ga) may be smaller than about 0.8 or greater than about 0.99. In some embodiments, the resulting film from step 2430 is over 500 Å, 1000 Å, over 2000 Å, over 4000 Å, over 8000 Å, over 10,000 Å, over 20,000 Å.

Note that throughout steps 2420 and 2430, a vapor-overpressure of (Se,S) can be used to prevent (In,Ga)₂(Se,S) from forming and evaporating, until the Cu-poor layer of Cu(In,Ga)(Se,S)₂ is formed and cooled to a temperature at which (In,Ga)₂(Se,S) no longer forms and/or evaporates.

It is to be noted that the three-step process described above is provided by way of illustration. Any process that allows deposition, sputtering, or coating one or more layers of semiconductor material on a substrate may be adopted in accordance with the instant application. For example, additional deposition methods such as a one step or two-step method or even multi-step method may be used to manufacture devices of the instant application. See, for example, U.S. Pat. Nos. 5,141,564; 4,581,108; and 4,465,575; each of which is hereby incorporated by reference herein in its entirety.

### 7. REFERENCES CITED

All references cited herein are incorporated herein by reference in their entirety and for all purposes to the same extent as if each individual publication or patent or patent application was specifically and individually indicated to be incorporated by reference in its entirety for all purposes.

### 8. EXEMPLARY EMBODIMENTS

Under one aspect, a solar cell unit includes an elongated solar cell and an at least partially transparent casing that encases the solar cell. The elongated solar cell includes: a nonplanar substrate defining a length of the solar cell, wherein a length of the nonplanar substrate is at least three times longer than a width of the nonplanar substrate; a back-electrode disposed around all or a portion of a perimeter of the nonplanar substrate, wherein the back-electrode extends along all or a portion of a length of the nonplanar substrate; a semiconductor junction disposed on the back-electrode, the semiconductor junction including a first layer and a second layer, each of the first and second layers including an inorganic semiconductor; and an at least partially transparent conductive layer disposed on the semiconductor junction.

In some embodiments, the first layer has a first conductivity type, and the second layer has a second conductivity type that is different from the first conductivity type. In some embodiments, a difference between the first conductivity type and the second conductivity type generates a potential difference across an interface between the first and second layers. In some embodiments, the solar cell unit is connected to an external load, and wherein responsive to irradiation with photons having energies above a first band gap of the first layer the first layer generates electrons that drift through the external load under the influence of the potential difference and then recombine with holes in the second layer. In some embodiments, at least thirty percent, or at least fifty percent, or at least seventy percent, or at least ninety percent, or substantially all of the electrons in the external load are derived from the first layer's response to irradiation with photons above the first band gap.

In some embodiments, the first conductivity type is p and the second conductivity type is n. In some embodiments, the first conductivity type is n and the second conductivity type is p. Some embodiments include a third layer disposed between the first and second layers, the third layer including an undoped insulator. In some embodiments, the first layer includes an n type inorganic semiconductor; and the second layer includes an n+ type inorganic semiconductor. In some embodiments, the first layer is an absorber layer and the second layer is a junction partner layer. In some embodiments, the first layer is a junction partner layer and the second layer is an absorption layer.

In some embodiments, the first layer is characterized by a first band gap; the second layer is characterized by a second band gap; and the second band gap is larger than the first band gap. In other embodiments, the first layer is characterized by a first band gap; the second layer is characterized by a second band gap; and the second band gap is smaller than the first band gap. In some embodiments, the first layer is characterized by a first band gap that is in the range of 0.7 eV to 2.2 eV.

In some embodiments, the first layer includes copper-indium-gallium-diselenide (CIGS); and the first layer is characterized by a first band gap that is in the range of 1.04 eV to 1.67 eV. In some embodiments, the first layer includes copper-indium-gallium-diselenide (CIGS); and the first layer is characterized by a first band gap that is in the range of 1.1 eV to 1.2 eV. In some embodiments, the first layer is an absorber layer that is graded such that a band gap of the first layer varies as a function of absorber layer depth. In some embodiments, the first layer is an absorber layer including copper-indium-gallium-diselenide having the stoichiometry CuIn₁₋ₓGaₓSe₂ with non-uniform Ga/In composition versus absorber layer depth. In some embodiments, the first layer is an absorber layer including copper-indium-gallium-diselenide with the stoichiometry CuIn₁₋ₓGaₓSe₂ and wherein a band gap of the absorber layer ranges between a first value in the range 1.04 eV to 1.67 eV and a second value in the range of 1.04 eV to 1.67 eV as a function of absorber layer depth, where the first value is greater than the second value. In some embodiments, the first layer is an absorber layer including copper-indium-gallium-diselenide having the stoichiometry CuIn₁₋ₓGaₓSe₂ wherein a band gap of the absorber layer ranges between a first value in the range of 1.04 eV to 1.67 eV to a second value in the range of 1.04 eV to 1.67 eV as a function of absorber layer depth, wherein the first value is less than the second value. In some embodiments, the band gap of the absorber layer ranges between the first value and the second value in a continuous linear gradient as a function of absorber layer depth. In some embodiments, the band gap ranges between the first value and the second value in a nonlinear gradient or discontinuously as a function of absorber layer depth. In some embodiments, In some embodiments, the first layer is characterized by a first band gap that is in the range of 0.9 eV and 1.8 eV. In some embodiments, the first layer is characterized by a first band gap that is in the range of 1.1 eV and 1.4 eV.

In some embodiments, the nonplanar substrate has cross-sectional symmetry or approximate cross-sectional symmetry. In some embodiments, the substrate is cylindrical. In some embodiments, the nonplanar substrate is characterized by a cross-section having a bounding shape, wherein the bounding shape is circular, elliptical, a polygon, ovoid, or wherein the bounding shape is characterized by one or more smooth curved edges, or wherein the bounding shape is characterized by one or more arcuate edges. In some embodiments, the nonplanar substrate is a hollow tube or a solid rod. In some embodiments, at least one of the nonplanar substrate and the at least partially transparent casing is rigid. In some embodiments, at least one of the nonplanar substrate and the at least partially transparent casing includes a linear material. In some embodiments, the nonplanar substrate has a Young's Modulus and a thickness that are selected such that the nonplanar substrate has the property that the nonplanar substrate does not visibly deflect when a first end of the nonplanar substrate is subjected to a force of between 1 dyne and 10⁵ dynes while a second end of the nonplanar is held fixed. In some embodiments, the nonplanar substrate has a Young's Modulus and a thickness that are selected such that the nonplanar substrate has the property that the nonplanar substrate does not visibly deflect when a first end of the nonplanar substrate is subjected to a force of between 100 dynes and 10⁶ dynes while a second end of the nonplanar substrate is held fixed. In some embodiments, the nonplanar substrate has a Young's Modulus and a thickness that are selected such that the nonplanar substrate has the property that the nonplanar substrate does not visibly deflect when a first end of the nonplanar substrate is subjected to a force of between 10,000 dynes and 10⁷ dynes while a second end of the nonplanar substrate is held fixed. In some embodiments, the nonplanar substrate has a Young's Modulus and a thickness that are selected such that the nonplanar substrate has the property that the nonplanar substrate does not visibly deflect when a first end of the nonplanar substrate is subjected to the force of gravity while a second end of the nonplanar substrate is held in a stationary position.

In some embodiments, at least one of the first layer and the second layer includes an inorganic semiconductor selected from the group consisting of a type I-III-VI₂ material, a type III-V material, a type II-VI material, and silicon. In some embodiments, a state of the first layer and a state of the second layer is each independently crystalline, polycrystalline, or amorphous. In some embodiments, more than 10% of molecules in the first layer of the semiconductor junction are in a crystalline state and the first layer includes one or more crystals. In some embodiments, more than 50% of molecules in the first layer of the semiconductor junction are in a crystalline state and the first layer includes one or more crystals. In some embodiments, more than 70% of molecules in the first layer of the semiconductor junction are in a crystalline state and the first layer includes one or more crystals. In some embodiments, more than 90% of molecules in the first layer of the semiconductor junction are independently arranged into one or more crystals, where such crystals are in a triclinic, monoclinic, orthorhombic, tetragonal, trigonal (rhombohedral lattice), trigonal (hexagonal lattice), hexagonal, or cubic crystal system and the first layer includes one or more crystals. In some embodiments, more than 90% of molecules in the second layer of the semiconductor junction are independently arranged into one or more crystals, where such crystals are in a triclinic, monoclinic, orthorhombic, tetragonal, trigonal (rhombohedral lattice), trigonal (hexagonal lattice), hexagonal, or cubic crystal system and wherein the second layer includes one or more crystals. In some embodiments, more than 50% of molecules in the first layer or the second layer of the semiconductor junction are arranged in a cubic space group and the first layer or the second layer includes one or more crystals. In some embodiments, more than 50% of molecules in the first layer or the second layer of the semiconductor junction are in a tetragonal space group and the first layer or the second layer includes one or more crystals. In some embodiments, more than 50% of molecules in the first layer or the second layer of the semiconductor junction are arranged in an Fm3m space group and the first layer includes one or more crystals. In some embodiments, at least one of the first layer and the second layer includes a grain boundary.

In some embodiments, an electronic band structure of the first layer is characterized by a valence band and a conduction band, with a gap between the valence band and the conduction band. In some embodiments, the semiconductor junction is characterized by a short circuit current density J_{sc} that is between 22 mA/cm² and 35 mA/cm² when the solar cell unit is irradiated at 25° C. with 100 mW/cm² of an AM 1.5 G spectrum. In some embodiments, the semiconductor junction is characterized by a short circuit current density J_{sc} that is between 22 mA/cm² and 35 mA/cm² when the solar cell unit is irradiated at any temperature between 0° C. and 70° C. with 100 mW/cm² of an AM 1.5 G spectrum. In some embodiments, the semiconductor junction is characterized by an open circuit voltage V_{oc} that is between 0.4 V and 0.8 V when the solar cell unit is irradiated at any temperature between 0° C. and 70° C. with 100 mW/cm² of an AM 1.5 G spectrum. In some embodiments, the first layer has a first density that is between 2.33 g/cm³ and 8.9 g/cm³ and the second layer has a second density that is between 2.33 g/cm³ and 8.9 g/cm³ wherein the first density and the second density are the same or different.

In some embodiments, the semiconductor junction is scribed thereby forming a plurality of individual units, wherein a first unit in the plurality of units is electrically connected in series to a second unit in the plurality of units in a monolithically integrated manner. In some embodiments, the semiconductor junction is scribed thereby forming a plurality of individual units, wherein a first unit in the plurality of units is electrically connected in parallel to a second unit in the plurality of units.

In some embodiments, all the materials in the solar cell are in a solid state. In some embodiments, the semiconductor junction is in a solid state. In some embodiments, at least eighty percent of molecules in the first layer are inorganic semiconductor molecules and wherein at least eighty percent of the molecules in the second layer are inorganic semiconductor molecules.

Some embodiments further include a filler material between the solar cell and the at least partially transparent casing. In some embodiments, the filler material includes silicone. In some embodiments, the filler material includes a gel or liquid. Some embodiments include a filler material that occupies at least fifty percent of a volume formed between the solar cell and the at least partially transparent casing. Some embodiments include a filler material that occupies at least seventy-five percent of a volume formed between the solar cell and the at least partially transparent casing.

In some embodiments, the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 1 dyne and 10⁵ dynes while a second end of the at least partially transparent casing is held fixed. In some embodiments, the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 100 dynes and 10⁶ dynes while a second end of the at least partially transparent casing is held fixed. In some embodiments, the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 10,000 dynes and 10⁷ dynes while a second end of the at least partially transparent casing is held fixed.

Under another aspect, a solar cell unit includes an elongated solar cell and an at least partially transparent casing that encases the solar cell. The elongated solar cell includes: a nonplanar substrate defining a length of the solar cell, wherein a length of the nonplanar substrate is at three times longer than a width of the nonplanar substrate; a back-electrode disposed around all or a portion of a perimeter of the nonplanar substrate, wherein the back-electrode extends along all or a portion of a length of the nonplanar substrate; a semiconductor junction disposed on the back-electrode, the semiconductor junction including a first layer and a second layer, each of the first and second layers including a crystalline or a polycrystalline semiconductor; and an at least partially transparent conductive layer disposed on the semiconductor junction.

Under another aspect, a solar cell unit includes an elongated solar cell and an at least partially transparent casing encasing the solar cell. The elongated solar cell includes a nonplanar substrate defining a length of the solar cell, wherein a length of the nonplanar substrate is much larger than a width of the nonplanar substrate; a back-electrode disposed around all or a portion of a perimeter of the nonplanar substrate, wherein the back-electrode extends along all or a portion of a length of the nonplanar substrate; a semiconductor junction disposed on the back-electrode; and an at least partially transparent conductive layer circumferentially disposed on the semiconductor junction. The nonplanar substrate has a Young's modulus and a thickness selected such that the nonplanar substrate does not visibly deflect when a first end of the nonplanar substrate is subjected to a force of up to 10,000 dynes while a second end of the nonplanar substrate is held fixed.

In some embodiments, the nonplanar substrate has a Young's modulus and a thickness selected such that the nonplanar substrate does not visibly deflect when a first end of the nonplanar substrate is subjected to a force of up to 1,000 dynes while a second end of the nonplanar substrate is held fixed. In some embodiments, the nonplanar substrate has a Young's modulus and a thickness selected such that the nonplanar substrate does not visibly deflect when a first end of the nonplanar substrate is subjected to a force of up to 100 dynes while a second end of the nonplanar substrate is held fixed.

Under another aspect, a solar cell unit includes an elongated solar cell and an at least partially transparent casing that encases the solar cell. The elongated solar cell includes a nonplanar substrate defining a length of the solar cell, wherein a length of the nonplanar substrate is at least five times a width of the nonplanar substrate; a back-electrode disposed around all or a portion of a perimeter of the nonplanar substrate, wherein the back-electrode extends along all or a portion of a length of the nonplanar substrate; a semiconductor junction disposed on the back-electrode, the semiconductor junction including a first layer and a second layer, wherein at least one of the first and second layers characterized by a band gap of between 0.7 eV and 2.2 eV; and an at least partially transparent conductive layer disposed on the semiconductor junction.

In some embodiments, the band gap is between 0.9 eV and 1.8 eV. In some embodiments, the band gap is between 1.1 eV and 1.4 eV.

Under another aspect, a solar cell unit includes an elongated solar cell and an at least partially transparent casing encasing the solar cell. The elongated solar cell includes a nonplanar substrate defining a length of the solar cell, wherein a length of the nonplanar substrate is at three times longer than a width of the nonplanar substrate; a back-electrode disposed around all or a portion of a perimeter of the nonplanar substrate, wherein the back-electrode extends along all or a portion of a length of the nonplanar substrate; a semiconductor junction disposed on the back-electrode; and an at least partially transparent conductive layer disposed on the semiconductor junction. Responsive to irradiation with 1000 W/m² of an AM 1.5 global spectrum, the semiconductor junction exhibits a current density of between 10 mA/cm² and 39 mA/cm².

In some embodiments, responsive to irradiation with 1000 W/m² of an AM 1.5 global spectrum, the semiconductor junction exhibits a current density of between 20 mA/cm² and 39 mA/cm². In some embodiments, responsive to irradiation with 1000 W/m² of an AM 1.5 global spectrum, the semiconductor junction exhibits a current density of between 30 mA/cm² and 39 mA/cm².

Under another aspect, a method of making a solar cell unit includes making an elongated solar cell and encasing the solar cell with an at least partially transparent casing. Making the elongated solar cell includes (i) disposing a back electrode around all or a portion of a perimeter of a nonplanar substrate such that the back-electrode extends along all or a portion of a length of the nonplanar substrate; (ii) disposing a semiconductor junction on the back electrode; and (iii) disposing an at least partially transparent conductive layer on the semiconductor junction. Disposing the semiconductor junction over the back electrode step (ii) includes disposing a first semiconductor layer on the back electrode and disposing a second semiconductor layer over the first semiconductor layer. Disposing the first semiconductor layer includes: (a) depositing at least one of indium and gallium, and at least one of selenium and sulfur, on the back electrode to form a first layer; (b) depositing copper and at least one of selenium and sulfur on the first layer to form a second layer; and (c) depositing at least one of indium and gallium, and at least one of selenium and sulfur, on the second layer, to form a third layer.

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

What is claimed:

1. A solar cell unit comprising:
a) an elongated solar cell comprising:
a nonplanar substrate defining a length of the solar cell, wherein a length of the nonplanar substrate is at least three times longer than a width of the nonplanar substrate;
a back-electrode disposed around all or a portion of a perimeter of the nonplanar substrate, wherein the back-electrode extends along all or a portion of a length of the nonplanar substrate;
a semiconductor junction disposed on the back-electrode, the semiconductor junction comprising a first layer and a second layer, each of the first and second layers comprising an inorganic semiconductor; and
an at least partially transparent conductive layer disposed on the semiconductor junction; and
b) an at least partially transparent casing that encases the solar cell.

2. The solar cell unit of claim 1, wherein:
the first layer has a first conductivity type, and
the second layer has a second conductivity type that is different from the first conductivity type.

3. The solar cell unit of claim 2, wherein a difference between the first conductivity type and the second conductivity type generates a potential difference across an interface between the first and second layers.

4. The solar cell unit of claim 3, wherein the solar cell unit is connected to an external load, and wherein responsive to irradiation with photons having energies above a first band gap of the first layer the first layer generates electrons that drift through the external load under the influence of the potential difference and then recombine with holes in the second layer.

5. The solar cell unit of claim 4, wherein at least thirty percent of the electrons in the external load are derived from the first layer's response to irradiation with photons above the first band gap.

6. The solar cell unit of claim 4, wherein at least fifty percent of the electrons in the external load are derived from the first layer's response to irradiation with photons above the first band gap.

7. The solar cell unit of claim 4, wherein at least seventy percent of the electrons in the external load are derived from the first layer's response to irradiation with photons above the first band gap.

8. The solar cell unit of claim 4, wherein at least ninety percent of the electrons in the external load are derived from the first layer's response to irradiation with photons above the first band gap.

9. The solar cell unit of claim 4, wherein substantially all the electrons in the external load are derived from the first layer's response to irradiation with photons above the first band gap.

10. The solar cell unit of claim 2, wherein the first conductivity type is p and the second conductivity type is n.

11. The solar cell unit of claim 2, wherein the first conductivity type is n and the second conductivity type is p.

12. The solar cell unit of claim 1, further comprising a third layer disposed between the first and second layers, the third layer comprising an undoped insulator.

13. The solar cell unit of claim 1, wherein:
the first layer comprises an n type inorganic semiconductor; and
the second layer comprises an n+ type inorganic semiconductor.

14. The solar cell unit of claim 1, wherein the first layer is an absorber layer and the second layer is a junction partner layer.

15. The solar cell unit of claim 1, wherein the first layer is ajunction partner layer and the second layer is an absorption layer.

16. The solar cell unit of claim 1, wherein:
the first layer is characterized by a first band gap;
the second layer is characterized by a second band gap; and
the second band gap is larger than the first band gap.

17. The solar cell unit of claim 1, wherein:
the first layer is characterized by a first band gap;
the second layer is characterized by a second band gap; and
the second band gap is smaller than the first band gap.

18. The solar cell unit of claim 1, wherein the first layer is characterized by a first band gap that is in the range of 0.7 eV to 2.2 eV.

19. The solar cell unit of claim 1, wherein:
the first layer comprises copper-indium-gallium-diselenide (CIGS); and
the first layer is characterized by a first band gap that is in the range of 1.04 eV to 1.67 eV.

20. The solar cell unit of claim 1, wherein:
the first layer comprises copper-indium-gallium-diselenide (CIGS); and
the first layer is characterized by a first band gap that is in the range of 1.1 eV to 1.2 eV.

21. The solar cell unit of claim 1, wherein the first layer is an absorber layer that is graded such that a band gap of the first layer varies as a function of absorber layer depth.

22. The solar cell unit of claim 1, wherein the first layer is an absorber layer comprising copper-indium-gallium-diselenide having the stoichiometry CuIn₁₋ₓGaₓSe₂ with non-uniform Ga/In composition versus absorber layer depth.

23. The solar cell unit of claim 1, wherein the first layer is an absorber layer comprising copper-indium-gallium-diselenide with the stoichiometry CuIn₁₋ₓGaₓSe₂ and wherein a band gap of the absorber layer ranges between a first value in the range 1.04 eV to 1.67 eV and a second value in the range of 1.04 eV to 1.67 eV as a function of absorber layer depth, where the first value is greater than the second value.

24. The solar cell unit of claim 1, wherein the first layer is an absorber layer comprising copper-indium-gallium-diselenide having the stoichiometry CuIn₁₋ₓGaₓSe₂ wherein a band gap of the absorber layer ranges between a first value in the range of 1.04 eV to 1.67 eV to a second value in the range of 1.04 eV to 1.67 eV as a function of absorber layer depth, wherein the first value is less than the second value.

25. The solar cell unit of claim 23, wherein the band gap of the absorber layer ranges between the first value and the second value in a continuous linear gradient as a function of absorber layer depth.

26. The solar cell unit of claim 24, wherein the band gap of the absorber layer ranges between the first value and the second value in a continuous linear gradient as a function of absorber layer depth.

27. The solar cell unit of claim 23, wherein the band gap ranges between the first value and the second value in a nonlinear gradient or discontinuously as a function of absorber layer depth.

28. The solar cell unit of claim 24, wherein the band gap ranges between the first value and the second value in a nonlinear gradient or discontinuously as a function of absorber layer depth.

29. The solar cell unit of claim 1, wherein the first layer is characterized by a first band gap that is in the range of 0.9 eV and 1.8 eV.

30. The solar cell unit of claim 1, wherein the first layer is characterized by a first band gap that is in the range of 1.1 eV and 1.4 eV.

31. The solar cell unit of claim 1, wherein the nonplanar substrate has cross-sectional symmetry or approximate cross-sectional symmetry.

32. The solar cell unit of claim 1, wherein the substrate is cylindrical.

33. The solar cell unit of claim 1, wherein the nonplanar substrate is characterized by a cross-section having a bounding shape, wherein the bounding shape is circular, elliptical, a polygon, ovoid, or wherein the bounding shape is characterized by one or more smooth curved edges, or wherein the bounding shape is characterized by one or more arcuate edges.

34. The solar cell unit of claim 1, wherein the nonplanar substrate is a hollow tube or a solid rod.

35. The solar cell unit of claim 1, wherein at least one of the nonplanar substrate and the at least partially transparent casing is rigid.

36. The solar cell unit of claim 1, wherein at least one of the nonplanar substrate and the at least partially transparent casing comprises a linear material.

37. The solar cell unit of claim 1, wherein the nonplanar substrate has a Young's Modulus and a thickness that are selected such that the nonplanar substrate has the property that the nonplanar substrate does not visibly deflect when a first end of the nonplanar substrate is subjected to a force of between 1 dyne and 10⁵ dynes while a second end of the nonplanar is held fixed.

38. The solar cell unit of claim 1, wherein the nonplanar substrate has a Young's Modulus and a thickness that are selected such that the nonplanar substrate has the property that the nonplanar substrate does not visibly deflect when a first end of the nonplanar substrate is subjected to a force of between 100 dynes and 10⁶ dynes while a second end of the nonplanar substrate is held fixed.

39. The solar cell unit of claim 1, wherein the nonplanar substrate has a Young's Modulus and a thickness that are selected such that the nonplanar substrate has the property that the nonplanar substrate does not visibly deflect when a first end of the nonplanar substrate is subjected to a force of between 10,000 dynes and 10⁷ dynes while a second end of the nonplanar substrate is held fixed.

40. The solar cell unit of claim 1, wherein the nonplanar substrate has a Young's Modulus and a thickness that are selected such that the nonplanar substrate has the property that the nonplanar substrate does not visibly deflect when a first end of the nonplanar substrate is subjected to the force of gravity while a second end of the nonplanar substrate is held in a stationary position

41. The solar cell unit of claim 1, wherein at least one of the first layer and the second layer comprises an inorganic semiconductor selected from the group consisting of a type I-III-VI₂ material, a type III-V material, a type II-VI material, and silicon.

42. The solar cell unit of claim 1, wherein a state of the first layer and a state of the second layer is each independently crystalline, polycrystalline, or amorphous.

43. The solar cell unit of claim 1, wherein more than 10% of molecules in the first layer of the semiconductor junction are in a crystalline state and wherein the first layer comprises one or more crystals.

44. The solar cell unit of claim 1, wherein more than 50% of molecules in the first layer of the semiconductor junction are in a crystalline state and wherein the first layer comprises one or more crystals.

45. The solar cell unit of claim 1, wherein more than 70% of molecules in the first layer of the semiconductor junction are in a crystalline state and wherein the first layer comprises one or more crystals.

46. The solar cell unit of claim 1, wherein more than 90% of molecules in the first layer of the semiconductor junction are independently arranged into one or more crystals, where such crystals are in a triclinic, monoclinic, orthorhombic, tetragonal, trigonal (rhombohedral lattice), trigonal (hexagonal lattice), hexagonal, or cubic crystal system and wherein the first layer comprises one or more crystals.

47. The solar cell unit of claim 1, wherein more than 90% of molecules in the second layer of the semiconductor junction are independently arranged into one or more crystals, where such crystals are in a triclinic, monoclinic, orthorhombic, tetragonal, trigonal (rhombohedral lattice), trigonal (hexagonal lattice), hexagonal, or cubic crystal system and wherein the second layer comprises one or more crystals.

48. The solar cell unit of claim 1, wherein more than 50% of molecules in the first layer or the second layer of the semiconductor junction are arranged in a cubic space group and wherein the first layer or the second layer comprises one or more crystals.

49. The solar cell unit of claim 1, wherein more than 50% of molecules in the first layer or the second layer of the semiconductor junction are in a tetragonal space group and wherein the first layer or the second layer comprises one or more crystals.

50. The solar cell unit of claim 1, wherein more than 50% of molecules in the first layer or the second layer of the semiconductor junction are arranged in an Fm3m space group and wherein the first layer comprises one or more crystals.

51. The solar cell unit of claim 1, wherein at least one of the first layer and the second layer comprises a grain boundary.

52. The solar cell unit of claim 1, wherein an electronic band structure of the first layer is characterized by a valence band and a conduction band, with a gap between the valence band and the conduction band.

53. The solar cell unit of claim 1, wherein the semiconductor junction is characterized by a short circuit current density J_{sc} that is between 22 mA/cm² and 35 mA/cm² when the solar cell unit is irradiated at 25° C. with 100 mW/cm² of an AM 1.5 G spectrum.

54. The solar cell unit of claim 1, wherein the semiconductor junction is characterized by a short circuit current density J_{sc} that is between 22 mA/cm² and 35 mA/cm² when the solar cell unit is irradiated at any temperature between 0° C. and 70° C. with 100 mW/cm² of an AM 1.5 G spectrum.

55. The solar cell unit of claim 1, wherein the semiconductor junction is characterized by an open circuit voltage V_{oc} that is between 0.4 V and 0.8 V when the solar cell unit is irradiated at any temperature between 0° C. and 70° C. with 100 mW/cm² of an AM 1.5 G spectrum.

56. The solar cell unit of claim 1, wherein the first layer has a first density that is between 2.33 g/cm³ and 8.9 g/cm³ and the second layer has a second density that is between 2.33 g/cm³ and 8.9 g/cm³ wherein the first density and the second density are the same or different.

57. The solar cell unit of claim 1, wherein the semiconductor junction is scribed thereby forming a plurality of individual units, wherein a first unit in the plurality of units is electrically connected in series to a second unit in the plurality of units in a monolithically integrated manner.

58. The solar cell unit of claim 1, wherein the semiconductor junction is scribed thereby forming a plurality of individual units, wherein a first unit in the plurality of units is electrically connected in parallel to a second unit in the plurality of units.

59. The solar cell unit of claim 1, wherein all the materials in the solar cell are in a solid state.

60. The solar cell unit of claim 1, wherein the semiconductor junction is in a solid state.

61. The solar cell unit of claim 1, further comprising a filler material between the solar cell and the at least partially transparent casing.

62. The solar cell of claim 61, wherein the filler material comprises silicone.

63. The solar cell of claim 61, wherein the filler material comprises a gel or liquid.

64. The solar cell unit of claim 1, wherein at least eighty percent of molecules in the first layer are inorganic semiconductor molecules and wherein at least eighty percent of the molecules in the second layer are inorganic semiconductor molecules.

65. The solar cell unit of claim 1, further comprising a sealant cap that is hermetically sealed to an end of the at least partially transparent casing.

66. A solar cell unit comprising:
a) an elongated solar cell comprising:
a nonplanar substrate defining a length of the solar cell, wherein a length of the nonplanar substrate is at three times longer than a width of the nonplanar substrate;
a back-electrode disposed around all or a portion of a perimeter of the nonplanar substrate, wherein the back-electrode extends along all or a portion of a length of the nonplanar substrate;
a semiconductor junction disposed on the back-electrode, the semiconductor junction comprising a first layer and a second layer, each of the first and second layers comprising a crystalline or a polycrystalline semiconductor; and
an at least partially transparent conductive layer disposed on the semiconductor junction; and
b) an at least partially transparent casing that encases the solar cell.

67. A solar cell unit comprising:
a) an elongated solar cell comprising:
a nonplanar substrate defining a length of the solar cell, wherein a length of the nonplanar substrate is much larger than a width of the nonplanar substrate;
a back-electrode disposed around all or a portion of a perimeter of the nonplanar substrate, wherein the back-electrode extends along all or a portion of a length of the nonplanar substrate;
a semiconductor junction disposed on the back-electrode; and
an at least partially transparent conductive layer circumferentially disposed on the semiconductor junction; and
b) an at least partially transparent casing encasing the solar cell,
wherein the nonplanar substrate has a Young's modulus and a thickness selected such that the nonplanar substrate does not visibly deflect when a first end of the nonplanar substrate is subjected to a force of up to 10,000 dynes while a second end of the nonplanar substrate is held fixed.

68. The solar cell unit of claim 67, wherein the nonplanar substrate has a Young's modulus and a thickness selected such that the nonplanar substrate does not visibly deflect when a first end of the nonplanar substrate is subjected to a force of up to 1,000 dynes while a second end of the nonplanar substrate is held fixed.

69. The solar cell unit of claim 67, wherein the nonplanar substrate has a Young's modulus and a thickness selected such that the nonplanar substrate does not visibly deflect when a first end of the nonplanar substrate is subjected to a force of up to 100 dynes while a second end of the nonplanar substrate is held fixed.

70. A solar cell unit comprising:
a) an elongated solar cell comprising:
a nonplanar substrate defining a length of the solar cell, wherein a length of the nonplanar substrate is at least five times a width of the nonplanar substrate;
a back-electrode disposed around all or a portion of a perimeter of the nonplanar substrate, wherein the back-electrode extends along all or a portion of a length of the nonplanar substrate;
a semiconductor junction disposed on the back-electrode, the semiconductor junction comprising a first layer and a second layer, wherein at least one of the first and second layers characterized by a band gap of between 0.7 eV and 2.2 eV; and
an at least partially transparent conductive layer disposed on the semiconductor junction; and
b) an at least partially transparent casing that encases the solar cell.

71. The solar cell unit of claim 70, wherein the band gap is between 0.9 eV and 1.8 eV.

72. The solar cell unit of claim 70, wherein the band gap is between 1.1 eV and 1.4 eV.

73. A solar cell unit comprising:
a) an elongated solar cell comprising:
a nonplanar substrate defining a length of the solar cell, wherein a length of the nonplanar substrate is at three times longer than a width of the nonplanar substrate;
a back-electrode disposed around all or a portion of a perimeter of the nonplanar substrate, wherein the back-electrode extends along all or a portion of a length of the nonplanar substrate;
a semiconductor junction disposed on the back-electrode; and
an at least partially transparent conductive layer disposed on the semiconductor junction; and
b) an at least partially transparent casing encasing the solar cell,
wherein, responsive to irradiation with 1000 W/m² of an AM 1.5 global spectrum, the semiconductor junction exhibits a current density of between 10 mA/cm² and 39 mA/cm².

74. The solar cell unit of claim 73, wherein responsive to irradiation with 1000 W/m² of an AM 1.5 global spectrum, the semiconductor junction exhibits a current density of between 20 mA/cm² and 39 mA/cm².

75. The solar cell unit of claim 72, wherein responsive to irradiation with 1000 W/m² of an AM 1.5 global spectrum, the semiconductor junction exhibits a current density of between 30 mA/cm and 39 mA/cm².

76. A method of making a solar cell unit, the method comprising:
a) making an elongated solar cell by the method comprising:
i) disposing a back electrode around all or a portion of a perimeter of a nonplanar substrate such that the back-electrode extends along all or a portion of a length of the nonplanar substrate;
ii) disposing a semiconductor junction on the back electrode; and
iii) disposing an at least partially transparent conductive layer on the semiconductor junction; and
b) encasing the solar cell with an at least partially transparent casing, wherein the disposing the semiconductor junction over the back electrode step (ii) comprises disposing a first semiconductor layer on the back electrode and disposing a second semiconductor layer over the first semiconductor layer, wherein disposing the first semiconductor layer comprises:
a) depositing at least one of indium and gallium, and at least one of selenium and sulfur, on the back electrode to form a first layer;
b) depositing copper and at least one of selenium and sulfur on the first layer to form a second layer; and
c) depositing at least one of indium and gallium, and at least one of selenium and sulfur, on the second layer, to form a third layer.

77. The solar cell unit of claim 1, wherein the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 1 dyne and 10⁵ dynes while a second end of the at least partially transparent casing is held fixed.

78. The solar cell unit of claim 1, wherein the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 100 dynes and 10⁶ dynes while a second end of the at least partially transparent casing is held fixed.

79. The solar cell unit of claim 1, wherein the at least partially transparent casing has a Young's Modulus, a thickness and a width that are selected such that the at least partially transparent casing has the property that the at least partially transparent casing does not visibly deflect when a first end of the at least partially transparent casing is subjected to a force of between 10,000 dynes and 10⁷ dynes while a second end of the at least partially transparent casing is held fixed.

80. The solar cell unit of claim 1, further comprising a filler material that occupies at least fifty percent of a volume formed between the solar cell and the at least partially transparent casing.

81. The solar cell unit of claim 1, further comprising a filler material that occupies at least seventy-five percent of a volume formed between the solar cell and the at least partially transparent casing.
